(19) United States
(12) Patent Application Publication
(10) Pub. No.: US 2023/0120875 A1
(43) Pub. Date: Apr. 20, 2023

(54) Display Device, Display Module, Electronic Device, And Method For Manufacturing Display Device

(71) Applicant: Semiconductor Energy Laboratory Co., Ltd., Kanagawa-ken (JP)

(72) Inventors: Shunpei Yamazaki, Tokyo (JP); Ryota Hodo, Atsugi (JP); Yasuhiro Jinbo, Isehara (JP)

(73) Assignee: Semiconductor Energy Laboratory Co., Ltd., Kanagawa-ken (JP)

(21) Appl. No.: 17/963,585

(22) Filed: Oct. 11, 2022

(30) Foreign Application Priority Data
Oct. 15, 2021 (JP) 2021-169567

(51) Int. Cl. H01L 51/52; H01L 51/56

(52) U.S. Cl. CPC H01L 51/5209; H01L 51/5218; H01L 51/56; H01L 2251/301; H01L 2251/308; H01L 2251/5315

(57) ABSTRACT

A highly reliable display device is provided. The display device includes a pixel electrode including first to fourth conductive layers, and an EL layer including a functional layer and a light-emitting layer. The second to fourth conductive layers are stacked in this order and provided to cover the first conductive layer. The functional layer includes a region that covers the second to fourth conductive layers and is in contact with the fourth conductive layer. The light-emitting layer is provided over the functional layer. The side surface of the first conductive layer has a tapered shape with a taper angle less than 90° in the cross section. The second to fourth conductive layers each include a tapered portion in a region overlapping the side surface of the first conductive layer. The visible light reflectance of the third conductive layer is higher than that of the first, second, and fourth conductive layers.

### BACKGROUND OF THE INVENTION

### 1. Field of the Invention

One embodiment of the present invention relates to a display device, a display module, and an electronic device. One embodiment of the present invention relates to a method for manufacturing a display device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### 2. Description of the Related Art

Recent display devices have been expected to be applied to a variety of uses. Usage examples of large-sized display devices include a television device for home use (also referred to as a TV or a television receiver), digital signage, and a public information display (PID). In addition, a smartphone, a tablet terminal, and the like each including a touch panel are being developed as portable information terminals.

Higher-resolution display devices have been required. For example, devices for virtual reality (VR), augmented reality (AR), substitutional reality (SR), or mixed reality (MR) are given as devices requiring high-resolution display devices and have been actively developed.

Light-emitting apparatuses including light-emitting elements (also referred to as light-emitting devices) have been developed as display devices, for example. For example, light-emitting elements utilizing electroluminescence (also referred to as EL elements or organic EL elements) have features such as ease of reduction in thickness and weight, high-speed response to input signals, and capability of DC constant voltage driving, and have been used in display devices.

Patent Document 1 discloses a display device for VR using organic EL elements (also referred to as organic EL devices).

Non-Patent Document 1 discloses a method for manufacturing an organic optoelectronic device using standard UV photolithography.

### REFERENCE

### Patent Document

[Patent Document 1] International Publication No. WO2018/087625

### Non-Patent Document

[Non-Patent Document 1] B. Lamprecht et al., “Organic optoelectronic device fabrication using standard UV photolithography”, Phys. Stat. Sol. (RRL) 2, No. 1, pp. 16-18 (2008)

### SUMMARY OF THE INVENTION

For example, an organic EL element can have a structure in which a layer containing an organic compound is sandwiched between a pair of electrodes. Here, characteristics required for the electrode range widely over reflectance or transmittance of light having a predetermined wavelength, improbability of film peeling, improbability of disconnection, and unlikeness of change in properties of a material used for the electrode, for example.

An object of one embodiment of the present invention is to provide a highly reliable display device. Another object of one embodiment of the present invention is to provide a display device with high outcoupling efficiency. Another object of one embodiment of the present invention is to provide a display device including a light-emitting element with low driving voltage. Another object of one embodiment of the present invention is to provide a display device including a light-emitting element with high emission efficiency. Another object of one embodiment of the present invention is to provide a display device with low power consumption. Another object of one embodiment of the present invention is to provide an inexpensive display device. Another object of one embodiment of the present invention is to provide a display device with high display quality. Another object of one embodiment of the present invention is to provide a high-resolution display device. Another object of one embodiment of the present invention is to provide a high-definition display device. Another object of one embodiment of the present invention is to provide a novel display device.

Another object of one embodiment of the present invention is to provide a method for manufacturing a display device with a high yield. Another object of one embodiment of the present invention is to provide a method for manufacturing a highly reliable display device. Another object of one embodiment of the present invention is to provide a method for manufacturing a display device with high outcoupling efficiency. Another object of one embodiment of the present invention is to provide a method for manufacturing a display device including a light-emitting element with low driving voltage. Another object of one embodiment of the present invention is to provide a method for manufacturing a display device including a light-emitting element with high emission efficiency. Another object of one embodiment of the present invention is to provide a method for manufacturing a display device with low power consumption. Another object of one embodiment of the present invention is to provide a method for manufacturing a display device with high display quality. Another object of one embodiment of the present invention is to provide a method for manufacturing a high-resolution display device. Another object of one embodiment of the present invention is to provide a method for manufacturing a high-definition display device. Another object of one embodiment of the present invention is to provide a method for manufacturing a novel display device.

Note that the description of these objects does not preclude the existence of other objects. One embodiment of the present invention does not need to achieve all of these objects. Other objects can be derived from the description of the specification, the drawings, and the claims.

One embodiment of the present invention is a display device including a first conductive layer, a second conductive layer, a third conductive layer, a fourth conductive layer, a functional layer, and a light-emitting layer. The second conductive layer, the third conductive layer, and the fourth conductive layer are positioned to cover the first conductive layer and to be electrically connected to the first conductive layer. The third conductive layer is positioned over the second conductive layer. The fourth conductive layer is positioned over the third conductive layer. The functional layer includes a region covering the second conductive layer, the third conductive layer, and the fourth conductive layer and being in contact with the fourth conductive layer. The light-emitting layer is positioned over the functional layer. A side surface of the first conductive layer has a tapered shape with a taper angle less than 90° in a cross-sectional view. The second conductive layer, the third conductive layer, and the fourth conductive layer each include a tapered portion in a region overlapping the side surface of the first conductive layer. Visible light reflectance of the third conductive layer is higher than visible light reflectance of the first conductive layer, the second conductive layer, and the fourth conductive layer.

In the above embodiment, the functional layer may include one or both of a hole-injection layer and a hole-transport layer. A work function of the fourth conductive layer may be higher than a work function of the third conductive layer.

In the above embodiment, the functional layer may include one or both of an electron-injection layer and an electron-transport layer. A work function of the fourth conductive layer may be lower than a work function of the third conductive layer.

In the above embodiments, the first conductive layer may be provided over a base insulating layer. The base insulating layer may include a projection portion in a region overlapped by the first conductive layer. A side surface of the projection portion of the base insulating layer may have a tapered shape with a taper angle less than 90° in a cross-sectional view.

In the above embodiments, the visible light reflectance of the third conductive layer may be higher than visible light reflectance of aluminum.

In the above embodiments, the third conductive layer may include silver.

In the above embodiments, the first conductive layer may include titanium. The second conductive layer and the fourth conductive layer may each include an oxide containing one or more selected from indium, tin, zinc, gallium, titanium, aluminum, and silicon.

A display module including the display of one embodiment of the present invention and at least one of a connector and an integrated circuit is also one embodiment of the present invention.

An electronic device including the display module of one embodiment of the present invention and at least one of a battery, a camera, a speaker, and a microphone is also one embodiment of the present invention.

Another embodiment of the present invention is a method for manufacturing a display device, including forming a first conductive film; processing the first conductive film, thereby forming a first conductive layer whose side surface has a tapered shape with a taper angle less than 90° in a cross-sectional view; forming, over the first conductive layer, a second conductive film, a third conductive film over the second conductive film, and a fourth conductive film over the third conductive film; processing the second conductive film, the third conductive film, and the fourth conductive film, thereby forming a second conductive layer, a third conductive layer, and a fourth conductive layer to cover the first conductive layer, to be electrically connected to the first conductive layer, and to include a tapered portion in a region overlapping the side surface of the first conductive layer; and forming a functional layer including a region covering the second conductive layer, the third conductive layer, and the fourth conductive layer and being in contact with the fourth conductive layer, and a light-emitting layer over the functional layer. As the third conductive film, a film having higher visible light reflectance than the first conductive film, the second conductive film, and the fourth conductive film is formed.

In the above embodiment, as the fourth conductive film, a film having a higher work function than the third conductive film may be formed. As the functional layer, one or both of a hole-injection layer and a hole-transport layer may be formed.

In the above embodiment, as the fourth conductive film, a film having a lower work function than the third conductive film may be formed. As the functional layer, one or both of an electron-injection layer and an electron-transport layer may be formed.

In the above embodiments, the first conductive film may be formed over a base insulating layer. In the step of processing the first conductive film to form the first conductive layer, a depression portion whose side surface has a tapered shape with a taper angle less than 90° may be formed in the base insulating layer in a region not overlapped by the first conductive layer.

In the above embodiments, the third conductive film may include silver.

In the above embodiments, the visible light reflectance of the third conductive film may be higher than visible light reflectance of aluminum.

In the above embodiments, the first conductive film may include titanium. The second conductive film and the fourth conductive film may each include an oxide containing one or more selected from indium, tin, zinc, gallium, titanium, aluminum, and silicon.

In the above embodiments, a functional film, a light-emitting film over the functional film, and a mask film over the light-emitting film may be formed over the fourth conductive layer. The functional film, the light-emitting film, and the mask film may be processed, thereby forming the functional layer, the light-emitting layer, and a mask layer over the light-emitting layer. At least part of the mask layer may be removed.

In the above embodiment, the functional film, the light-emitting film, and the mask film may be processed by a photolithography method.

One embodiment of the present invention can provide a highly reliable display device. One embodiment of the present invention can provide a display device with high outcoupling efficiency. One embodiment of the present invention can provide a display device including a light-emitting element with low driving voltage. One embodiment of the present invention can provide a display device including a light-emitting element with high emission efficiency. One embodiment of the present invention can provide a display device with low power consumption. One embodiment of the present invention can provide an inexpensive display device. One embodiment of the present invention can provide a display device with high display quality. One embodiment of the present invention can provide a high-resolution display device. One embodiment of the present invention can provide a high-definition display device. One embodiment of the present invention can provide a novel display device.

One embodiment of the present invention can provide a method for manufacturing a display device with a high yield. One embodiment of the present invention can provide a method for manufacturing a highly reliable display device. One embodiment of the present invention can provide a method for manufacturing a display device with high outcoupling efficiency. One embodiment of the present invention can provide a method for manufacturing a display device including a light-emitting element with low driving voltage. One embodiment of the present invention can provide a method for manufacturing a display device including a light-emitting element with high emission efficiency. One embodiment of the present invention can provide a method for manufacturing a display device with low power consumption. One embodiment of the present invention can provide a method for manufacturing a display device with high display quality. One embodiment of the present invention can provide a method for manufacturing a high-resolution display device. One embodiment of the present invention can provide a method for manufacturing a high-definition display device. One embodiment of the present invention can provide a method for manufacturing a novel display device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIG. 1A is a top view illustrating a structure example of a display device, and FIG. 1B is a cross-sectional view illustrating a structure example of a display device;

FIGS. 2A and 2B are cross-sectional views illustrating structure examples of a display device;

FIGS. 3A and 3B are cross-sectional views illustrating structure examples of a display device;

FIGS. 4A and 4B are cross-sectional views illustrating a structure example of a display device;

FIGS. 5A and 5B are cross-sectional views illustrating a structure example of a display device;

FIGS. 6A and 6B are cross-sectional views illustrating a structure example of a display device;

FIGS. 7A and 7B are cross-sectional views illustrating a structure example of a display device;

FIGS. 8A and 8B are cross-sectional views illustrating a structure example of a display device;

FIGS. 9A and 9B are cross-sectional views illustrating a structure example of a display device;

FIGS. 10A and 10B are cross-sectional views illustrating structure examples of a display device;

FIGS. 11A to 11C are cross-sectional views illustrating structure examples of a display device;

FIGS. 12A and 12B are cross-sectional views illustrating structure examples of a display device;

FIGS. 13A and 13B are cross-sectional views illustrating a structure example of a display device;

FIGS. 14A and 14B are cross-sectional views illustrating structure examples of a display device;

FIG. 15 is a cross-sectional view illustrating a structure example of a display device;

FIGS. 16A1, 16A2, 16B1, 16B2, and 16C are cross-sectional views illustrating an example of a method for manufacturing a display device;

FIGS. 17A1, 17A2, 17B1, and 17B2 are cross-sectional views illustrating an example of a method for manufacturing a display device;

FIGS. 18A1, 18A2, 18B1, and 18B2 are cross-sectional views illustrating an example of a method for manufacturing a display device;

FIGS. 19A to 19D are cross-sectional views illustrating an example of a method for manufacturing a display device;

FIGS. 20A to 20C are cross-sectional views illustrating an example of a method for manufacturing a display device;

FIGS. 21A and 21B are cross-sectional views illustrating an example of a method for manufacturing a display device;

FIGS. 22A and 22B are cross-sectional views illustrating an example of a method for manufacturing of a display device;

FIGS. 23A and 23B are cross-sectional views illustrating an example of a method for manufacturing of a display device;

FIGS. 24A and 24B are cross-sectional views illustrating an example of a method for manufacturing a display device;

FIGS. 25A and 25B are cross-sectional views illustrating an example of a method for manufacturing of a display device;

FIGS. 26A to 26E are cross-sectional views illustrating an example of a method for manufacturing a display device;

FIGS. 27A to 27D are cross-sectional views illustrating an example of a method for manufacturing a display device;

FIGS. 28A to 28G are top views illustrating structure examples of pixels;

FIGS. 29A to 291 are top views illustrating structure examples of pixels;

FIGS. 30A and 30B are perspective views illustrating a structure example of a display module;

FIGS. 31A and 31B are cross-sectional views each illustrating a structure example of a display device;

FIG. 32 is a cross-sectional view illustrating a structure example of a display device;

FIG. 33 is a cross-sectional view illustrating a structure example of a display device;

FIG. 34 is a cross-sectional view illustrating a structure example of a display device;

FIG. 35 is a cross-sectional view illustrating a structure example of a display device;

FIG. 36 is a cross-sectional view illustrating a structure example of a display device;

FIG. 37 is a perspective view illustrating a structure example of a display device;

FIG. 38A is a cross-sectional view illustrating a structure example of a display device, and FIGS. 38B and 38C are cross-sectional views each illustrating a structure example of a transistor;

FIGS. 39A to 39D are cross-sectional views illustrating structure examples of a display device;

FIGS. 40A to 40F are cross-sectional views illustrating structure examples of a light-emitting element;

FIGS. 41A to 41C are cross-sectional views illustrating structure examples of a light-emitting element;

FIGS. 42A to 42D illustrate examples of electronic devices;

FIGS. 43A to 43F illustrate examples of electronic devices; and

FIGS. 44A to 44G illustrate examples of electronic devices.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, or the like of each structure illustrated in drawings is not accurately represented in some cases for easy understanding. Therefore, the disclosed invention is not necessarily limited to the position, size, range, or the like disclosed in the drawings.

In this specification and the like, terms for describing arrangement, such as “over”, “under”, “above”, and “below”, are sometimes used for convenience to describe the positional relation between components with reference to drawings. Furthermore, the positional relation between components changes as appropriate in accordance with the direction in which each component is described. Thus, the positional relation is not limited to that described with a term used in this specification and the like and can be explained with another term as appropriate depending on the situation. For example, the expression “an insulating layer over a conductive layer” can be replaced with the expression “an insulating layer under a conductive layer” when the direction of a diagram showing these components is rotated by 180°.

Note that the terms “film” and “layer” can be interchanged with each other depending on the situation or circumstances. For example, the term “conductive layer” can be changed into the term “conductive film” in some cases. As another example, the term “insulating film” can be changed into the term “insulating layer” in some cases.

### Embodiment 1

In this embodiment, a display device of one embodiment of the present invention and a manufacturing method thereof will be described.

The display device of one embodiment of the present invention includes a light-emitting element. The light-emitting element includes an EL layer between a pair of electrodes. The EL layer includes at least a light-emitting layer. The EL layer can also include a carrier-injection layer, a carrier-transport layer, and a carrier-blocking layer, for example.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that in some cases, the above-described carrier-injection layer, carrier-transport layer, and carrier-blocking layer cannot be distinguished from each other depending on the cross-sectional shape, properties, or the like. One layer may have two or three functions of the carrier-injection layer, the carrier-transport layer, and the carrier-blocking layer in some cases.

The display device of one embodiment of the present invention is capable of full-color display. For example, a display device capable of full-color display can be manufactured by separately forming EL layers of different emission colors. As another example, a display device capable of full-color display can be manufactured by providing a coloring layer (also referred to as a color filter) over an EL layer that emits white light.

In this specification and the like, a structure in which at least light-emitting layers are separately formed for light-emitting elements with different emission wavelengths is referred to as a side-by-side (SBS) structure in some cases. The SBS structure can optimize materials and structures of light-emitting elements and thus can extend freedom of choice of materials and structures, whereby the luminance and the reliability can be easily improved. In contrast, in the case where a coloring layer is provided over an EL layer that emits white light, for example, the manufacturing process can be simplified compared to that for a display device having the SBS structure, and the display device can be manufactured at low cost.

In the case of manufacturing a display device including a plurality of light-emitting elements that emit light of different colors, light-emitting layers different in emission color need to be formed in an island shape. Also in the case of manufacturing a display device in which all light-emitting elements exhibit the same emission color, e.g., white, it is preferable to form light-emitting layers in an island shape, in which case leakage current that would be generated between adjacent light-emitting elements through a light-emitting layer can be reduced.

Note that in this specification and the like, the term “island shape” refers to a state where two or more layers formed using the same material in the same step are physically separated from each other. For example, “island-shaped light-emitting layer” means a state where the light-emitting layer and its adjacent light-emitting layer are physically separated from each other.

For example, an island-shaped light-emitting layer can be formed by a vacuum evaporation method using a metal mask. However, this method causes a deviation from the designed shape and position of an island-shaped light-emitting layer due to various influences such as the low accuracy of the metal mask position, the positional deviation between the metal mask and a substrate, a warp of the metal mask, and the vapor-scattering-induced expansion of outline of the formed film; accordingly, it is difficult to achieve high resolution and a high aperture ratio of the display device. In addition, the outline of the layer may blur during vapor deposition, whereby the thickness of an end portion may be small. That is, the thickness of the island-shaped light-emitting layer may vary from area to area. In the case of manufacturing a display device with a large size, high definition, or high resolution, the manufacturing yield might be reduced because of low dimensional accuracy of the metal mask and deformation due to heat or the like.

In view of the above, to manufacture the display device of one embodiment of the present invention, a light-emitting layer is processed into a fine pattern by a photolithography method without using a shadow mask such as a metal mask. Specifically, after a pixel electrode is formed in each subpixel to be in contact with a base insulating layer, for example, a light-emitting layer is formed over a plurality of pixel electrodes. Then, the light-emitting layer is processed by a photolithography method so that one island-shaped light-emitting layer is formed for every pixel electrode. Thus, the light-emitting layer can be divided into island-shaped light-emitting layers for respective subpixels.

In this specification and the like, a device formed using a metal mask or a fine metal mask (FMM) may be referred to as a device having a metal mask (MM) structure. In this specification and the like, a device formed without using a metal mask or an FMM may be referred to as a device having a metal maskless (MML) structure.

One of the ways of processing a light-emitting layer into an island shape is to perform processing by a photolithography method directly on the light-emitting layer. In this way, damage to the light-emitting layer (e.g., process damage) might significantly degrade the reliability. In view of the above, to manufacture the display device of one embodiment of the present invention, a mask layer (also referred to as a sacrificial layer, a protective layer, or the like), for example, is preferably formed over a functional layer (e.g., a carrier-blocking layer, a carrier-transport layer, or a carrier-injection layer, and specifically, a hole-blocking layer, an electron-transport layer, or an electron-injection layer) above the light-emitting layer, followed by the processing of the light-emitting layer and the functional layer into an island shape. Such a method provides a highly reliable display device. The functional layer between the light-emitting layer and the mask layer can inhibit the light-emitting layer from being exposed on the outermost surface during the manufacturing process of the display device and can reduce damage to the light-emitting layer.

In this specification and the like, a mask layer refers to a layer that is positioned above at least a light-emitting layer (specifically, a layer processed into an island shape among layers included in an EL layer) and has a function of protecting the light-emitting layer in the manufacturing process.

An EL layer can include a functional layer below as well as above a light-emitting layer. Here, in the case where the light-emitting layer is processed into an island shape, a functional layer positioned below the light-emitting layer (e.g., a carrier-injection layer, a carrier-transport layer, or a carrier-blocking layer, and specifically, a hole-injection layer, a hole-transport layer, or an electron-blocking layer) is preferably processed into an island shape with the same pattern as the light-emitting layer. When the layer positioned below the light-emitting layer is processed into an island shape with the same pattern as the light-emitting layer, a leakage current that would occur between adjacent subpixels (sometimes referred to as a horizontal leakage current or a lateral leakage current) can be reduced. For example, in the case where a hole-injection layer is shared by adjacent subpixels, a horizontal leakage current would be generated because of the hole-injection layer. In contrast, in the display device of one embodiment of the present invention, the hole-injection layer can be processed into an island shape with the same pattern as the light-emitting layer; hence, a horizontal leakage current between adjacent subpixels is not substantially generated or a horizontal leakage current can be extremely small.

Here, the EL layer is preferably provided to cover a pixel electrode. In that case, the aperture ratio can be higher than that of a structure in which an end portion of an EL layer is positioned on the inner side of an end portion of a pixel electrode.

On the other hand, when the EL layer is provided to cover the pixel electrode, disconnection or local thinning, for example, occurs in the EL layer in some cases. In view of the above, in one embodiment of the present invention, a pixel electrode includes a tapered portion where the taper angle is less than 90° in the cross section. Thus, the coverage of the pixel electrode with the EL layer is improved and occurrence of disconnection and local thinning, for example, can be inhibited in the EL layer, as compared to the case where a pixel electrode does not have a tapered portion, that is, the case where a pixel electrode includes a region whose taper angle is 90°, for example. Accordingly, the display device of one embodiment of the present invention can be highly reliable.

In this specification and the like, disconnection refers to a phenomenon in which a layer, a film, or an electrode is split because of the shape of the formation surface (e.g., a level difference).

Here, in the case where the pixel electrode includes a tapered portion, the pixel electrode preferably includes a first conductive layer and a second conductive layer that covers the top surface and the side surface of the first conductive layer, and the side surface of the first conductive layer is preferably tapered with a taper angle less than 90° in the cross section. In that case, the second conductive layer can include a flat portion that overlaps the top surface of the first conductive layer, a flat portion that does not overlap the top surface of the first conductive layer, and a tapered portion between these two flat portions. The tapered portion includes a region overlapping the side surface of the first conductive layer.

In this specification and the like, a tapered shape refers to a shape such that at least part of a side surface of a component is inclined with respect to the substrate surface. For example, a tapered shape refers to a shape including a region where the angle between the inclined side surface and the substrate surface (also referred to as a taper angle) is less than 90°. Note that the side surface of the component and the substrate surface are not necessarily completely flat and may be substantially flat with a slight curvature or with slight unevenness. In this specification and the like, a tapered portion refers to a region having a tapered shape.

When the pixel electrode includes two or more flat portions and a tapered portion between the two flat portions as described above, the coverage of the pixel electrode with the EL layer is favorably improved and occurrence of disconnection and local thinning, for example, in the EL layer can be favorably inhibited. Thus, the reliability of the display device of one embodiment of the present invention can be favorably increased.

Characteristics required for the pixel electrode are wide in range. Thus, in the display device of one embodiment of the present invention, at least one of the first conductive layer and the second conductive layer has a stacked-layer structure including a plurality of layers containing different materials. For example, the second conductive layer has a three-layer structure of a first layer, a second layer over the first layer, and a third layer over the second layer.

For the first conductive layer, it is possible to use a material that is hardly oxidized and has electrical resistivity unlikely to increase significantly even when being oxidized. For example, for the first conductive layer, it is possible to use a material that is less likely to be oxidized than aluminum and whose oxide has a lower electric resistivity than aluminum oxide. For example, the first conductive layer can be formed using titanium. Alternatively, the first conductive layer can be formed using an alloy containing titanium. In this manner, a change in properties of the first conductive layer is inhibited, and the display device of one embodiment of the present invention can have high reliability.

As described above, the second conductive layer can have a three-layer structure of a first layer, a second layer over the first layer, and a third layer over the second layer, for example. The first layer has higher adhesion to the second layer than a base insulating layer does, for example. For the first layer, an oxide containing one or more selected from indium, tin, zinc, gallium, titanium, aluminum, and silicon, for example, can be used. For example, for the first layer, indium tin oxide (also referred to as ITO) or indium tin oxide containing silicon (also referred to as ITSO) can be used. In this manner, peeling of the second layer is inhibited, and the display device of one embodiment of the present invention can have high reliability. Note that the display device of one embodiment of the present invention can be configured such that the first layer is in contact with the base insulating layer and the second layer is not in contact with the base insulating layer.

The second layer has higher visible light reflectance than the first conductive layer, the first layer, and the third layer. For the second layer, a material that has higher visible light reflectance than aluminum, such as silver or an alloy containing silver, can be used, for example. In this manner, the display device of one embodiment of the present invention can have high outcoupling efficiency.

In this specification and the like, visible light refers to light with a wavelength greater than or equal to 400 nm and less than 750 nm.

In the case where a functional layer positioned below the light-emitting layer includes at least one of a hole-injection layer and a hole-transport layer, for example, and the third layer is in contact with the functional layer, a layer that has a higher work function than the second layer is used as the third layer. That is, in the case where the pixel electrode functions as an anode, the third layer has a higher work function than the second layer. When the third layer has a high work function, holes can be easily injected into the functional layer, which results in lower driving voltage of the light-emitting element. For the third layer, a material similar to the material usable for the first layer can be used, for example. For example, the first layer and the third layer can be formed using the same kind of material.

In the above manner, the display device of one embodiment of the present invention can have high reliability and high outcoupling efficiency. In addition, the display device of one embodiment of the present invention can include a light-emitting element with low driving voltage.

Note that it is not necessary to form all layers included in the EL layers separately between the light-emitting elements that emit light of different colors, and some layers can be formed in the same step. In the method for manufacturing the display device of one embodiment of the present invention, some layers included in the EL layer are formed into an island shape separately for each color, and then at least part of the mask layer is removed. After that, the other layer included in the EL layers (sometimes referred to as a common layer) and a common electrode (also referred to as an upper electrode) are formed to be shared by the light-emitting elements of different colors (formed as one film across the light-emitting elements of different colors). For example, a carrier-injection layer and the common electrode can be formed to be shared by the light-emitting elements of different colors.

The carrier-injection layer is often a layer having relatively high conductivity in the EL layer. Therefore, when the carrier-injection layer is in contact with a side surface of any layer included in the EL layer formed in an island shape or a side surface of the pixel electrode, the light-emitting element might be short-circuited. Note that also in the case where the carrier-injection layer is formed in an island shape and the common electrode is shared by light-emitting elements of different colors, the light-emitting element might be short-circuited when the common electrode is in contact with a side surface of the EL layer or a side surface of the pixel electrode.

In view of the above, the display device of one embodiment of the present invention includes an insulating layer covering at least the side surface of the island-shaped light-emitting layer. The insulating layer preferably covers part of the top surface of the island-shaped light-emitting layer.

Thus, at least some layer in the EL layer formed in an island shape and the pixel electrode can be prevented from being in contact with the carrier-injection layer or the common electrode. Hence, a short circuit in the light-emitting element is prevented, and the reliability of the light-emitting element can be increased.

In a cross-sectional view, the side surface of the insulating layer preferably has a tapered shape with a taper angle less than 90°. This prevents a connection defect caused by disconnection of the common layer and the common electrode provided over the insulating layer, and prevents an increase in electrical resistance caused by local thinning of the common layer and the common electrode.

In the above manner, in the method for manufacturing the display device of one embodiment of the present invention, the island-shaped light-emitting layer is formed by processing a light-emitting layer formed on the entire surface, not by using a metal mask having a fine metal mask. Accordingly, a high-resolution display device or a display device with a high aperture ratio, which has been difficult to achieve so far, can be obtained. Light-emitting layers can be formed separately for the respective colors, enabling the display device to perform extremely clear display with high contrast and high display quality. Moreover, providing the mask layer over the light-emitting layer can reduce damage to the light-emitting layer in the manufacturing process of the display device, resulting in an increase in reliability of the light-emitting element.

A formation method using a fine metal mask, for example, does not easily reduce the distance between adjacent light-emitting elements to less than 10 μm. Meanwhile, the method using photolithography according to one embodiment of the present invention can shorten the distance between adjacent light-emitting elements, the distance between adjacent EL layers, or the distance between adjacent pixel electrodes to less than 10 μm, 5 μm or less, 3 μm or less, 2 μm or less, 1.5 μm or less, 1 μm or less, or even 0.5 μm or less, for example, in a process over a glass substrate. Using a light exposure apparatus for LSI can further shorten the distance between adjacent light-emitting elements, the distance between adjacent EL layers, or the distance between adjacent pixel electrodes to 500 nm or less, 200 nm or less, 100 nm or less, or even 50 nm or less, for example, in a process over a Si wafer. Accordingly, the area of a non-light-emitting region that may exist between two light-emitting elements can be significantly reduced, and the aperture ratio can be close to 100%. For example, the aperture ratio of the display device of one embodiment of the present invention is higher than or equal to 40%, higher than or equal to 50%, higher than or equal to 60%, higher than or equal to 70%, higher than or equal to 80%, or higher than or equal to 90%; that is, an aperture ratio lower than 100% can be achieved.

Increasing the aperture ratio of the display device can improve the reliability of the display device. Specifically, with reference to the lifetime of a display device including an organic EL element and having an aperture ratio of 10%, a display device having an aperture ratio of 20% (i.e., having an aperture ratio two times the reference) has a lifetime approximately 3.25 times the reference, and a display device having an aperture ratio of 40% (i.e., having an aperture ratio four times the reference) has a lifetime approximately 10.6 times the reference. Thus, the density of current flowing to the organic EL element can be reduced with the increasing aperture ratio, and accordingly the lifetime of the display device can be increased. The display device of one embodiment of the present invention can have a higher aperture ratio and thus can have higher display quality. Furthermore, the display device of one embodiment of the present invention has excellent effect that the reliability (especially the lifetime) can be significantly improved with the increasing aperture ratio.

A pattern of the light-emitting layer itself can be made much smaller than that in the case of using a fine metal mask. For example, in the case of using a metal mask for forming light-emitting layers separately, a variation in the thickness of the pattern occurs between the center and the edge of the pattern. This causes a reduction in an effective area that can be used as a light-emitting region with respect to the entire pattern area. In contrast, in the above manufacturing method, the film with a uniform thickness is processed, so that island-shaped light-emitting layers can be formed to have a uniform thickness. Accordingly, even with a fine pattern, almost the all area of the light-emitting layer can be used as a light-emitting region. Thus, a display device having both high resolution and a high aperture ratio can be manufactured. Furthermore, the display device can be reduced in size and weight.

Specifically, the display device of one embodiment of the present invention can have a pixel density of, for example, 2000 ppi or more, preferably 3000 ppi or more, further preferably 5000 ppi or more, still further preferably 6000 ppi or more and 20000 ppi or less or 30000 ppi or less.

### [Structure Example 1]

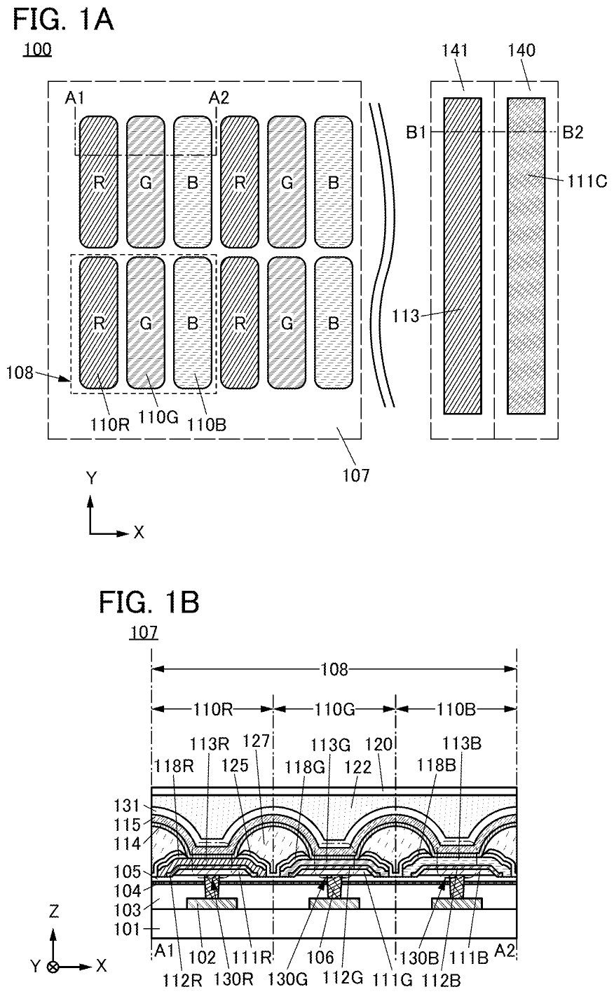

FIG. 1A is a top view illustrating a structure example of a display device 100. The display device 100 includes a pixel portion 107 in which a plurality of pixels 108 are arranged in matrix. The pixel 108 includes a subpixel 110R, a subpixel 110G, and a subpixel 110B. FIG. 1A illustrates subpixels 110 arranged in two rows and six columns, which form pixels 108 in two rows and two columns.

In this specification and the like, for example, a description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 107. The pixel portion 107 can therefore be referred to as a display portion. Note that in this embodiment, three colors of red (G), light (G), and blue (B) are given as colors of light emitted by subpixels; however, the subpixels may emit light of three colors of yellow (Y), cyan (C), and magenta (M), for example. The number of types of subpixels is not limited to three, and four or more types of subpixels may be used. Examples of four subpixels include subpixels emitting light of four colors R, G, and B, and white (W), subpixels emitting light of four colors R, G, and B, and Y, and subpixels emitting light of colors, R, G, and B and emitting infrared light (IR).

It can also be said that stripe arrangement is employed for the pixels 108 illustrated in FIG. 1A. An arrangement method applicable to the pixels 108 will be described in detail in a later embodiment.

In this specification and the like, the row direction and the column direction are sometimes referred to as the X direction and the Y direction, respectively. The X direction and the Y direction intersect with each other and are perpendicular to each other, for example.

FIG. 1A illustrates an example where subpixels of different colors are arranged in the X direction and subpixels of the same color are arranged in the Y direction. Note that subpixels of different colors may be arranged in the Y direction, and subpixels of the same color may be arranged in the X direction.

A region 141 and a connection portion 140 are provided outside the pixel portion 107, and the region 141 is positioned between the pixel portion 107 and the connection portion 140. An EL layer 113 is provided in the region 141. A conductive layer 111C is provided in the connection portion 140.

Although FIG. 1A illustrates an example where the region 141 and the connection portion 140 are positioned on the right side of the pixel portion 107 in the top view, the position of the region 141 and the connection portion 140 is not particularly limited. The region 141 and the connection portion 140 are provided in at least one of the upper side, the right side, the left side, and the lower side of the pixel portion 107 in the top view, and may be provided so as to surround the four sides of the pixel portion 107. The top surface shape of the region 141 and the connection portion 140 can be a belt-like shape, an L shape, a U shape, a frame-like shape, or the like. The number of regions 141 and the number of connection portions 140 can each be one or more.

FIG. 1B is a cross-sectional view along the dashed-dotted line A1-A2 in FIG. 1A and illustrates a structure example of the pixel 108 provided in the pixel portion 107. FIG. 1B is a cross-sectional view in the XZ plane.

In this specification and the like, the X direction may be referred to as the horizontal direction, and the Z direction may be referred to as the height direction or the vertical direction. The Y direction may be referred to as the horizontal direction. The X direction, Y direction, and Z direction can be perpendicular to each other to express a three-dimensional space.

As illustrated in FIG. 1B, the display device 100 includes an insulating layer 101, a conductive layer 102 over the insulating layer 101, an insulating layer 103 over the insulating layer 101 and the conductive layer 102, an insulating layer 104 over the insulating layer 103, and an insulating layer 105 over the insulating layer 104. The insulating layer 101 is provided over a substrate (not illustrated). An opening reaching the conductive layer 102 is provided in the insulating layers 105, 104, and 103, and a plug 106 is provided to fill the opening.

In the pixel portion 107, a light-emitting element 130 is provided over the insulating layer 105 and the plug 106. The insulating layer 105 can be referred to as a base insulating layer because the light-emitting element 130 is provided over the insulating layer 105. A protective layer 131 is provided to cover the light-emitting element 130. A substrate 120 is bonded to the protective layer 131 with a resin layer 122. An insulating layer 125 and an insulating layer 127 over the insulating layer 125 are provided between the adjacent light-emitting elements 130.

Although FIG. 1B shows cross sections of a plurality of insulating layers 125 and a plurality of insulating layers 127, the insulating layers 125 are connected to each other and the insulating layers 127 are connected to each other when the display device 100 is seen from above. In other words, the display device 100 can be configured to include one insulating layer 125 and one insulating layer 127, for example. Note that the display device 100 may include a plurality of insulating layers 125 that are separated from each other and a plurality of insulating layers 127 that are separated from each other.

In FIG. 1B, a light-emitting element 130R, a light-emitting element 130G, and a light-emitting element 130B are shown as the light-emitting element 130. The light-emitting elements 130R, 130G, and 130B emit light of different colors. For example, the light-emitting element 130R can emit red light, the light-emitting element 130G can emit green light, and the light-emitting element 130B can emit blue light. Alternatively, the light-emitting element 130R, the light-emitting element 130G, or the light-emitting element 130B may emit cyan light, magenta light, yellow light, white light, infrared light, or the like.

The display device of one embodiment of the present invention can be, for example, a top-emission display device where light is emitted in the direction opposite to a substrate over which light-emitting elements are formed.

As the light-emitting element 130, an organic light-emitting diode (OLED) or a quantum-dot light-emitting diode (QLED) is preferably used, for example. Examples of a light-emitting substance included in the light-emitting element 130 include a substance exhibiting fluorescence (a fluorescent material), a substance exhibiting phosphorescence (a phosphorescent material), an inorganic compound (e.g., a quantum dot material), and a substance exhibiting thermally activated delayed fluorescence (a thermally activated delayed fluorescent (TADF) material). Alternatively, a light-emitting diode (LED) such as a micro-LED can be used as the light-emitting element 130.

The light-emitting element 130R includes a conductive layer 111R over the plug 106 and the insulating layer 105, a conductive layer 112R covering the top surface and the side surface of the conductive layer 111R, an EL layer 113R covering the top surface and the side surface of the conductive layer 112R, a common layer 114 over the EL layer 113R, and a common electrode 115 over the common layer 114. Here, the conductive layer 111R can include a region in contact with the plug 106 and the insulating layer 105, for example. The conductive layer 112R can include a region in contact with the conductive layer 111R and the insulating layer 105, for example. The conductive layers 111R and 112R form a pixel electrode of the light-emitting element 130R. Note that in the light-emitting element 130R, the EL layer 113R and the common layer 114 can be collectively referred to as an EL layer.

The light-emitting element 130G includes a conductive layer 111G over the plug 106 and the insulating layer 105, a conductive layer 112G covering the top surface and the side surface of the conductive layer 111G, an EL layer 113G covering the top surface and the side surface of the conductive layer 112G, the common layer 114 over the EL layer 113G, and the common electrode 115 over the common layer 114. Here, the conductive layer 111G can include a region in contact with the plug 106 and the insulating layer 105, for example. The conductive layer 112G can include a region in contact with the conductive layer 111G and the insulating layer 105, for example. The conductive layers 111G and 112G form a pixel electrode of the light-emitting element 130G. Note that in the light-emitting element 130G, the EL layer 113G and the common layer 114 can be collectively referred to as an EL layer.

The light-emitting element 130B includes a conductive layer 111B over the plug 106 and the insulating layer 105, a conductive layer 112B covering the top surface and the side surface of the conductive layer 111B, an EL layer 113B covering the top surface and the side surface of the conductive layer 112B, the common layer 114 over the EL layer 113B, and the common electrode 115 over the common layer 114. Here, the conductive layer 111B can include a region in contact with the plug 106 and the insulating layer 105, for example. The conductive layer 112B can include a region in contact with the conductive layer 111B and the insulating layer 105, for example. The conductive layers 111B and 112B form a pixel electrode of the light-emitting element 130B. Note that in the light-emitting element 130B, the EL layer 113B and the common layer 114 can be collectively referred to as an EL layer.

In the light-emitting element, one of the pixel electrode and the common electrode functions as an anode and the other functions as a cathode. Hereinafter, the pixel electrode may function as the anode and the common electrode may function as the cathode unless otherwise specified.

Each of the EL layers 113R, 113G, and 113B includes at least a light-emitting layer. For example, the EL layer 113R, the EL layer 113G, and the EL layer 113B can respectively include a light-emitting layer that emits red light, a light-emitting layer that emits green light, and a light-emitting layer that emits blue light. The EL layer 113R, the EL layer 113G, or the EL layer 113B may emit cyan light, magenta light, yellow light, white light, infrared light, or the like.

The EL layer 113R, the EL layer 113G, and the EL layer 113B are separated from each other. Providing the island-shaped EL layer 113 in each light-emitting element 130 can suppress a leakage current between the adjacent light-emitting elements 130. This can prevent crosstalk due to unintended light emission, so that a display device with extremely high contrast can be obtained. Specifically, a display device having high current efficiency at low luminance can be obtained.

The island-shaped EL layer 113 can be formed by forming an EL film and processing the EL film by a photolithography method, for example. For example, the EL layer 113R can be formed by forming and processing an EL film to be EL layer 113R, the EL layer 113G can be formed by forming and processing an EL film to be the EL layer 113G, and the EL layer 113B can be formed by forming and processing an EL film to be the EL layer 113B.

The EL layer 113 is provided to cover the pixel electrode of the light-emitting element 130. Thus, the aperture ratio of the display device 100 can be increased as compared to the structure where the end portion of the EL layer 113 is positioned on the inner side of the end portion of the pixel electrode. Covering the side surface of the pixel electrode of the light-emitting element 130 with the EL layer 113 can prevent the pixel electrode from being in contact with the common electrode 115; hence, a short circuit of the light-emitting element 130 can be prevented. Furthermore, the distance between the light-emitting region (i.e., the region overlapping the pixel electrode) in the EL layer 113 and the end portion of the EL layer 113 can be increased. Since the end portion of the EL layer 113 might be damaged by processing, using a region that is away from the end portion of the EL layer 113 as the light-emitting region may increase the reliability of the light-emitting element 130.

For the conductive layers 111 and 112, a metal can be used, for example. Specifically, it is possible to use a metal such as titanium (Ti), silver (Ag), aluminum (Al), magnesium (Mg), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), yttrium (Y), or neodymium (Nd) or an alloy containing an appropriate combination of any of these metals. As the alloy material, an alloy containing silver, such as an alloy of silver, palladium, and copper (Ag—Pd—Cu, or APC), can be used. As the alloy material, an alloy containing aluminum, such as an alloy of aluminum, nickel, and lanthanum (Al—Ni—La), can also be used.

For the conductive layers 111 and 112, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium titanium oxide, zinc titanate, aluminum zinc oxide, indium zinc oxide containing gallium, indium zinc oxide containing aluminum, indium tin oxide containing silicon, indium zinc oxide containing silicon, and the like. Structures and particularly preferred materials for the conductive layers 111 and 112 will be described later.

In FIG. 1B, an insulating layer (also referred to as a bank or a component) that covers an upper end portion of the conductive layer 112R is not provided between the conductive layer 112R and the EL layer 113R. An insulating layer that covers an upper end portion of the conductive layer 112G is not provided between the conductive layer 112G and the EL layer 113G. An insulating layer that covers an upper end portion of the conductive layer 112B is not provided between the conductive layer 112B and the EL layer 113B. Thus, the distance between the adjacent light-emitting elements 130 can be extremely small. Accordingly, the display device can have high resolution or high definition. In addition, a mask for forming the insulating layers is not needed, which leads to a reduction in manufacturing cost of the display device.

Furthermore, light emitted by the EL layer 113 can be extracted efficiently with the structure where an insulating layer covering the end portion of the conductive layer 112 is not provided between the conductive layer 112 and the EL layer 113, i.e., the structure where an insulating layer is not provided between the conductive layer 112 and the EL layer 113. Therefore, the viewing angle dependence of the display device 100 can be extremely small. A small viewing angle dependence leads to an increase in visibility of images on the display device 100. For example, in the display device 100, the viewing angle (the maximum angle at which a given constant ratio is maintained when the screen is seen in an oblique direction) can be greater than or equal to 100° and less than 180°, preferably greater than or equal to 150° and less than or equal to 170°. Note that the viewing angle refers to that in both the vertical direction and the horizontal direction.

The insulating layers 101, 103, and 105 function as interlayer insulating layers. As the insulating layers 101, 103, and 105, a variety of inorganic insulating films such as an oxide insulating film, a nitride insulating film, an oxynitride insulating film, and a nitride oxide insulating film can be suitably used; specifically, a silicon oxide film, a silicon oxynitride film, an aluminum oxide film, a silicon nitride film, or a silicon nitride oxide film can be used, for example.

Note that in this specification and the like, oxynitride refers to a material that contains more oxygen than nitrogen, and nitride oxide refers to a material that contains more nitrogen than oxygen. For example, silicon oxynitride refers to a material in which an oxygen content is higher than a nitrogen content, and silicon nitride oxide refers to a material in which a nitrogen content is higher than an oxygen content.

The insulating layer 104 functions as a barrier layer that inhibits entry of impurities such as water into the light-emitting element 130, for example. As the insulating layer 104, for example, a film in which hydrogen or oxygen is less likely to diffuse than in a silicon oxide film can be used. Examples of such a film include a silicon nitride film, an aluminum oxide film, and a hafnium oxide film.

The thickness of the insulating layer 105 in a region not overlapped by the conductive layer 111 is sometimes smaller than that of the insulating layer 105 in a region overlapped by the conductive layer 111. That is, the insulating layer 105 may have a depression portion in the region not overlapped by the conductive layer 111. In other words, the insulating layer 105 may have a projection portion in the region overlapped by the conductive layer 111. The depression and projection of the insulating layer 105 are formed because of the step of forming the conductive layer 111, for example.

The conductive layer 102 functions as a wiring. The conductive layer 102 is electrically connected to the light-emitting element 130 through the plug 106.

For the conductive layer 102 and the plug 106, it is possible to use a variety of conductive materials, for example, a metal such as aluminum (Al), magnesium (Mg), titanium (Ti), chromium (Cr), nickel (Ni), copper (Cu), yttrium (Y), zirconium (Zr), tin (Sn), zinc (Zn), silver (Ag), platinum (Pt), gold (Au), molybdenum (Mo), tantalum (Ta), or tungsten (W) or an alloy containing the metal as its main component. As the alloy, a silver-containing alloy, such as an alloy of silver, palladium, and copper (APC), can be used, for example. For the conductive layer 102 and the plug 106, an oxide such as tin oxide or zinc oxide may be used.

The light-emitting element 130 may employ a single structure (a structure including only one light-emitting unit) or a tandem structure (a structure including a plurality of light-emitting units). The light-emitting unit includes at least one light-emitting layer.

As described above, each of the EL layers 113R, 113G, and 113B includes at least a light-emitting layer. For example, the EL layer 113R, the EL layer 113G, and the EL layer 113B can respectively include a light-emitting layer that emits red light, a light-emitting layer that emits green light, and a light-emitting layer that emits blue light.

In the case of using a tandem light-emitting element, for example, the EL layer 113R can include a plurality of light-emitting units that emit red light, the EL layer 113G can include a plurality of light-emitting units that emit green light, and the EL layer 113B can include a plurality of light-emitting units that emit blue light. A charge-generation layer is preferably provided between the light-emitting units.

Each of the EL layers 113R, 113G, and 113B may include one or more of a hole-injection layer, a hole-transport layer, a hole-blocking layer, a charge-generation layer, an electron-blocking layer, an electron-transport layer, and an electron-injection layer.

In this specification and the like, a functional layer refers to a layer that is included in the EL layer and is other than a light-emitting layer and a charge-generation layer. The functional layer can include, for example, one or more of the above-described hole-injection layer, hole-transport layer, hole-blocking layer, electron-blocking layer, electron-transport layer, and electron-injection layer. Note that a charge-generation layer is included in the category of the functional layer in some cases.

The upper temperature limit of the compounds included in the EL layers 113R, 113G, and 113B is preferably higher than or equal to 100° C. and lower than or equal to 180° C., further preferably higher than or equal to 120° C. and lower than or equal to 180° C., still further preferably higher than or equal to 140° C. and lower than or equal to 180° C. For example, the glass transition temperature (Tg) of these compounds is preferably higher than or equal to 100° C. and lower than or equal to 180° C., further preferably higher than or equal to 120° C. and lower than or equal to 180° C., still further preferably higher than or equal to 140° C. and lower than or equal to 180° C.

In particular, the upper temperature limit of the functional layer provided over the light-emitting layer is preferably high. It is further preferable that the upper temperature limit of the functional layer provided on and in contact with the light-emitting layer be high. When such a functional layer has high heat resistance, the light-emitting layer can be effectively protected, resulting in less damage to the light-emitting layer.

The upper temperature limit of the light-emitting layer is preferably high. This inhibits a reduction in light emission efficiency due to damage to the light-emitting layer by heating and a decrease in lifetime.

The structure and materials of the light-emitting element included in the display device of one embodiment of the present invention will be described in detail in a later embodiment.

In the case where the conductive layers 111 and 112 function as the anode and the common electrode 115 functions as the cathode, the common layer 114 includes at least one of an electron-injection layer and an electron-transport layer and, for example, includes an electron-injection layer. Alternatively, the common layer 114 may include a stack of an electron-transport layer and an electron-injection layer. Meanwhile, in the case where the conductive layers 111 and 112 function as the cathode and the common electrode 115 functions as the anode, the common layer 114 includes at least one of a hole-injection layer and a hole-transport layer and, for example, includes a hole-injection layer. Alternatively, the common layer 114 may include a stack of a hole-transport layer and a hole-injection layer. The common layer 114 is shared by the light-emitting elements 130R, 130G, and 130B. Note that the common layer 114 is not necessarily provided in the display device 100.

Like the common layer 114, the common electrode 115 is shared by the light-emitting elements 130R, 130G, and 130B.

In the example illustrated in FIG. 1B, a mask layer 118R is positioned over the EL layer 113R included in the light-emitting element 130R, a mask layer 118G is positioned over the EL layer 113G included in the light-emitting element 130G, and a mask layer 118B is positioned over the EL layer 113B included in the light-emitting element 130B. The mask layer 118R is the remainder of the mask layer provided in contact with the top surface of the EL layer 113R at the time of processing the EL layer 113R. Similarly, the mask layer 118G is the remainder of the mask layer provided at the time of forming the EL layer 113G, and the mask layer 118B is the remainder of the mask layer provided at the time of forming the EL layer 113B. In this manner, the mask layer used to protect the EL layer at the time of forming the EL layer may partly remain in the display device 100. Two or all of the mask layers 118R, 118G, and 118B may be formed using the same material, or they may be formed using different materials. Note that hereinafter the mask layers 118R, 118G, and 118B may be collectively referred to as the mask layer 118.

In FIG. 1B, one end portion of the mask layer 118R is aligned or substantially aligned with an end portion of the EL layer 113R, and the other end portion of the mask layer 118R is positioned over the EL layer 113R. Here, the other end portion of the mask layer 118R preferably overlaps the conductive layer 111R. In that case, the other end portion of the mask layer 118R is likely to be formed on a substantially flat surface of the EL layer 113R. The same applies to the mask layers 118G and 118B. The mask layer 118 remains between the top surface of the EL layer 113 processed into an island shape and the insulating layer 125, for example.

In the case where end portions are aligned or substantially aligned with each other and the case where top surface shapes are the same or substantially the same, it can be said that outlines of stacked layers overlap each other at least partly in a top view. For example, the case of patterning or partly patterning an upper layer and a lower layer with the use of the same mask pattern is included. The expression “end portions are aligned or substantially aligned with each other” or “top surface shapes are the same or substantially the same” also includes the case where the outlines do not completely overlap each other; for instance, the edge of the upper layer may be positioned on the inner side or the outer side compared to the edge of the lower layer.

The side surfaces of the EL layers 113R, 113G, and 113B are covered with the insulating layer 125. The insulating layer 127 overlaps the side surfaces of the EL layers 113R, 113G, and 113B with the insulating layer 125 therebetween.

The top surfaces of the EL layers 113R, 113G, and 113B are partly covered with the mask layer 118. The insulating layers 125 and 127 overlap part of the top surfaces of the EL layers 113R, 113G, and 113B with the mask layer 118 therebetween.

Covering the side surfaces and part of the top surfaces of the EL layers 113R, 113G, and 113B with at least one of the insulating layer 125, the insulating layer 127, and the mask layer 118 can prevent the common layer 114 or the common electrode 115 from being in contact with the side surfaces of the EL layers 113R, 113G, and 113B and thus prevent a short circuit of the light-emitting element 130. Consequently, the reliability of the light-emitting element 130 can be increased.

The thicknesses of the EL layers 113R, 113G, and 113B can be different from each other. For example, the thicknesses of the EL layers 113R, 113G, and 113B are preferably set to match an optical path length that intensifies light emitted from each EL layer. Thus, a microcavity structure is achieved, and the color purity of light emitted from the subpixels 110 can be improved.

The insulating layer 125 is preferably in contact with the side surfaces of the EL layers 113R, 113G, and 113B. In that case, peeling of the EL layers 113R, 113G, and 113B can be prevented. When the insulating layer 125 is closely attached to the EL layer 113R, the EL layer 113G, or the EL layer 113B, the effect of fixing or bonding the adjacent EL layers 113 by the insulating layer 125 is obtained, for example. Thus, the light-emitting element 130 can be highly reliable. Moreover, the light-emitting element 130 can be manufactured by a method with a high yield.

The insulating layers 125 and 127 cover both the side surfaces and part of the top surfaces of the EL layers 113R, 113G, and 113B as illustrated in FIG. 1B, whereby peeling of the EL layers 113 can be favorably prevented. Thus, the reliability of the light-emitting elements 130 can be favorably increased. In addition, the manufacturing yield of the light-emitting elements 130 can be favorably increased.

FIG. 1B illustrates an example in which a stacked-layer structure of the EL layer 113R, the mask layer 118R, the insulating layer 125, and the insulating layer 127 is positioned over the end portion of the conductive layer 112R. Similarly, a stacked-layer structure of the EL layer 113G, the mask layer 118G, the insulating layer 125, and the insulating layer 127 is positioned over the end portion of the conductive layer 112G; and a stacked-layer structure of the EL layer 113B, the mask layer 118B, the insulating layer 125, and the insulating layer 127 is positioned over the end portion of the conductive layer 112B.

FIG. 1B illustrates a structure in which the end portion of the conductive layer 112R is covered with the EL layer 113R and the insulating layer 125 is in contact with the side surface of the EL layer 113R. Similarly, the end portion of the conductive layer 112G is covered with the EL layer 113G, the end portion of the conductive layer 112B is covered with the EL layer 113B, and the insulating layer 125 is in contact with the side surfaces of the EL layers 113G and 113B.

The insulating layer 127 is provided over the insulating layer 125 to fill a depression portion formed by the insulating layer 125. The insulating layer 127 can overlap the side surfaces and part of the top surfaces of the EL layers 113R, 113G, and 113B with the insulating layer 125 therebetween. The insulating layer 127 preferably covers at least part of the side surface of the insulating layer 125.

The insulating layers 125 and 127 can fill a gap between adjacent island-shaped layers; hence, extreme unevenness of the formation surface of the layers (e.g., the carrier-injection layer and the common electrode) provided over the island-shaped layers can be reduced, and the formation surface can be made flatter. Consequently, the coverage with the carrier-injection layer, the common electrode, and the like can be improved.

The common layer 114 and the common electrode 115 are provided over the EL layers 113R, 113G, and 113B, the mask layers 118R, 118G, and 118B, and the insulating layers 125 and 127. At the stage before the insulating layers 125 and 127 are provided, a level difference due to a region where the island-shaped EL layer 113 is provided and a region where the island-shaped EL layer 113 is not provided (a region between the light-emitting elements) is caused. In the display device 100, the insulating layers 125 and 127 can eliminate the level difference and improve the coverage with the common layer 114 and the common electrode 115. Thus, a connection defect due to disconnection and an increase in electric resistance due to local thinning can be prevented.

The top surface of the insulating layer 127 preferably has a shape with higher flatness, but may include a projection portion, a convex surface, a concave surface, or a depression portion. For example, the top surface of the insulating layer 127 preferably has a smooth convex shape with high flatness.

Note that in the display device 100, the insulating layer 127 is provided over the insulating layer 125 to fill the depression portion formed by the insulating layer 125. Moreover, the insulating layer 127 is provided between the island-shaped EL layers. In other words, the display device 100 employs a process in which an island-shaped EL layer is formed and then the insulating layer 127 is formed to overlap an end portion of the island-shaped EL layer (hereinafter referred to as a process 1). As a process different from the process 1, there is a process in which a pixel electrode is formed in an island shape, an insulating layer that covers an end portion of the pixel electrode is formed, and then an island-shaped EL layer is formed over the pixel electrode and the insulating layer (hereinafter referred to as a process 2).

The process 1 is preferable to the process 2 because of having a wider margin. Specifically, the process 1 has a wider margin with respect to alignment accuracy between different patterning steps than the process 2 and can provide display devices with few variations. Since the method for manufacturing the display device 100 is based on the process 1, a display device with few variations and high display quality can be provided.

Next, examples of materials of the insulating layers 125 and 127 are described.

The insulating layer 125 can be formed using an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferably used because it has high selectivity with respect to the EL layer in etching and has a function of protecting the EL layer when the insulating layer 127 is formed. In particular, when an inorganic insulating film such as an aluminum oxide film, a hafnium oxide film, or a silicon oxide film formed by an atomic layer deposition (ALD) method is used as the insulating layer 125, the insulating layer 125 has a small number of pin holes and excels in a function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. The insulating layer 125 preferably has a function of inhibiting diffusion of at least one of water and oxygen. The insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like means a function of inhibiting diffusion of a particular substance (also referred to as a function of less easily transmitting the substance). Alternatively, a barrier property refers to a function of capturing or fixing (also referred to as gettering) a particular sub stance.

When the insulating layer 125 has a function of the barrier insulating layer or a gettering function, entry of impurities (typically, at least one of water and oxygen) that would diffuse into the light-emitting element 130 from the outside can be suppressed. With this structure, a highly reliable light-emitting element and a highly reliable display device can be provided.

The insulating layer 125 preferably has a low impurity concentration. In that case, degradation of the EL layer 113 due to entry of impurities into the EL layer 113 from the insulating layer 125 can be suppressed. In addition, when the impurity concentration is reduced in the insulating layer 125, a barrier property against at least one of water and oxygen can be increased. For example, one or both of the hydrogen concentration and the carbon concentration in the insulating layer 125 are preferably low.

Note that the insulating layer 125 can be formed using the same material as the mask layers 118R, 118G, and 118B. In this case, the boundary between the insulating layer 125 and any of the mask layers 118R, 118G, and 118B may be unclear so that they cannot be distinguished from each other. Thus, the insulating layer 125 and any of the mask layers 118R, 118G, and 118B are observed as one layer in some cases. In other words, it sometimes appears that one layer is provided in contact with the side surfaces and part of the top surfaces of the EL layers 113R, 113G, and 113B, and the insulating layer 127 covers at least part of the side surface of the one layer.

The insulating layer 127 provided over the insulating layer 125 has a function of filling extreme unevenness of the insulating layer 125, which is formed between the adjacent light-emitting elements 130. In other words, the insulating layer 127 has an effect of improving the planarity of the formation surface of the common electrode 115.

As the insulating layer 127, an insulating layer containing an organic material can be favorably used. As the organic material, a photosensitive material such as a photosensitive organic resin is preferably used, and for example, a photosensitive resin composition containing an acrylic resin is preferably used. Note that in this specification and the like, an acrylic resin refers to not only a polymethacrylic acid ester or a methacrylic resin, but also all the acrylic polymer in a broad sense in some cases.

The insulating layer 127 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. The insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used as the photosensitive resin. As the photosensitive organic resin, either a positive-type material or a negative-type material may be used.

The insulating layer 127 may be formed using a material absorbing visible light. When the insulating layer 127 absorbs light emitted from the light-emitting element 130, light leakage (stray light) from the light-emitting element 130 to the adjacent light-emitting element 130 through the insulating layer 127 can be suppressed. Thus, the display quality of the display device can be improved. Since no polarizing plate is required to improve the display quality of the display device, the weight and thickness of the display device can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two or three or more colors is particularly preferred, in which case the effect of blocking visible light is enhanced. In particular, mixing color filter materials of three or more colors enables the formation of a black or nearly black resin layer.

The volume shrinkage rate of the material used for the insulating layer 127 is preferably low, in which case the insulating layer 127 can be easily formed with a desired shape. Moreover, the volume shrinkage rate of the insulating layer 127 after curing is preferably low, in which case the shape of the insulating layer 127 can be easily maintained in various steps after the formation of the insulating layer 127. Specifically, the volume shrinkage rate of the insulating layer 127 after thermal curing, after light curing, or after light curing and thermal curing is preferably lower than or equal to 10%, further preferably lower than or equal to 5%, still further preferably lower than or equal to 1%. Here, the volume shrinkage rate can be one of the rate of volume shrinkage by light irradiation and the rate of volume shrinkage by heating, or the sum of these rates.

By providing the protective layer 131 over the light-emitting element 130, the reliability of the light-emitting element 130 can be increased. The protective layer 131 may have a single-layer structure or a stack-layered structure including two or more layers.

There is no limitation on the conductivity of the protective layer 131. The protective layer 131 can be an insulating layer, a semiconductor layer, or a conductive layer.

As the protective layer 131, an inorganic insulating film such as an oxide insulating film, a nitride insulating film, an oxynitride insulating film, or a nitride oxide insulating film can be used, for example. Specific examples of these inorganic films have been given in the description of the insulating layer 125. In particular, the protective layer 131 preferably includes a nitride insulating film or a nitride oxide insulating film, and further preferably includes a nitride insulating film.

An inorganic film containing indium tin oxide, indium zinc oxide, gallium zinc oxide, aluminum zinc oxide, indium gallium zinc oxide (also referred to as IGZO), or the like can also be used as the protective layer 131. The inorganic film preferably has high resistance, specifically, higher resistance than the common electrode 115. The inorganic film may further contain nitrogen.

The protective layer 131 including the inorganic film can prevent oxidation of the common electrode 115. Moreover, the protective layer 131 including the inorganic film can suppress entry of impurities (e.g., water and oxygen) into the light-emitting element. Accordingly, deterioration of the light-emitting element 130 can be suppressed, and the reliability of the display device 100 can be increased.

When light emitted from the light-emitting element 130 is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can be, for example, a stack of an aluminum oxide film and a silicon nitride film over the aluminum oxide film, or a stack of an aluminum oxide film and an IGZO film over the aluminum oxide film. Such a stacked-layer structure can suppress entry of impurities (such as water and oxygen) into the EL layer 113.

Furthermore, the protective layer 131 may include an organic film. For example, the protective layer 131 may include both an organic film and an inorganic film. Examples of an organic material that can be used for the protective layer 131 include organic insulating materials that can be used for the insulating layer 127.

The protective layer 131 may have a stacked-layer structure of two layers formed by different formation methods. Specifically, the first layer of the protective layer 131 may be formed by an ALD method, and the second layer of the protective layer 131 may be formed by a sputtering method.

A light-blocking layer may be provided on the surface of the substrate 120 on the resin layer 122 side. Moreover, a variety of optical members can be provided on the outer side of the substrate 120. Examples of optical members include a polarizing plate, a retardation plate, a light diffusion layer (e.g., a diffusion film), an anti-reflective layer, and a light-condensing film. Furthermore, an antistatic film preventing the attachment of dust, a water repellent film suppressing the attachment of stain, a hard coat film suppressing generation of a scratch caused by the use, an impact-absorbing layer, or the like may be provided as a surface protective layer on the outer surface of the substrate 120. For example, it is preferable to provide, as the surface protective layer, a glass layer or a silica layer (SiOₓ layer), in which case the surface contamination or damage can be prevented from being generated. The surface protective layer may be formed using diamond like carbon (DLC), aluminum oxide (AlOₓ), a polyester-based material, a polycarbonate-based material, or the like. For the surface protective layer, a material having a high visible-light-transmitting property is preferably used. The surface protective layer is preferably formed using a material with high hardness.

For the substrate 120, glass, quartz, ceramic, sapphire, a resin, a metal, an alloy, a semiconductor, or the like can be used. The substrate on the side from which light from the light-emitting element is extracted is formed using a material that transmits the light. Furthermore, a polarizing plate may be used as the substrate 120.

The substrate 120 may be formed using a flexible material. In that case, the display device can be highly flexible. Examples of flexible materials include polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (such as nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and a cellulose nanofiber. Glass that is thin enough to have flexibility may be used as the substrate 120.

In the case where a circularly polarizing plate overlaps the display device, a highly optically isotropic substrate is preferably used as the substrate included in the display device. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of films having high optical isotropy include a triacetyl cellulose (TAC, also referred to as cellulose triacetate) film, a cycloolefin polymer (COP) film, a cycloolefin copolymer (COC) film, and an acrylic film.

When a film used as the substrate absorbs water, the shape of the display device might be changed, e.g., creases might be caused. Thus, as the substrate, a film with a low water absorption rate is preferably used. For example, the water absorption rate of the film is preferably 1% or lower, further preferably 0.1% or lower, still further preferably 0.01% or lower.

For the resin layer 122, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. In particular, a material with low moisture permeability, such as an epoxy resin, is preferred. A two-component-mixture-type resin may be used. As another example, an adhesive sheet may be used.

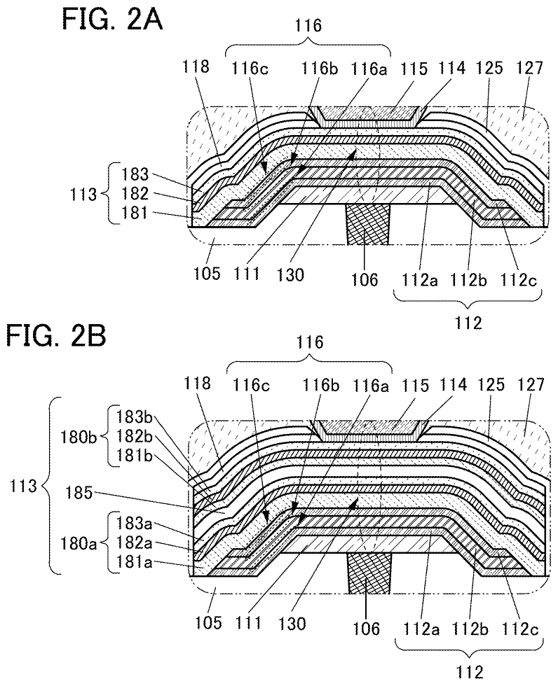

FIG. 2A is a cross-sectional view illustrating a structure example of the conductive layer 111, the conductive layer 112, the EL layer 113, and their periphery. As illustrated in FIG. 2A, the EL layer 113 is provided to cover the pixel electrode including the conductive layers 111 and 112. Thus, the aperture ratio of the pixel 108 can be increased as compared to the structure where the end portion of the EL layer 113 is positioned on the inner side of the end portion of the pixel electrode.

On the other hand, when the EL layer 113 is provided to cover the pixel electrode, disconnection or local thinning, for example, occurs in the EL layer 113 in some cases. In view of the above, in one embodiment of the present invention, the pixel electrode includes a tapered portion where the taper angle is less than 90° in the cross section. Thus, the coverage of the pixel electrode with the EL layer 113 is improved and occurrence of disconnection and local thinning, for example, can be inhibited in the EL layer 113, as compared to the case where a pixel electrode does not have a tapered portion, that is, the case where a pixel electrode includes a region whose taper angle is 90°, for example. Accordingly, the display device 100 can be highly reliable.

As illustrated in FIG. 2A, the conductive layer 111 has a tapered side surface with a taper angle less than 90° in the cross section. Accordingly, the conductive layer 112 covering the top surface and the side surface of the conductive layer 111 includes a tapered portion 116 between a flat portion overlapping the top surface of the conductive layer 111 and a flat portion not overlapping the top surface of the conductive layer 111. The tapered portion 116 includes a region overlapping the side surface of the conductive layer 111.

Here, not only the side surface of the conductive layer 111 but also the side surface of a projection portion of the insulating layer 105 may have a tapered shape with a taper angle less than 90° in the cross section. In that case, the tapered portion 116 of the conductive layer 112 may include a region overlapping the side surface of the projection portion of the insulating layer 105.

As illustrated in FIG. 2A, an upper end portion of the side surface of the projection portion of the insulating layer 105 may be aligned with a lower end portion of the side surface of the conductive layer 111. FIG. 2A shows an example where the taper angle of the side surface of the projection portion of the insulating layer 105 matches the taper angle of the side surface of the conductive layer 111; however, these taper angles do not necessarily match.

As illustrated in FIG. 2A, for example, the conductive layer 112 may include a curved portion between a region having a tapered shape and a flat portion. In this specification and the like, the curved portion is regarded as being included in a tapered portion. For example, in the case where the conductive layer 112 includes a curved portion between the flat portion overlapping the top surface of the conductive layer 111 and the region having a tapered shape, the curved portion is regarded as being included in the tapered portion 116.

When the pixel electrode includes two or more flat portions and the tapered portion 116 between the two flat portions as described above, the coverage of the pixel electrode with the EL layer 113 is improved and occurrence of disconnection and local thinning, for example, in the EL layer 113 can be favorably inhibited. Thus, the display device 100 can have high reliability.

Characteristics required for the pixel electrode are wide in range. Thus, in the display device 100, at least one of the conductive layers 111 and 112 has a stacked-layer structure including a plurality of layers containing different materials. FIG. 2A illustrates an example in which the conductive layer 112 has a three-layer structure of a conductive layer 112a, a conductive layer 112b over the conductive layer 112a, and a conductive layer 112c over the conductive layer 112b. The conductive layers 112a, 112b, and 112c are electrically connected to the conductive layer 111. Note that the tapered portion 116 of the conductive layer 112a is denoted as a tapered portion 116a, the tapered portion 116 of the conductive layer 112b is denoted as a tapered portion 116b, and the tapered portion 116 of the conductive layer 112c is denoted as a tapered portion 116c.

The conductive layer 111 is formed using, for example, a material that is hardly oxidized when being in contact with the conductive layer 112a and has electrical resistivity unlikely to increase significantly even when being oxidized. For example, the conductive layer 111 is formed using a material that is less likely to be oxidized than aluminum when being in contact with the conductive layer 112a and whose oxide has a lower electric resistivity than aluminum oxide. For example, the conductive layer 111 can be formed using titanium. Alternatively, the conductive layer 111 can be formed using an alloy containing titanium. Accordingly, a change in properties of the conductive layer 111 is inhibited, and the display device 100 can have high reliability. Note that a metal other than titanium may be used for the conductive layer 111.

The conductive layer 112a has higher adhesion to the conductive layer 112b than the insulating layer 105 does, for example. For the conductive layer 112a, an oxide containing one or more selected from indium, tin, zinc, gallium, titanium, aluminum, and silicon, for example, can be used. For example, it is preferable to use a conductive oxide containing one or more of indium oxide, indium tin oxide, indium zinc oxide, zinc oxide, zinc oxide containing gallium, titanium oxide, indium titanium oxide, zinc titanate, aluminum zinc oxide, indium zinc oxide containing gallium, indium zinc oxide containing aluminum, indium tin oxide containing silicon, indium zinc oxide containing silicon, and the like. Accordingly, peeling of the conductive layer 112b is inhibited, and the display device 100 can have high reliability. As illustrated in FIG. 2A, the conductive layer 112a is in contact with the insulating layer 105, and the conductive layer 112b is not in contact with the insulating layer 105.

The conductive layer 112b is a layer whose visible light reflectance (e.g., reflectance with respect to light with a predetermined wavelength in a range greater than or equal to 400 nm and less than 750 nm) is higher than that of the conductive layers 111, 112a, and 112c. The visible light reflectance of the conductive layer 112b can be, for example, higher than or equal to 70% and lower than or equal to 100%, and is preferably higher than or equal to 80% and lower than or equal to 100%, further preferably higher than or equal to 90% and lower than or equal to 100%. For the conductive layer 112b, a material having higher visible light reflectance than aluminum can be used, for example. Specifically, for the conductive layer 112b, silver or an alloy containing silver can be used, for example. An example of the alloy containing silver is an alloy of silver, palladium, and copper (APC). In the above manner, the display device 100 can have high outcoupling efficiency. Note that a metal other than silver may be used for the conductive layer 112b.

When the conductive layers 111 and 112 serve as the anode, a layer having a high work function is used as the conductive layer 112c. The conductive layer 112c has a higher work function than the conductive layer 112b, for example. This facilitates injection of holes into the EL layer 113, so that the driving voltage of the light-emitting element 130 can be lowered. For the conductive layer 112c, a material similar to the material usable for the conductive layer 112a can be used, for example. For example, the conductive layers 112a and 112c can be formed using the same kind of material. For example, in the case where indium tin oxide is used for the conductive layer 112a, indium tin oxide can also be used for the conductive layer 112c.

When the conductive layers 111 and 112 serve as the cathode, a layer having a low work function is used as the conductive layer 112c. The conductive layer 112c has a lower work function than the conductive layer 112b, for example. This facilitates injection of electrons into the EL layer 113, so that the driving voltage of the light-emitting element 130 can be lowered.

The conductive layer 112c is preferably a layer having high visible light transmittance (e.g., transmittance with respect to light with a predetermined wavelength in a range greater than or equal to 400 nm and less than 750 nm). For example, the visible light transmittance of the conductive layer 112c is preferably higher than that of the conductive layers 111 and 112b. The visible light transmittance of the conductive layer 112c can be, for example, greater than or equal to 60% and less than or equal to 100%, and is preferably higher than or equal to 70% and lower than or equal to 100%, further preferably higher than or equal to 80% and lower than or equal to 100%. Accordingly, the amount of light absorbed by the conductive layer 112c among light emitted from the EL layer 113 can be reduced. As described above, the conductive layer 112b under the conductive layer 112c can be a layer having high visible light reflectance. Thus, the display device 100 can have high outcoupling efficiency.

Note that the conductive layer 112b is a layer having high reflectance with respect to light emitted from the EL layer 113, and the conductive layer 112c is a layer having high transmittance with respect to light emitted from the EL layer 113. For example, in the case where the EL layer 113 emits infrared light, the conductive layer 112b is a layer having high reflectance with respect to infrared light, and the conductive layer 112c is a layer having high transmittance with respect to infrared light. For example, in the case where the EL layer 113 emits infrared light, “visible light” in the above description of the conductive layers 112b and 112c can be replaced with “infrared light”.

In the above manner, the display device 100 can have high reliability and high outcoupling efficiency. In addition, the display device 100 can include a light-emitting element with low driving voltage.

Although FIG. 2A illustrates an example where the end portions of the conductive layers 112a, 112b, and 112c are aligned or substantially aligned with each other, one embodiment of the present invention is not limited thereto. Although FIG. 2A illustrates an example where the end portions of the conductive layers 112a, 112b, and 112c are tapered, they are not necessarily tapered particularly when the conductive layer 112 has a small thickness. For example, when the thickness of the conductive layer 112 is sufficiently smaller than a difference between the height of a flat portion of the top surface of the conductive layer 112 in a region where the conductive layer 112 overlaps the conductive layer 111 and the height of a flat portion of the top surface of the conductive layer 112 in a region where the conductive layer 112 does not overlap the conductive layer 111, the end portions of the conductive layers 112a, 112b, and 112c are not necessarily tapered.

The EL layer 113 includes a functional layer 181, a light-emitting layer 182 over the functional layer 181, and a functional layer 183 over the light-emitting layer 182. The functional layer 181 includes a region that covers the conductive layer 112 and is in contact with the conductive layer 112c. The functional layer 183 includes a region in contact with the common layer 114.

For example, in the case where the conductive layers 111 and 112 function as the anode and the common electrode 115 functions as the cathode, the functional layer 181 includes one or both of a hole-injection layer and a hole-transport layer. For example, the functional layer 181 includes a hole-injection layer and a hole-transport layer over the hole-injection layer. The functional layer 183 includes an electron-transport layer. Here, the functional layer 181 may include an electron-blocking layer;

for example, the electron-blocking layer may be provided between the hole-transport layer and the light-emitting layer 182. The functional layer 183 may include a hole-blocking layer; for example, the hole-blocking layer may be provided between the electron-transport layer and the light-emitting layer 182. Furthermore, the functional layer 183 may include an electron-injection layer; for example, the electron-injection layer may be provided between the electron-transport layer and the common layer 114. A structure may be employed in which the functional layer 183 includes an electron-transport layer and an electron-injection layer over the electron-transport layer, and the common layer 114 is not provided. Note that the functional layer 181 may include one of the hole-injection layer and the hole-transport layer and not include the other. The functional layer 183 may not include the electron-transport layer. In the case where the conductive layers 111 and 112 function as the anode and the common electrode 115 functions as the cathode, the common layer 114 includes an electron-injection layer as described above, for example.

As another example, in the case where the conductive layers 111 and 112 function as the cathode and the common electrode 115 functions as the anode, the functional layer 181 includes one or both of an electron-injection layer and an electron-transport layer. For example, the functional layer 181 includes an electron-injection layer and an electron-transport layer over the electron-injection layer. The functional layer 183 includes a hole-transport layer. Here, the functional layer 181 may include a hole-blocking layer; for example, the hole-blocking layer may be provided between the electron-transport layer and the light-emitting layer 182. The functional layer 183 may include an electron-blocking layer; for example, the electron-blocking layer may be provided between the hole-transport layer and the light-emitting layer 182. Furthermore, the functional layer 183 may include a hole-injection layer; for example, the hole-injection layer may be provided between the hole-transport layer and the common layer 114. A structure may be employed in which the functional layer 183 includes a hole-transport layer and a hole-injection layer over the hole-transport layer, and the common layer 114 is not provided. Note that the functional layer 181 may include one of the electron-injection layer and the electron-transport layer and not include the other. The functional layer 183 may not include the hole-transport layer. In the case where the conductive layers 111 and 112 function as the cathode and the common electrode 115 functions as the anode, the common layer 114 includes a hole-injection layer as described above, for example.

The conductive layer 112 includes a region in contact with the undermost layer, for example, among the layers provided in the functional layer 181. For example, in the case where the functional layer 181 has a stacked-layer structure of a hole-injection layer and a hole-transport layer over the hole-injection layer, the conductive layer 112 includes a region in contact with the hole-injection layer. As another example, in the case where the functional layer 181 has a stacked-layer structure of an electron-injection layer and an electron-transport layer over the electron-injection layer, the conductive layer 112 includes a region in contact with the electron-injection layer.

In the case where the functional layer 181 includes one or both of the hole-injection layer and the hole-transport layer as described above, the conductive layers 111 and 112 function as the anode. Accordingly, the conductive layer 112c including a region in contact with the functional layer 181 is preferably a layer having a high work function and is specifically a layer having a higher work function than the conductive layer 112b, for example. Meanwhile, in the case where the functional layer 181 includes one or both of the electron-injection layer and the electron-transport layer as described above, the conductive layers 111 and 112 function as the cathode. Accordingly, the conductive layer 112c including a region in contact with the functional layer 181 is preferably a layer having a low work function and is specifically a layer having a lower work function than the conductive layer 112b, for example.

Here, providing the functional layer 183 over the light-emitting layer 182 can prevent the light-emitting layer 182 from being exposed on the outermost surface in the manufacturing process of the display device. This can reduce damage to the light-emitting layer 182. Thus, the reliability of the light-emitting element 130 can be increased.

Although FIG. 2A illustrates a structure example of the EL layer 113 in the case where the light-emitting element 130 has a single structure, the light-emitting element 130 may employ a tandem structure. FIG. 2B is a cross-sectional view illustrating a structure example of the EL layer 113 and its periphery in the case where the light-emitting element 130 has a two-unit tandem structure.

In the light-emitting element 130 having a two-unit tandem structure, the EL layer 113 includes a light-emitting unit 180a, a charge-generation layer 185 over the light-emitting unit 180a, and a light-emitting unit 180b over the charge-generation layer 185. The light-emitting unit 180a includes a functional layer 181a, a light-emitting layer 182a over the functional layer 181a, and a functional layer 183a over the light-emitting layer 182a. The light-emitting unit 180b includes a functional layer 181b, a light-emitting layer 182b over the functional layer 181b, and a functional layer 183b over the light-emitting layer 182b. The functional layer 181a includes a region in contact with the conductive layer 112, and the functional layer 183b includes a region in contact with the common layer 114.

For example, in the case where the conductive layers 111 and 112 function as the anode and the common electrode 115 functions as the cathode, the functional layer 181a includes one or both of a hole-injection layer and a hole-transport layer. For example, the functional layer 181a includes a hole-injection layer and a hole-transport layer over the hole-injection layer. The functional layer 183a includes an electron-transport layer, the functional layer 181b includes a hole-transport layer, and the functional layer 183b includes an electron-transport layer. Here, for example, the functional layer 183a may include a hole-blocking layer; for instance, the hole-blocking layer may be provided between the electron-transport layer and the light-emitting layer 182a. For example, the functional layer 181b may include an electron-blocking layer; for example, the electron-blocking layer may be provided between the hole-transport layer and the light-emitting layer 182b. Furthermore, the functional layer 183b may include an electron-injection layer; for example, the electron-injection layer may be provided between the electron-transport layer and the common layer 114. A structure may be employed in which the functional layer 183b includes an electron-transport layer and an electron-injection layer over the electron-transport layer, and the common layer 114 is not provided. Note that the functional layer 181a may include one of the hole-injection layer and the hole-transport layer and not include the other. The functional layer 183b may not include the electron-transport layer. In the case where the conductive layers 111 and 112 function as the anode and the common electrode 115 functions as the cathode, the common layer 114 includes an electron-injection layer as described above, for example.

As another example, in the case where the conductive layers 111 and 112 function as the cathode and the common electrode 115 functions as the anode, the functional layer 181a includes one or both of an electron-injection layer and an electron-transport layer. For example, the functional layer 181a includes an electron-injection layer and an electron-transport layer over the electron-injection layer. The functional layer 183a includes a hole-transport layer, the functional layer 181b includes an electron-transport layer, and the functional layer 183b includes a hole-transport layer. Here, for example, the functional layer 183a may include an electron-blocking layer; for example, the electron-blocking layer may be provided between the hole-transport layer and the light-emitting layer 182a. For example, the functional layer 181b may include a hole-blocking layer; for example, the hole-blocking layer may be provided between the electron-transport layer and the light-emitting layer 182b. Furthermore, the functional layer 183b may include a hole-injection layer; for example, the hole-injection layer may be provided between the hole-transport layer and the common layer 114. A structure may be employed in which the functional layer 183b includes a hole-transport layer and a hole-injection layer over the hole-transport layer, and the common layer 114 is not provided. Note that the functional layer 181a may include one of the electron-injection layer and the electron-transport layer and not include the other. The functional layer 183b may not include the hole-transport layer. In the case where the conductive layers 111 and 112 function as the cathode and the common electrode 115 functions as the anode, the common layer 114 includes a hole-injection layer as described above, for example.

The conductive layer 112 includes a region in contact with the undermost layer, for example, among the layers provided in the functional layer 181a. For example, in the case where the functional layer 181a has a stacked-layer structure of a hole-injection layer and a hole-transport layer over the hole-injection layer, the conductive layer 112 includes a region in contact with the hole-injection layer. As another example, in the case where the functional layer 181a has a stacked-layer structure of an electron-injection layer and an electron-transport layer over the electron-injection layer, the conductive layer 112 includes a region in contact with the electron-injection layer.

In the case where the functional layer 181a includes one or both of the hole-injection layer and the hole-transport layer as described above, the conductive layers 111 and 112 function as the anode. Accordingly, the conductive layer 112c including a region in contact with the functional layer 181a is preferably a layer having a high work function and is specifically a layer having a higher work function than the conductive layer 112b, for example. Meanwhile, in the case where the functional layer 181a includes one or both of the electron-injection layer and the electron-transport layer as described above, the conductive layers 111 and 112 function as the cathode. Accordingly, the conductive layer 112c including a region in contact with the functional layer 181a is preferably a layer having a low work function and is specifically a layer having a lower work function than the conductive layer 112b, for example.

Here, providing the functional layer 183b over the light-emitting layer 182b can prevent the light-emitting layer 182b from being exposed on the outermost surface in the manufacturing process of the display device. This can reduce damage to the light-emitting layer 182b. Thus, the reliability of the light-emitting element 130 can be increased.

The light-emitting layers 182a and 182b can emit light of the same color. For example, the light-emitting layers 182a and 182b included in the EL layer 113R can emit red light, the light-emitting layers 182a and 182b included in the EL layer 113G can emit green light, and the light-emitting layers 182a and 182b included in the EL layer 113B can emit blue light.

The charge-generation layer 185 includes at least a charge-generation region. The charge-generation layer 185 has a function of injecting electrons into one of the light-emitting units 180a and 180b and injecting holes to the other of the light-emitting units 180a and 180b when voltage is applied between the conductive layers 111 and 112 and the common electrode 115.

The light-emitting element 130 may employ a tandem structure with three units or more. That is, the EL layer 113 may include three or more light-emitting units. In such a case, providing a functional layer over the light-emitting layer in the uppermost light-emitting unit can prevent the light-emitting layer from being exposed on the outermost surface in the manufacturing process of the display device, whereby the reliability of the light-emitting element 130 can be increased.

When the light-emitting element 130 has a tandem structure, the current efficiency for light emission can be increased, so that the light emission efficiency of the light-emitting element 130 can be increased. Alternatively, the density of current flowing through the light-emitting element 130 can be reduced at the same luminance; thus, power consumption of the display device 100 including the light-emitting element 130 can be reduced. When the light-emitting element 130 has a tandem structure, the reliability of the light-emitting element 130 can be increased.

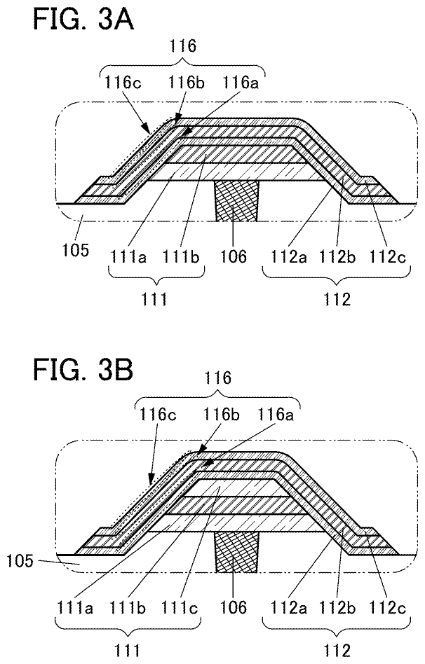

FIGS. 3A and 3B are cross-sectional views illustrating structure examples of the conductive layer 111 and the conductive layer 112. The example in FIG. 3A differs from the structure in FIG. 2A, for instance, in that the conductive layer 111 has a two-layer structure of a conductive layer 111a and a conductive layer 111b over the conductive layer 111a. The structure in FIG. 3B differs from the structure in FIG. 2A, for instance, in that the conductive layer 111 has a three-layer structure of the conductive layer 111a, the conductive layer 111b over the conductive layer 111a, and a conductive layer 111c over the conductive layer 111b.

The conductive layers 111a and 111c can be formed using a material similar to that for the conductive layer 111 illustrated in FIG. 2A, for example, titanium or an alloy containing titanium. The conductive layer 111b can be a layer having higher visible light reflectance than the conductive layer 111a, for example. Moreover, the conductive layer 111b can be a layer that is more easily processed by etching than the conductive layer 112b, for example. In the above manner, the conductive layer 112b that can contain silver or an alloy containing silver, for example, can be made thin while the visible light reflectance of the pixel electrode increases. Hence, the display device 100 can have high outcoupling efficiency and be easily manufactured. For the conductive layer 111b, aluminum or an alloy containing aluminum can be used, for example.

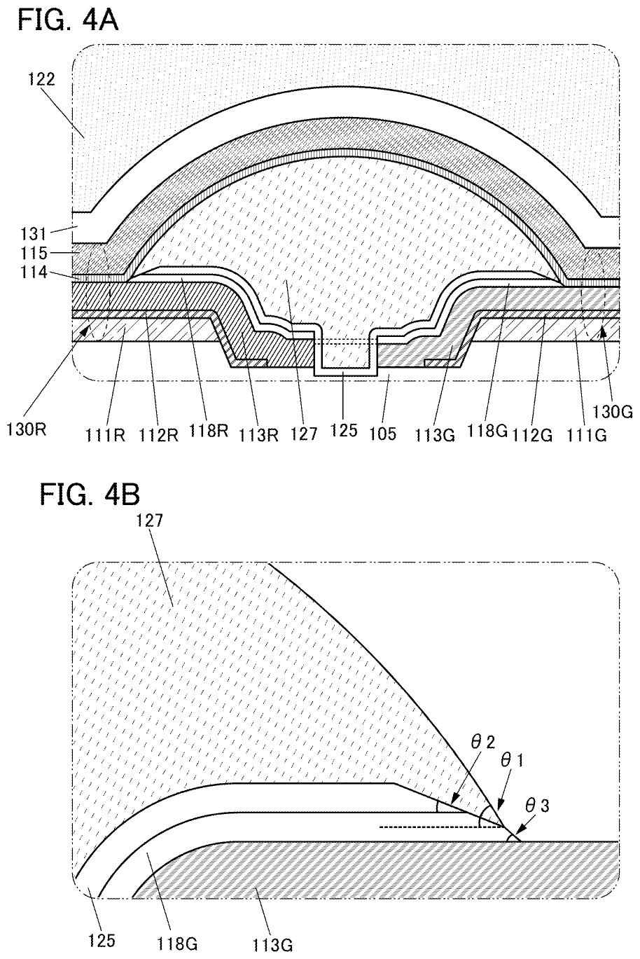

Next, a structure of the insulating layer 127 and its vicinity will be described with reference to FIGS. 4A and 4B. FIG. 4A is a cross-sectional enlarged view of a region including the insulating layer 127 between the EL layer 113R and the EL layer 113G and the vicinity thereof. The description is made below using the insulating layer 127 between the EL layer 113R and the EL layer 113G as an example; the same applies to the insulating layer 127 between the EL layer 113G and the EL layer 113B and the insulating layer 127 between the EL layer 113B and the EL layer 113R. FIG. 4B is an enlarged view of an end portion of the insulating layer 127 over the EL layer 113G illustrated in FIG. 4A and the vicinity thereof. The description is made below using the end portion of the insulating layer 127 over the EL layer 113G as an example; the same applies to the end portion of the insulating layer 127 over the EL layer 113R and the end portion of the insulating layer 127 over the EL layer 113B.

As illustrated in FIG. 4A, the EL layer 113R is provided to cover the conductive layer 112R, and the EL layer 113G is provided to cover the conductive layer 112G. The mask layer 118R is provided in contact with part of the top surface of the EL layer 113R, and the mask layer 118G is provided in contact with part of the top surface of the EL layer 113G. The insulating layer 125 is provided in contact with the top surface and the side surface of the mask layer 118R, the side surface of the EL layer 113R, the top surface of the insulating layer 105, the top surface and the side surface of the mask layer 118G, and the side surface of the EL layer 113G. The insulating layer 127 is provided in contact with the top surface of the insulating layer 125. The insulating layer 127 overlaps the side surface and part of the top surface of the EL layer 113R and the side surface and part of the top surface of the EL layer 113G with the insulating layer 125 therebetween, and is in contact with at least part of the side surface of the insulating layer 125. The common layer 114 is provided to cover the EL layer 113R, the mask layer 118R, the EL layer 113G, the mask layer 118G, the insulating layer 125, and the insulating layer 127. The common electrode 115 is provided over the common layer 114.

As indicated by dotted lines in FIG. 4A, the EL layer 113R and the EL layer 113G can have different thicknesses. Thus, a microcavity structure is achieved as described above, and the color purity of light emitted from the subpixels 110 can be improved. As described above, the thickness of the EL layer 113B can be different from those of the EL layers 113R and 113G.

As illustrated in FIG. 4A, the thickness of the insulating layer 105 in a region not overlapped by the EL layer 113 may be smaller than that of the insulating layer 105 in a region overlapped by the EL layer 113. That is, the insulating layer 105 may have a depression portion in the region not overlapped by the EL layer 113. The depression portion is formed because of the step of forming the EL layer 113, for example.

The insulating layer 127 is formed in a region between the two island-shaped EL layers 113 (e.g., a region between the EL layer 113R and the EL layer 113G in FIG. 4A). In this case, at least part of the insulating layer 127 is positioned between a side end portion of one of the EL layers 113 (e.g., the EL layer 113R in FIG. 4A) and a side end portion of the other EL layer 113 (e.g., the EL layer 113G in FIG. 4A). By providing such an insulating layer 127, formation of a disconnection portion and a local thinning portion can be suppressed in the common layer 114 and the common electrode 115 formed over the island-shaped EL layers 113 and the insulating layer 127.

As illustrated in FIG. 4B, the end portion of the insulating layer 127 preferably has a tapered shape with a taper angle θ1 in the cross-sectional view of the display device 100. The taper angle θ1 is an angle formed by the side surface of the insulating layer 127 and the substrate surface. Alternatively, the taper angle θ1 may be an angle formed by the side surface of the insulating layer 127 and, instead of the substrate surface, the top surface of a flat portion of the EL layer 113G or the top surface of a flat portion of the conductive layer 112G.

The taper angle θ1 of the insulating layer 127 is less than 90°, preferably less than or equal to 60°, further preferably less than or equal to 45°, still further preferably less than or equal to 20°. When the end portion of the insulating layer 127 has such a forward tapered shape, the common layer 114 and the common electrode 115 can favorably cover the insulating layer 127; thus, disconnection, local thinning, or the like can be suppressed. Consequently, the in-plane uniformity of the common layer 114 and the common electrode 115 can be increased, so that the display quality of the display device can be improved.

As illustrated in FIG. 4A, the top surface of the insulating layer 127 preferably has a convex shape in the cross-sectional view of the display device 100. The convex top surface of the insulating layer 127 preferably has a shape that expands gradually toward the center. The convex portion at the center of the top surface of the insulating layer 127 preferably has a shape connected smoothly to the tapered portion of the end portion. When the insulating layer 127 has such a shape, the common layer 114 and the common electrode 115 can favorably cover the entire insulating layer 127.

As illustrated in FIG. 4B, the end portion of the insulating layer 127 is preferably positioned on the outer side of the end portion of the insulating layer 125. In that case, unevenness of the surface where the common layer 114 and the common electrode 115 are formed is reduced, and coverage of the formation surface with the common layer 114 and the common electrode 115 can be improved.

As illustrated in FIG. 4B, the end portion of the insulating layer 125 preferably has a tapered shape with a taper angle θ2 in the cross-sectional view of the display device 100. The taper angle θ2 is an angle formed by the side surface of the insulating layer 125 and the substrate surface. Alternatively, the taper angle θ2 may be an angle formed by the side surface of the insulating layer 125 and, instead of the substrate surface, the top surface of the flat portion of the EL layer 113G or the top surface of the flat portion of the conductive layer 112G.

The taper angle θ2 of the insulating layer 125 is less than 90°, preferably less than or equal to 60°, further preferably less than or equal to 45°, still further preferably less than or equal to 20°.

As illustrated in FIG. 4B, the end portion of the mask layer 118G preferably has a tapered shape with a taper angle θ3 in the cross-sectional view of the display device 100. The taper angle θ3 is an angle formed by the side surface of the mask layer 118G and the substrate surface. Alternatively, the taper angle θ3 may be an angle formed by the side surface of the mask layer 118G and, instead of the substrate surface, the top surface of the flat portion of the EL layer 113G or the top surface of the flat portion of the conductive layer 112G.

The taper angle θ3 of the mask layer 118G is less than 90°, preferably less than or equal to 60°, further preferably less than or equal to 45°, still further preferably less than or equal to 20°. When the mask layer 118G has such a forward tapered shape, the common layer 114 and the common electrode 115 can favorably cover the mask layer 118G.

The end portion of the mask layer 118R and the end portion of the mask layer 118G are preferably positioned on the outer side of the end portion of the insulating layer 125. In that case, unevenness of the surface where the common layer 114 and the common electrode 115 are formed is reduced, and coverage of the formation surface with the common layer 114 and the common electrode 115 can be improved.

Although the details will be described later, when the insulating layer 125 and the mask layer 118 are etched at once, the insulating layer 125 and the mask layer 118 under the end portion of the insulating layer 127 may disappear because of side-etching and a void may be formed. The void causes unevenness on the formation surface of the common layer 114 and the common electrode 115; hence, disconnection or local thinning is more likely to be caused in the common layer 114 and the common electrode 115. Accordingly, when etching treatment is divided into two steps and heat treatment is performed between the two etching steps, even if a void is formed by the first etching treatment, the shape of the insulating layer 127 is changed by the heat treatment to fill the void. Since the second etching treatment is for etching a thinner film, the amount of side-etching decreases, a void is less likely to be formed, and even if a void is formed, it can be extremely small. Thus, unevenness can be inhibited from being formed on the formation surface of the common layer 114 and the common electrode 115, and disconnection and local thinning in the common layer 114 and the common electrode 115 can be suppressed. Since the etching treatment is performed twice, the taper angle θ2 and the taper angle θ3 are different from each other in some cases. The taper angle θ2 and the taper angle θ3 may be the same. Furthermore, the taper angle θ2 and the taper angle θ3 may each be smaller than the taper angle θ1.

The insulating layer 127 may cover at least part of the side surface of the mask layer 118. For instance, FIG. 4B illustrates an example in which the insulating layer 127 touches and covers a sloping surface that is formed by the first etching treatment and positioned at the end portion of the mask layer 118G, and a sloping surface that is formed by the second etching treatment and positioned at the end portion of the mask layer 118G is exposed. These two sloping surfaces can sometimes be distinguished from each other because of different taper angles. In some cases, they cannot be distinguished from each other because the taper angles on the side surface formed by the two etching treatments are almost the same.

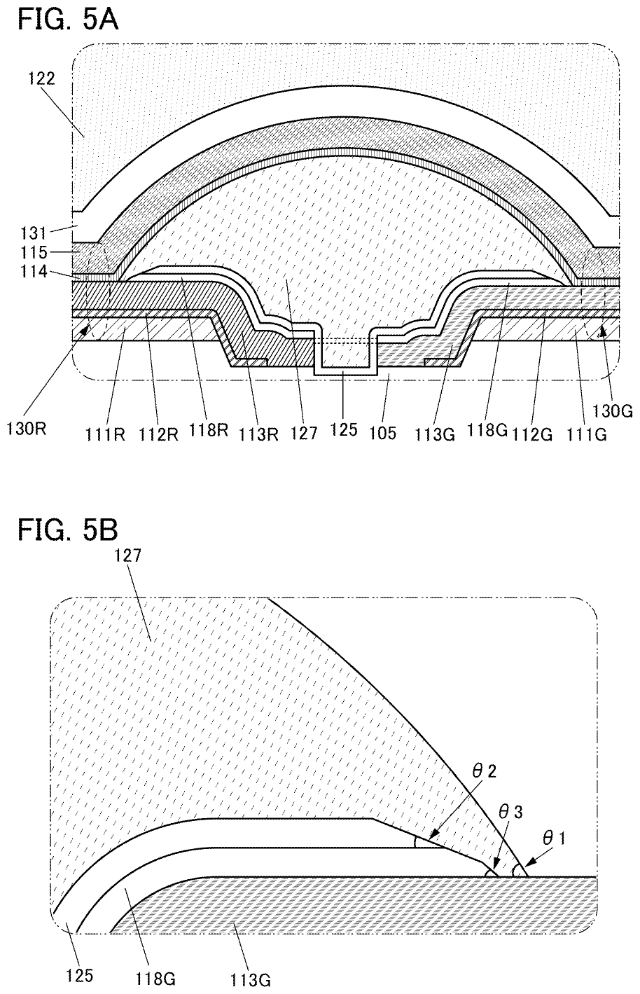

FIGS. 5A and 5B show a variation example of the structure in FIGS. 4A and 4B, and illustrates an example where the insulating layer 127 covers the entire side surface of the mask layer 118R and the entire side surface of the mask layer 118G. Specifically, in FIG. 5B, the insulating layer 127 touches and covers both of the two sloping surfaces. This is preferred because unevenness on the formation surface of the common layer 114 and the common electrode 115 can be further reduced. FIG. 5B illustrates an example where the end portion of the insulating layer 127 is positioned on the outer side of the end portion of the mask layer 118G. The end portion of the insulating layer 127 may be positioned on the inner side of the end portion of the mask layer 118G or may be aligned or substantially aligned with the end portion of the mask layer 118G. As illustrated in FIG. 5B, the insulating layer 127 is in contact with the EL layer 113G in some cases.

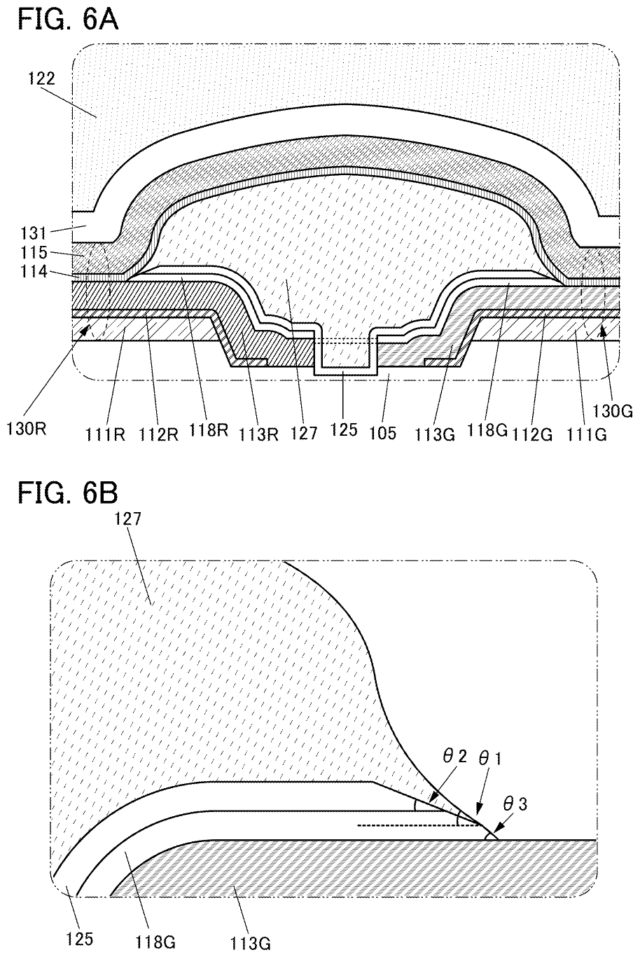

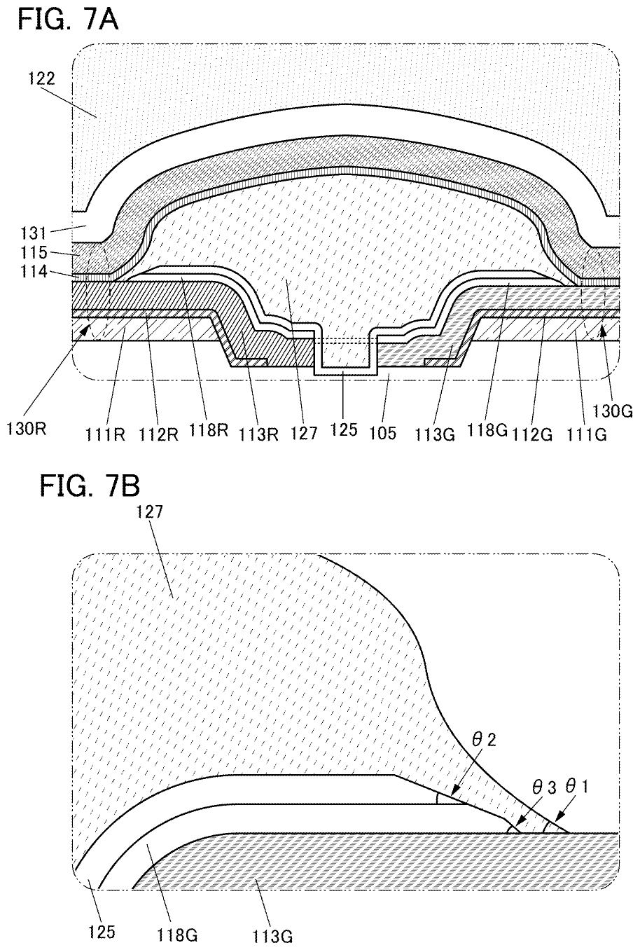

FIG. 6A and FIG. 7A show variation examples of the structure in FIG. 4A, and FIG. 6B and FIG. 7B show variation examples of the structure in FIG. 4B. FIGS. 6A and 6B and FIGS. 7A and 7B illustrate examples where the side surface of the insulating layer 127 has a concave shape (also referred to as a narrow region, a depression portion, a dent, a hollow, or the like). In some cases, the side surface of the insulating layer 127 has a concave shape depending on the material and formation conditions (e.g., heating temperature, heating time, and heating atmosphere) of the insulating layer 127.

FIGS. 6A and 6B illustrate an example where the insulating layer 127 covers part of the side surfaces of the mask layers 118R and 118G, and the other regions of the side surfaces of the mask layers 118R and 118G are exposed. FIGS. 7A and 7B illustrate an example where the insulating layer 127 touches and covers the entire side surface of the mask layer 118R and the entire side surface of the mask layer 118G.

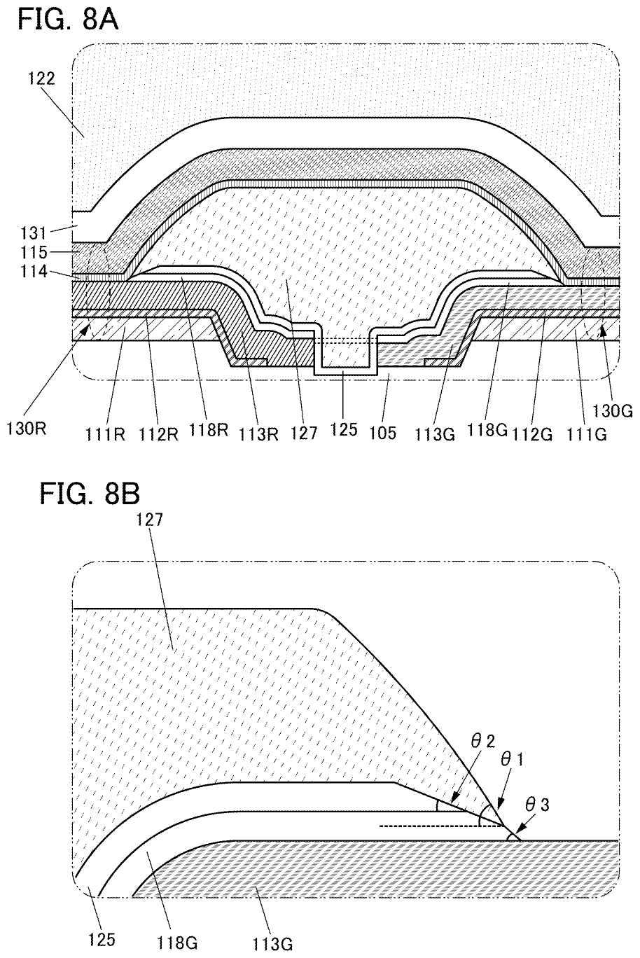

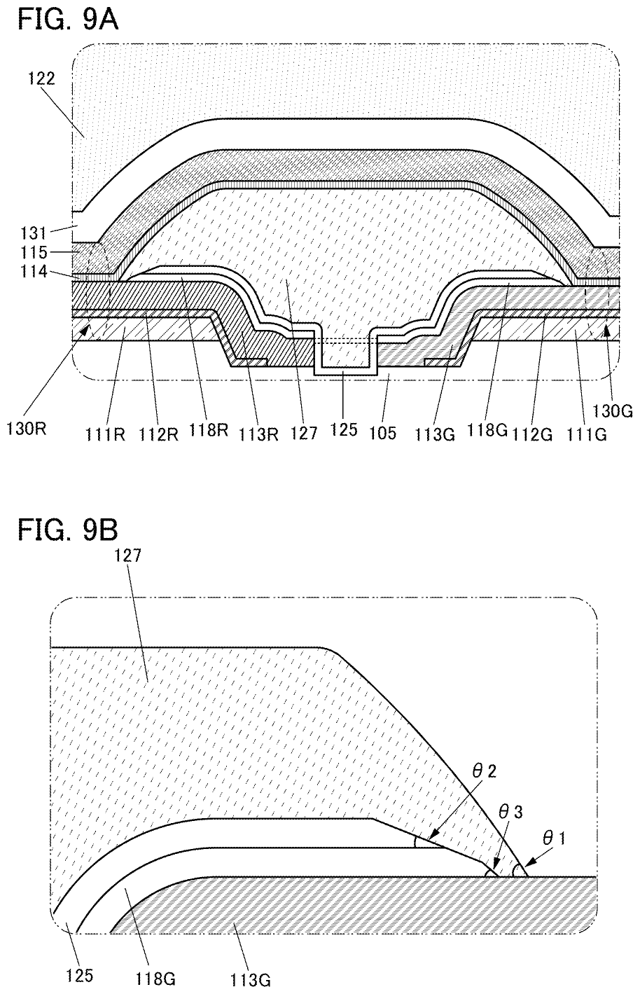

FIG. 8A and FIG. 9A show variation examples of the structure in FIG. 4A, and FIG. 8B and FIG. 9B show variation examples of the structure in FIG. 4B. FIGS. 8A and 8B and FIGS. 9A and 9B illustrate examples where the top surface of the insulating layer 127 has a flat portion in the cross section.

FIGS. 8A and 8B illustrate an example where the insulating layer 127 covers part of the side surfaces of the mask layers 118R and 118G, and the other regions of the side surfaces of the mask layers 118R and 118G are exposed. FIGS. 9A and 9B illustrate an example where the insulating layer 127 touches and covers the entire side surface of the mask layer 118R and the entire side surface of the mask layer 118G.

In the structures illustrated in FIGS. 5B to 9B, each of the taper angles θ1 to 03 is preferably in the range described with FIG. 4B.

It is preferable that one of the end portions of the insulating layer 127 overlap the top surface of the conductive layer 111R and the other end portion of the insulating layer 127 overlap the top surface of the conductive layer 111G, as illustrated in FIGS. 4A to 9A. With such a structure, the end portions of the insulating layer 127 can be formed over substantially flat regions of the EL layers 113R and 113G. Thus, it becomes relatively easy to form tapered shapes of the insulating layer 127, the insulating layer 125, the mask layer 118R, and the mask layer 118G. Furthermore, peeling of the conductive layers 111R, 111G, 112R, and 112G and the EL layers 113R and 113G can be inhibited. In contrast, as a region where the insulating layer 127 overlaps the top surface of the pixel electrode is smaller, a larger light-emitting region of the light-emitting element and a higher aperture ratio are achieved, which is preferable.

As described above, in the structures illustrated in FIGS. 4A to 9A and FIGS. 4B to 9B, providing the insulating layers 127 and 125 and the mask layers 118R and 118G enables the common layer 114 and the common electrode 115 to be formed to favorably cover the entire region from the substantially flat region of the EL layer 113R to the substantially flat region of the EL layer 113G. Moreover, formation of a disconnection portion and a local thinning portion can be suppressed in the common layer 114 and the common electrode 115. Thus, a connection defect due to a disconnection portion and an increase in electrical resistance due to a local thinning portion can be inhibited from occurring in the common layer 114 and the common electrode 115 between the light-emitting elements 130. Consequently, the display device 100 can have high display quality.

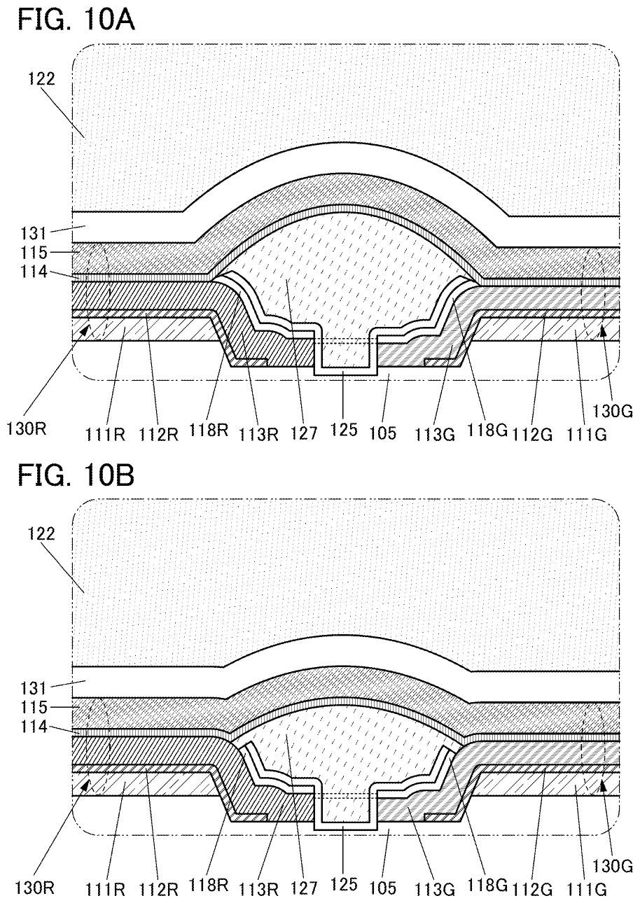

FIGS. 10A and 10B show variation examples of the structure illustrated in FIG. 4A. FIG. 10A illustrates an example where the insulating layer 127 does not overlap the top surface of the conductive layer 111 and the end portion of the insulating layer 127 overlaps the side surface of the conductive layer 111. FIG. 10B illustrates an example where the insulating layer 127 overlaps neither the top surface nor the side surface of the conductive layer 111. Even such a structure can improve coverage with the common layer 114 and the common electrode 115, as compared to a structure where the mask layer 118, the insulating layer 125, and the insulating layer 127 are not provided.

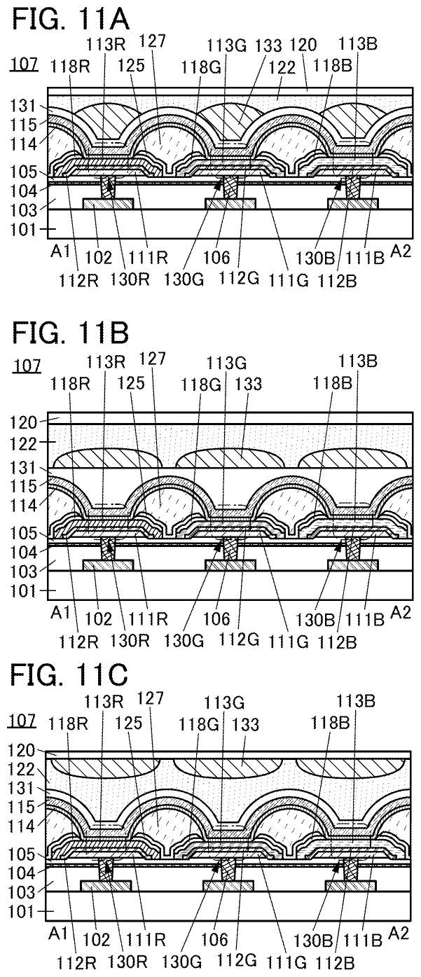

FIGS. 11A to 11C are cross-sectional views illustrating structure examples of the pixel portion 107 and show variation examples of the structure illustrated in FIG. 1B. FIGS. 11A to 11C illustrate examples where a lens array 133 is provided in the pixel portion 107. The lens array 133 can be provided to overlap the light-emitting elements 130.

FIGS. 11A and 11B illustrate examples where the lens array 133 is provided over the light-emitting elements 130 with the protective layer 131 therebetween. The lens array 133 is provided over the protective layer 131, and the protective layer 131 and the lens array 133 are attached to the substrate 120 with the resin layer 122, whereby alignment of the light-emitting elements 130 and the lens array 133 can be highly accurate. FIG. 11B illustrates an example where a layer having a planarization function is used as the protective layer 131.

FIG. 11C illustrates an example where the substrate 120 provided with the lens array 133 is attached to the protective layer 131 with the resin layer 122. Providing the lens array 133 on the substrate 120 can increase the temperature of heat treatment in the step of forming the lens array 133.

The lens array 133 may have a convex surface facing the substrate 120 side or a convex surface facing the light-emitting element 130.

The lens array 133 can be formed using at least one of an inorganic material and an organic material. When the protective layer 131 does not have a planarization function as illustrated in FIGS. 11A and 11C, an inorganic material can be used for the protective layer 131, for example. Meanwhile, when the protective layer 131 has a planarization function as illustrated in FIG. 11B, an organic material can be used for the protective layer 131, for example. Examples of the inorganic material include an oxide and a sulfide. Examples of the organic material include a resin.

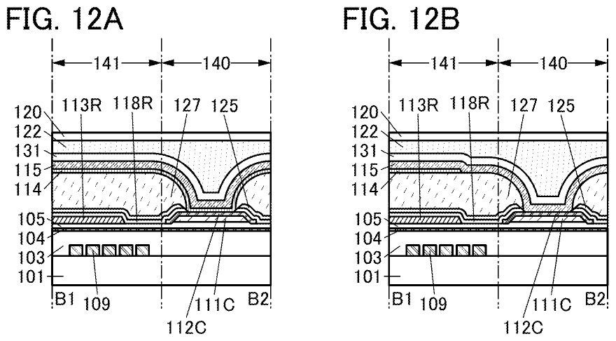

FIG. 12A is a cross-sectional view illustrating a structure example of the region 141 and the connection portion 140. In the region 141, a conductive layer 109 is provided over the insulating layer 101, and the insulating layer 103 is provided over the insulating layer 101 and the conductive layer 109. The conductive layer 109 can be formed in the same step as the conductive layer 102 illustrated in FIG. 1B and contain the same material as the conductive layer 102.

In the region 141, the EL layer 113R over the insulating layer 105, the mask layer 118R over the insulating layer 105 and the EL layer 113R, the insulating layer 125 over the mask layer 118R, the insulating layer 127 over the insulating layer 125, the common layer 114 over the insulating layer 127, the common electrode 115 over the common layer 114, the protective layer 131 over the common electrode 115, the resin layer 122 over the protective layer 131, and the substrate 120 over the resin layer 122 are provided. In the region 141, the mask layer 118R is provided to cover the end portion of the EL layer 113R, for example. Note that in some cases, depending on the manufacturing process of the display device 100, for example, the EL layer 113G or the EL layer 113B is provided in the region 141 instead of the EL layer 113R. In some cases, the mask layer 118G or the mask layer 118B is provided in the region 141 instead of the mask layer 118R.

The EL layer 113R provided in the region 141 is not electrically connected to the common electrode 115. Accordingly, no voltage is applied to the EL layer 113R provided in the region 141, so that the EL layer 113R provided in the region 141 does not emit light.

Although the details will be described later, in the display device in which the EL layer 113R and the mask layer 118R are provided in the region 141, it is possible to prevent the insulating layers 105, 104, and 103 from being partly removed by etching or the like during the manufacturing process of the display device and thus prevent the conductive layer 109 from being exposed. Hence, the conductive layer 109 can be prevented from being unintentionally in the contact with other electrodes, layers, or the like. For example, a short circuit between the conductive layer 109 and the common electrode 115 can be prevented. Accordingly, the display device 100 can have high reliability. Moreover, the display device 100 can be manufactured by a method with a high yield.

The connection portion 140 includes the conductive layer 111C over the insulating layer 105, a conductive layer 112C covering the top surface and the side surface of the conductive layer 111C, the common layer 114 over the conductive layer 112C, the common electrode 115 over the common layer 114, the protective layer 131 over the common electrode 115, the resin layer 122 over the protective layer 131, and the substrate 120 over the resin layer 122. The mask layer 118R is provided to cover the end portion of the conductive layer 112C. The insulating layer 125, the insulating layer 127, the common layer 114, the common electrode 115, and the protective layer 131 are stacked in this order over the mask layer 118R. In the case where the mask layer 118G or the mask layer 118B is provided in the region 141 instead of the mask layer 118R, the mask layer 118G or the mask layer 118B is also provided in the connection portion 140 instead of the mask layer 118R.

In the connection portion 140, the conductive layers 111C and 112C are electrically connected to the common electrode 115. The conductive layers 111C and 112C are electrically connected to an FPC (not illustrated), for example. Accordingly, by supplying a power supply potential to the FPC, for example, the power supply potential can be supplied to the common electrode 115 through the conductive layers 111C and 112C.

Here, in the case where the electric resistance of the common layer 114 in the thickness direction is negligible, electrical continuity between the conductive layers 111C and 112C and the common electrode 115 can be maintained even when the common layer 114 is provided between the conductive layer 112C and the common electrode 115. When the common layer 114 is provided not only in the pixel portion 107 but also in the region 141 and the connection portion 140, the common layer 114 can be formed, for example, without using a metal mask such as a mask for specifying a film formation area (also referred to as an area mask or a rough metal mask to be distinguished from a fine metal mask). Thus, the manufacturing process of the display device 100 can be simplified.

FIG. 12B shows a variation example of the structure in FIG. 12A, and illustrates a structure where the common layer 114 is not provided in the connection portion 140. In the example in FIG. 12B, the conductive layer 112C and the common electrode 115 can be in contact with each other. Thus, electric resistance between the conductive layer 112C and the common electrode 115 can be decreased. Although FIG. 12B illustrates a structure where in the region 141, the common layer 114 is provided in a region overlapping the EL layer 113R and the common layer 114 is not provided in a region not overlapping the EL layer 113R, one embodiment of the present invention is not limited thereto. For example, in the region 141, it is possible that the common layer 114 is not provided in a region overlapping the EL layer 113R, or the common layer 114 is provided in a region not overlapping the EL layer 113R.

### [Structure Example 2]

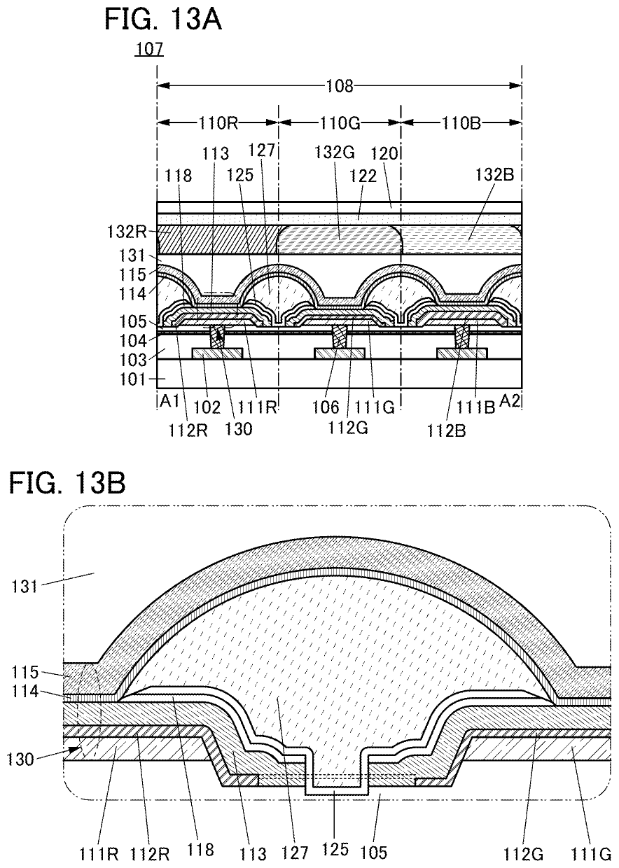

FIG. 13A shows a variation example of the structure in FIG. 1B, and illustrates an example in which the subpixel 110R includes a coloring layer 132R, the subpixel 110G includes a coloring layer 132G, and the subpixel 110B includes a coloring layer 132B.

As illustrated in FIG. 13A, the coloring layers 132R, 132G, and 132B can be provided over the protective layer 131. In this case, the protective layer 131 is preferably planarized but is not necessarily planarized.

In the example illustrated in FIG. 13A, the light-emitting element 130 included in the subpixel 110R, the light-emitting element 130 included in the subpixel 110G, and the light-emitting element 130 included in the subpixel 110B can emit light of the same color, e.g., white light. In this case, for example, when the coloring layer 132R transmits red light, the coloring layer 132G transmits green light, and the coloring layer 132B transmits blue light, the display device 100 having the structure illustrated in FIG. 13A can perform full-color display. Note that the coloring layer 132R, the coloring layer 132G, or the coloring layer 132B may transmit cyan light, magenta light, yellow light, white light, infrared light, or the like. The light-emitting element 130 may emit infrared light, for example.

Since the EL layers 113 do not have to be formed separately for different emission colors in the display device 100 having the structure illustrated in FIG. 13A, the manufacturing process of the display device 100 can be simplified. Consequently, the manufacturing cost of the display device 100 can be reduced, making the display device 100 inexpensive.

The adjacent coloring layers 132 include an overlap region over the insulating layer 127. For example, in the cross section illustrated in FIG. 13A, one end portion of the coloring layer 132G overlaps the coloring layer 132R, and the other end portion of the coloring layer 132G overlaps the coloring layer 132B. This can prevent leakage of light from the light-emitting element 130 to the adjacent subpixels 110. Thus, for example, light emitted from the light-emitting element 130 provided in the subpixel 110G can be prevented from entering the coloring layers 132R and 132B. Consequently, the display device 100 can have high display quality.

FIG. 13B is a cross-sectional enlarged view of a region including the insulating layer 127 between the two EL layer 113 in FIG. 13A and the vicinity thereof. FIG. 13B illustrates the conductive layer 111R and the conductive layer 111G as the conductive layer 111, and the conductive layer 112R and the conductive layer 112G as the conductive layer 112. The shapes of the mask layer 118, the insulating layer 125, the insulating layer 127, and the like illustrated in FIG. 13B are similar to those in FIG. 4A.

As illustrated in FIGS. 13A and 13B, the conductive layers 112R, 112G, and 112B can have different thicknesses. In FIG. 13B, different thicknesses of the conductive layers 112R and 112G are indicated by dotted lines.

For example, the thickness of each of the conductive layers 112R, 112G, and 112B is preferably set in accordance with an optical path length for intensifying light of the color that passes through the coloring layer 132. For example, in the case where the coloring layer 132R transmits red light, the thickness of the conductive layer 112R is preferably set to intensify red light; in the case where the coloring layer 132G transmits green light, the thickness of the conductive layer 112G is preferably set to intensify green light; in the case where the coloring layer 132B transmits blue light, the thickness of the conductive layer 112B is preferably set to intensify blue light. Thus, a microcavity structure is achieved, and the color purity of light emitted from the subpixels 110 can be improved. Note that the conductive layers 112R, 112G, and 112B may have different thicknesses in the structure illustrated in FIG. 1B, for example. In that case, a microcavity structure is achieved even when the EL layers 113R, 113G, and 113B have the same thickness. Here, in the case where the microcavity structure can sufficiently improve the color purity of light emitted from the subpixels 110, the coloring layer 132 is not necessarily provided in the subpixels 110.

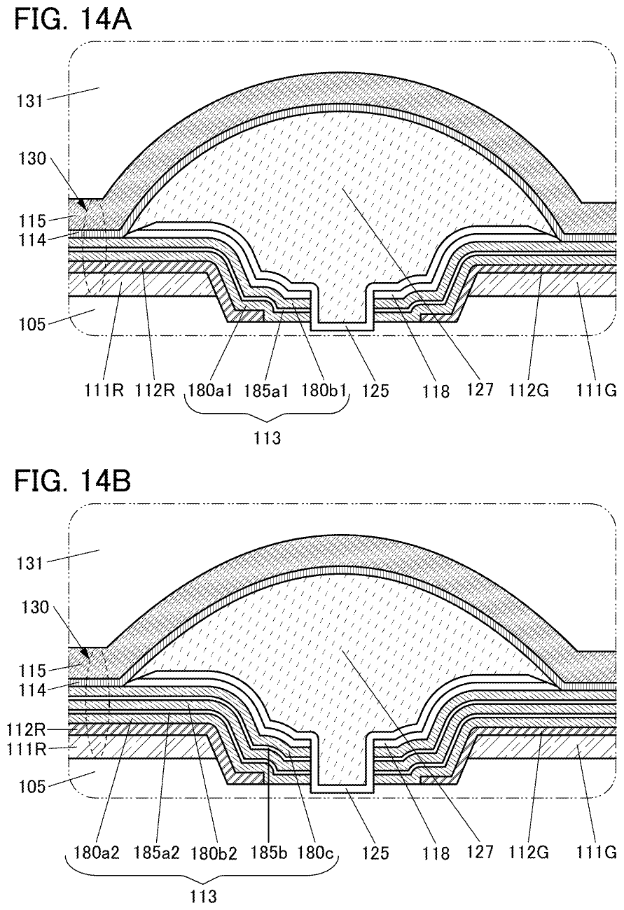

Although the light-emitting element 130 has a single structure in FIG. 13B, the light-emitting element 130 may have a tandem structure. FIG. 14A illustrates an example in which the EL layer 113 includes a light-emitting unit 180a1, a charge-generation layer 185a1 over the light-emitting unit 180a1, and a light-emitting unit 180b1 over the charge-generation layer 185a1. The light-emitting element 130 including the EL layer 113 illustrated in FIG. 14A has a two-unit tandem structure. When the light-emitting element 130 has a tandem structure, the current efficiency for light emission can be increased, so that the light emission efficiency of the light-emitting element 130 can be increased. Alternatively, the density of current flowing through the light-emitting element 130 can be reduced at the same luminance; thus, power consumption of the display device 100 including the light-emitting element 130 can be reduced. When the light-emitting element 130 has a tandem structure, the reliability of the light-emitting element 130 can be increased.

The light-emitting units 180a1 and 180b1 each include at least one light-emitting layer. The color of light emitted from the light-emitting unit 180a1 can be different from the color of light emitted from the light-emitting unit 180b1.

In this specification and the like, light emitted from a light-emitting layer included in a light-emitting unit is referred to as light emitted from the light-emitting unit.

The color of light emitted from the light-emitting unit 180a1 and the color of light emitted from the light-emitting unit 180b1 can be complementary colors, for example. For example, one of the light-emitting units 180a1 and 180b1 can emit blue light and the other of the light-emitting units 180a1 and 180b1 can emit yellow light. As another example, one of the light-emitting units 180a1 and 180b1 can be emit blue light and the other of the light-emitting units 180a1 and 180b1 can emit red light and green light. For example, when the conductive layers 111 and 112 function as the anode and the common electrode 115 functions as the cathode, the light-emitting unit 180a1 can emit blue light. Accordingly, the light-emitting element 130 can emit white light.

The light-emitting units 180a1 and 180b1 may each include a functional layer in addition to the light-emitting layer. For example, the light-emitting unit 180a1 can have a structure similar to that of the light-emitting unit 180a in FIG. 2B, and the light-emitting unit 180b1 can have a structure similar to that of the light-emitting unit 180b in FIG. 2B. In that case, the color of light emitted from the light-emitting layer 182a and the color of light emitted from the light-emitting layer 182b can be different as described above.

The charge-generation layer 185a1 includes at least a charge-generation region. The charge-generation layer 185a1 has a function of injecting electrons into one of the light-emitting units 180a1 and 180b1 and injecting holes to the other of the light-emitting units 180a1 and 180b1 when voltage is applied between the conductive layers 111 and 112 and the common electrode 115.

FIG. 14B illustrates an example in which the EL layer 113 includes a light-emitting unit 180a2, a charge-generation layer 185a2 over the light-emitting unit 180a2, a light-emitting unit 180b2 over the charge-generation layer 185a2, a charge-generation layer 185b over the light-emitting unit 180b2, and a light-emitting unit 180c over the charge-generation layer 185b. The light-emitting element 130 including the EL layer 113 illustrated in FIG. 14B has a three-unit tandem structure. By increasing the number of units in the tandem structure, the current efficiency of the light-emitting element 130 for light emission can be favorably increased, so that the light emission efficiency of the light-emitting element 130 can be favorably increased. Alternatively, the density of current flowing through the light-emitting element 130 can be favorably reduced at the same luminance; thus, power consumption of the display device 100 including the light-emitting element 130 can be favorably reduced. Moreover, the reliability of the light-emitting element 130 can be favorably increased. Note that the light-emitting element 130 may have a tandem structure with four or more units.

The light-emitting units 180a2, 180b2, and 180c each include at least one light-emitting layer. The color of light emitted from at least one of the light-emitting units 180a2, 180b2, and 180c can differ from the color(s) of light emitted from the other light-emitting unit(s). For example, the color of light emitted from at least one of the light-emitting units 180a2, 180b2, and 180c can be complementary to the color of light emitted from the other light-emitting unit(s).

For example, the light-emitting units 180a2 and 180c can emit blue light, and the light-emitting units 180b2 can emit yellow, yellow green, or green light. As another example, the light-emitting units 180a2 and 180c can emit blue light, and the light-emitting units 180b2 can emit red light, green light, and yellow green light. Accordingly, the light-emitting element 130 can emit white light.

The light-emitting units 180a2, 180b2, and 180c may each include a functional layer in addition to the light-emitting layer. For example, the light-emitting unit 180a2 can have a structure similar to that of the light-emitting unit 180a in FIG. 2B. The light-emitting units 180b2 and 180c can have a structure similar to that of the light-emitting unit 180b in FIG. 2B. Here, the color of light emitted from the light-emitting layer of the light-emitting unit 180a2, the color of light emitted from the light-emitting layer of the light-emitting unit 180b2, and the color of light emitted from the light-emitting layer of the light-emitting unit 180c can be as described above.

The charge-generation layers 185a2 and 185b each include at least a charge-generation region. The charge-generation layer 185a2 has a function of injecting electrons into one of the light-emitting units 180a2 and 180b2 and injecting holes to the other of the light-emitting units 180a2 and 180b2 when voltage is applied between the conductive layers 111 and 112 and the common electrode 115. The charge-generation layer 185b has a function of injecting electrons into one of the light-emitting units 180b2 and 180c and injecting holes to the other of the light-emitting units 180b2 and 180c when voltage is applied between the conductive layers 111 and 112 and the common electrode 115.

### [Structure Example 3]

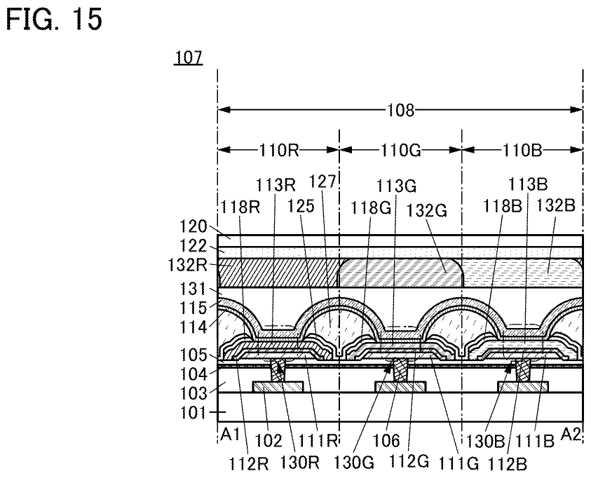

FIG. 15 shows a variation example of the structure in FIG. 1B, and illustrates an example in which the subpixel 110R includes the coloring layer 132R, the subpixel 110G includes the coloring layer 132G, and the subpixel 110B includes the coloring layer 132B. As illustrated in FIG. 15, the coloring layers 132R, 132G, and 132B can be provided over the protective layer 131. In this case, the protective layer 131 is preferably planarized but is not necessarily planarized.

In FIG. 15, as in the pixel 108 illustrated in FIG. 1B, for example, the EL layer 113R provided in the subpixel 110R, the EL layer 113G provided in the subpixel 110G, and the EL layer 113B provided in the subpixel 110B emit light of different colors. For example, the EL layers 113R, 113G, and 113B emit red light, green light, and blue light, respectively. This differs from FIG. 13A in which the EL layer 113 emits white light, for example. As in the pixel 108 in FIG. 1B, the EL layers 113R, 113G, and 113B have different thicknesses, whereby a microcavity structure is obtained.

When the subpixel 110 is provided with the coloring layer 132 and employs a microcavity structure as illustrated in FIG. 15, external light that enters the subpixel 110 and is reflected by the pixel electrode, for example, can be prevented from being observed without providing a circular polarizing plate over the substrate 120, for instance. In addition, the color purity of light emitted from the subpixel 110 can be improved. Accordingly, the display device 100 including the pixel portion 107 with the structure illustrated in FIG. 15 can have high display quality. Note that the subpixel 110 including the coloring layer 132 does not necessarily employ a microcavity structure. Even in the case where a microcavity structure is not employed, the color purity of light emitted from the subpixel 110 can be improved as compared to the case where the coloring layer 132 is not provided in the subpixel 110.

In the display device of one embodiment of the present invention, the island-shaped EL layer is provided in each light-emitting element, whereby generation of leakage current between the subpixels can be suppressed. This can prevent crosstalk due to unintended light emission, so that a display device with extremely high contrast can be obtained. An insulating layer whose end portion has a tapered shape is provided between the adjacent island-shaped EL layers, whereby occurrence of disconnection and local thinning can be inhibited at the time of forming the common electrode. Thus, a connection defect due to a disconnection portion and an increase in electrical resistance due to a local thinning portion can be inhibited from occurring in the common layer and the common electrode. Consequently, the display device of one embodiment of the present invention achieves both high resolution and high display quality.

### [Manufacturing Method Example 1]

An example of a method for manufacturing the display device 100 having the structures illustrated in FIG. 1B, FIG. 2A, FIG. 4A, and FIG. 12A will be described below.

Thin films included in the display device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like. Examples of a CVD method include a plasma-enhanced CVD (PECVD) method and a thermal CVD method. An example of a thermal CVD method is a metal organic CVD (MOCVD) method.

Thin films included in the display device (e.g., insulating films, semiconductor films, and conductive films) can also be formed by a wet process such as spin coating, dipping, spray coating, ink-jetting, dispensing, screen printing, offset printing, doctor blade coating, slit coating, roll coating, curtain coating, or knife coating.

In this specification and the like, “deposition of a film” is sometimes referred to as “formation of a film”.

Specifically, for fabrication of the light-emitting element, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, the functional layers (e.g., the hole-injection layer, the hole-transport layer, the hole-blocking layer, the electron-blocking layer, the electron-transport layer, and the electron-injection layer) included in the EL layer can be formed by an evaporation method (e.g., a vacuum evaporation method), a coating method (e.g., a dip coating method, a die coating method, a bar coating method, a spin coating method, or a spray coating method), a printing method (e.g., an ink-jet method, screen printing (stencil), offset printing (planography), flexography (relief printing), gravure printing, or micro-contact printing), or the like.

Thin films included in the display device can be processed by a photolithography method, for example. Alternatively, a nanoimprinting method, a sandblasting method, a lift-off method, or the like may be used to process thin films. Alternatively, island-shaped thin films may be directly formed by a film formation method using a shielding mask such as a metal mask.

There are two typical examples of photolithography methods. In one of the methods, a resist mask is formed over a thin film that is to be processed, the thin film is processed by etching, for example, and then the resist mask is removed. In the other method, a photosensitive thin film is formed and then processed into a desired shape by light exposure and development.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used. It is preferable to use EUV light, X-rays, or an electron beam because extremely minute processing can be performed. Note that when exposure is performed by scanning of a beam such as an electron beam, a photomask is not needed.

For etching of thin films, a dry etching method, a wet etching method, a sandblast method, or the like can be used.

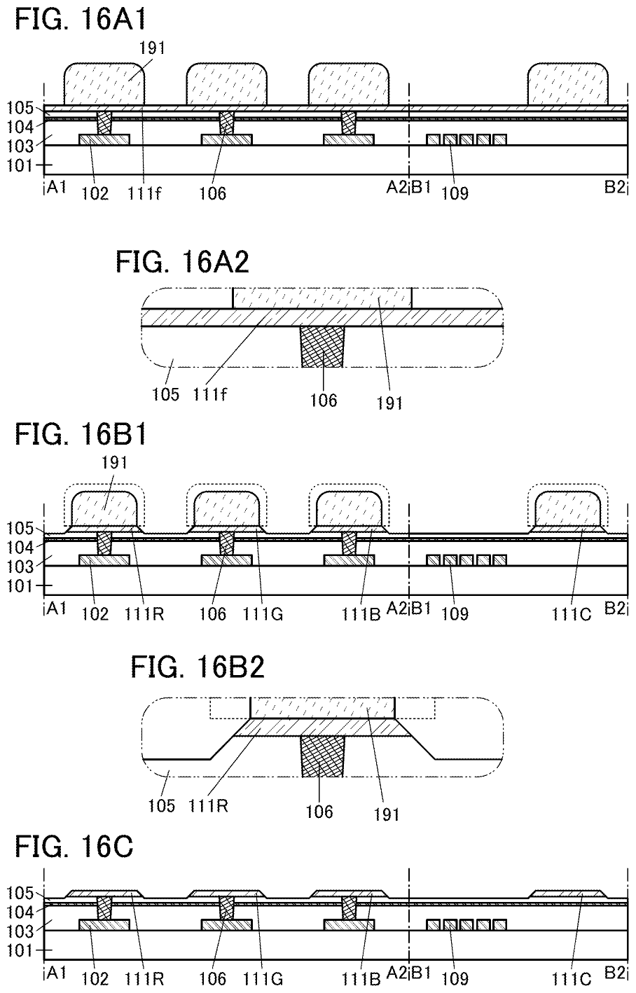

First, as illustrated in FIG. 16A1, the insulating layer 101 is formed over a substrate (not illustrated). Next, the conductive layer 102 and the conductive layer 109 are formed over the insulating layer 101, and the insulating layer 103 is formed over the insulating layer 101 so as to cover the conductive layer 102 and the conductive layer 109. Then, the insulating layer 104 is formed over the insulating layer 103, and the insulating layer 105 is formed over the insulating layer 104. Note that FIG. 16A1 illustrates a cross section along the dashed-dotted line A1-A2 and a cross section along the dashed-dotted line B1-B2 in FIG. 1A. In some cases, other diagrams showing the example of the method for manufacturing the display device also illustrate a cross section along the dashed-dotted line A1-A2 and a cross section along the dashed-dotted line B1-B2 in FIG. 1A.

As the substrate, a substrate that has heat resistance high enough to withstand at least heat treatment performed later can be used. When an insulating substrate is used, it is possible to use a glass substrate, a quartz substrate, a sapphire substrate, a ceramic substrate, an organic resin substrate, or the like. Alternatively, it is possible to use a semiconductor substrate such as a single crystal semiconductor substrate or a polycrystalline semiconductor substrate of silicon, silicon carbide, or the like; a compound semiconductor substrate of silicon germanium or the like; or an SOI substrate.

Next, as illustrated in FIG. 16A1, openings reaching the conductive layer 102 are formed in the insulating layers 105, 104, and 103. Then, the plugs 106 are formed to fill the openings.

Subsequently, the plugs 106 and the insulating layer 105 are preferably subjected to planarization treatment using a chemical mechanical polishing (CMP) method, for example. Thus, the adhesion between the insulating layer 105 and the layer provided over the insulating layer 105 can be increased, for example.

Next, as illustrated in FIG. 16A1, a conductive film 111f to be the conductive layers 111R, 111G, 111B, and 111C is formed over the plugs 106 and the insulating layer 105. The conductive film 111f can be formed by a sputtering method or a vacuum evaporation method, for example.

FIG. 16A2 is an enlarged view of the conductive film 111f and a region around the conductive film 111f in the cross-sectional view of FIG. 16A1. The conductive film 111f can have a single-layer structure.

The conductive film 111f is formed using a material that is not easily oxidized when being in contact with the conductive layer 112a formed in a later step and has electrical resistivity unlikely to increase significantly even when being oxidized, for example. For example, the conductive film 111f is formed using a material that is less likely to be oxidized than aluminum when being in contact with the conductive layer 112a formed in a later step, for instance, and whose oxide has a lower electric resistivity than aluminum oxide. For example, the conductive film 111f can be formed using titanium or an alloy containing titanium. In the above manner, a change in properties of the conductive film 111f is inhibited, and the display device 100 can be manufactured by a method with a high yield. The display device 100 can be highly reliable. Note that a metal other than titanium may be used for the conductive film 111f.

Then, as illustrated in FIGS. 16A1 and 16A2, a resist mask 191 is formed over the conductive film 111f. The resist mask 191 can be formed by application of a photosensitive material (photoresist), light exposure, and development.

Subsequently, as illustrated in FIGS. 16A1 and 16B1, the conductive film 111f in a region that is not overlapped by the resist mask 191, for example, is removed by an etching method, specifically, a dry etching method, for instance. Thus, the conductive layers 111R, 111G, 111B, and 111C are formed. Here, in the case where part of the conductive film 111f is removed by a dry etching method, for example, a depression portion may be formed in a region of the insulating layer 105 that is not overlapped by the conductive layer 111. Note that the conductive film 111f may be removed by a wet etching method.

FIG. 16B2 is an enlarged view of the conductive layer 111R and a region around the conductive layer 111R in the cross-sectional view of FIG. 16B1. FIG. 16B2 illustrates an example where a depression portion is formed in a region of the insulating layer 105 that is not overlapped by the conductive layer 111R.

Here, when the conductive film 111f is processed under conditions where the resist mask 191 is easily recessed (reduced in size) as compared to the case where the conductive layer 111 is formed so that the side surface does not have a tapered shape (i.e., the conductive layer 111 is formed to have a perpendicular side surface), the side surface of the conductive layer 111 can have a tapered shape. Specifically, the side surface of the conductive layer 111 can have a tapered shape with a taper angle less than 90° in the cross section. In FIGS. 16B1 and 16B2, the shape of the resist mask 191 before processing of the conductive film 111f is indicated by dotted lines.

In the case where a depression portion is formed in a region of the insulating layer 105 that is not overlapped by the conductive layer 111R, the side surface of the depression portion may also have a tapered shape with a taper angle less than 90° in the cross section. Here, in some case, an upper end portion of the side surface of the depression portion of the insulating layer 105 is aligned with a lower end portion of the side surface of the conductive layer 111. In some case, the taper angle of the side surface of the depression portion of the insulating layer 105 matches or does not match the taper angle of the side surface of the conductive layer 111. The taper angle of the side surface of the depression portion of the insulating layer 105 and the taper angle of the side surface of the conductive layer 111 may vary because of the difference between the etching rate of the insulating layer 105 and the etching rate of the conductive film 111f, for example. As another example, the taper angle of the side surface of the depression portion of the insulating layer 105 may be larger than the taper angle of the side surface of the conductive layer 111.

Next, the resist mask 191 is removed as illustrated in FIGS. 16B1 and 16C. The resist mask 191 can be removed by ashing using oxygen plasma, for example. Alternatively, an oxygen gas and CF₄, C₄F₈, SF₆, CHF₃, Cl₂, H₂O, BCl₃, or a Group 18 element may be used. As the Group 18 element, He can be used, for example. Alternatively, the resist mask 191 may be removed by wet etching.

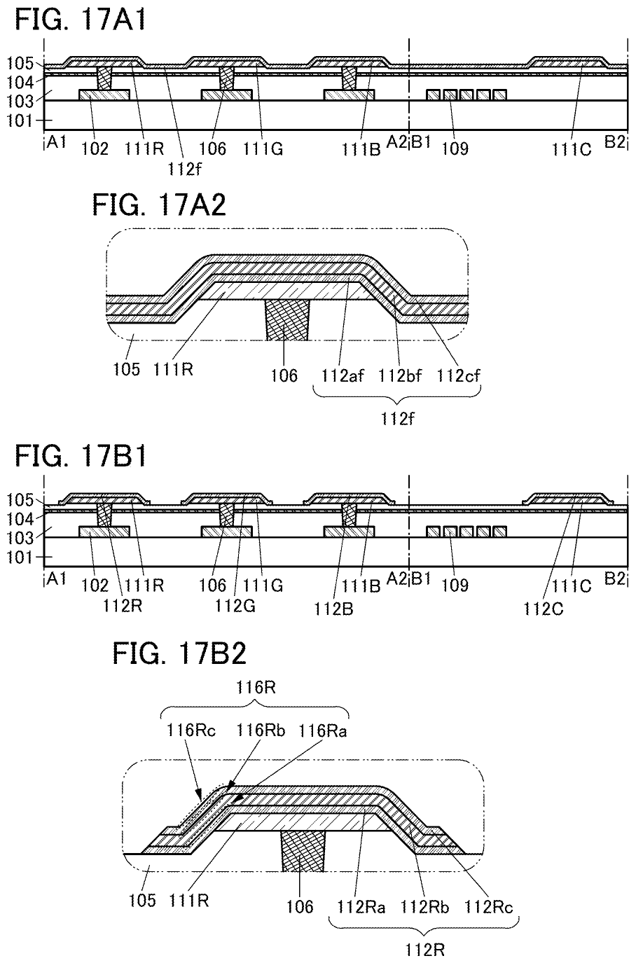

Next, as illustrated in FIG. 17A1, a conductive film 112f to be the conductive layers 112R, 112G, 112B, and 112C is formed over the conductive layers 111R, 111G, 111B, and 111C and the insulating layer 105. Specifically, the conductive film 112f is formed to cover the conductive layers 111R, 111G, 111B, and 111C, for example.

FIG. 17A2 is an enlarged view of the conductive layer 111R, the conductive film 112f, and a region around them in the cross-sectional view of FIG. 17A1. The conductive film 112f includes a conductive film 112af to be the conductive layer 112a, a conductive film 112bf to be the conductive layer 112b over the conductive film 112af, and a conductive film 112cf to be the conductive layer 112c over the conductive film 112bf. The conductive films 112af, 112bf, and 112cf can be formed by a sputtering method or a vacuum evaporation method, for example.

The conductive film 112af has higher adhesion to the conductive film 112bf than the insulating layer 105 does, for example. For the conductive film 112af, an oxide containing one or more selected from indium, tin, zinc, gallium, titanium, aluminum, and silicon, for example, indium tin oxide or indium tin oxide containing silicon can be used. As illustrated in FIG. 17A2, the conductive film 112af is in contact with the insulating layer 105, and the conductive film 112bf is not in contact with the insulating layer 105.

The conductive film 112bf is a film that has a higher visible light reflectance than the conductive films 111f, 112af, and 112cf. For the conductive film 112bf, a material having a higher visible light reflectance than aluminum can be used, for example. Specifically, for the conductive film 112bf, silver or an alloy containing silver can be used, for example. Accordingly, the display device 100 can have high outcoupling efficiency. Note that a metal other than silver may be used for the conductive film 112bf.

When the pixel electrode of the light-emitting element 130 serves as the anode, a layer having a high work function is used as the conductive film 112cf. The conductive film 112cf has a higher work function than the conductive film 112bf, for example. Hence, the driving voltage of the light-emitting element 130 can be lowered. For the conductive film 112cf, a material similar to the material usable for the conductive film 112af can be used, for example. For example, the conductive films 112af and 112cf can be formed using the same kind of material. For example, in the case where indium tin oxide is used for the conductive film 112af, indium tin oxide can also be used for the conductive film 112cf.

When the pixel electrode of the light-emitting element 130 serves as the cathode, a layer having a low work function is used as the conductive film 112cf. The conductive film 112cf has a lower work function than the conductive film 112bf, for example. Hence, the driving voltage of the light-emitting element 130 can be lowered.

The conductive film 112cf is preferably a layer having high visible light transmittance. For example, the visible light transmittance of the conductive film 112cf is preferably higher than that of the conductive films 111f and 112bf. In that case, the display device 100 can have high outcoupling efficiency.

In the above manner, the display device 100 manufactured by a method with a high yield can have high outcoupling efficiency. In addition, the display device 100 can include a highly reliable light-emitting element with low driving voltage.

The conductive films 112af and 112cf that can use an oxide can be formed by an ALD method as well as a sputtering method and a vacuum evaporation method described above. In the case of using an ALD method, the conductive film 112af or the conductive film 112cf can be formed by repeating a cycle of introduction of a precursor (generally referred to as a metal precursor or the like in some cases), purge of the precursor, introduction of an oxidizer (generally referred to as a reactant, a non-metal precursor, or the like in some cases), and purge of the oxidizer. Here, in the case where an oxide film containing a plurality of kinds of metal (e.g., indium tin oxide) is formed as the conductive film 112af or the conductive film 112cf, the composition of the metals can be controlled by varying the number of cycles for different kinds of precursor.

For example, in the case where an indium tin oxide film is formed as the conductive film 112af or the conductive film 112cf, after a precursor containing indium is introduced, the precursor is purged and an oxidizer is introduced to form an In—O film, and then a precursor containing tin is introduced, the precursor is purged and an oxidizer is introduced to form a Sn—O film. Here, when the number of cycles of forming an In—O film is larger than the number of cycles of forming a Sn—O film, the number of In atoms contained in the conductive film 112af or the conductive film 112cf can be larger than the number of Sn atoms.

For example, to form a zinc oxide film, a Zn—0 film is formed in the above procedure. As another example, to form an aluminum zinc oxide film, a Zn—0 film and an Al—O film are formed in the above procedure. As another example, to form a titanium oxide film, a Ti—O film is formed in the above procedure. As another example, to form an indium tin oxide film containing silicon, an In—O film, a Sn—O film, and a Si—O film are formed in the above procedure. As another example, to form a zinc oxide film containing gallium, a Ga—O film and a Zn—O film are formed in the above procedure.

As a precursor containing indium, it is possible to use, for example, triethylindium, trimethylindium, or [1,1,1-trimethyl-N-(trimethylsilyl)amide]-indium. As a precursor containing tin, it is possible to use, for example, tin chloride or tetrakis(dimethylamido)tin. As a precursor containing zinc, it is possible to use, for example, diethylzinc or dimethylzinc. As a precursor containing gallium, it is possible to use, for example, triethylgallium. As a precursor containing titanium, it is possible to use, for example, titanium chloride, tetrakis(dimethylamido)titanium, or tetraisopropyl titanate. As a precursor containing aluminum, it is possible to use, for example, aluminum chloride or trimethylaluminum. As a precursor containing silicon, it is possible to use, for example, trisilylamine, bis(diethylamino)silane, tris(dimethylamino)silane, bis(tert-butylamino)silane, or bis(ethylmethylamino)silane. As the oxidizer, water vapor, oxygen plasma, or an ozone gas can be used.

Then, as illustrated in FIGS. 17A1 and 17B1, the conductive film 112f is processed by a photolithography method, for example, whereby the conductive layers 112R, 112G, 112B, and 112C are formed. Specifically, after the resist mask is formed, part of the conductive film 112f is removed by an etching method, for example. Through the above steps, the pixel electrode including the conductive layer 111 and the conductive layer 112 is formed.

FIG. 17B2 is an enlarged view of the conductive layers 111R and 112R and a region around them in the cross-sectional view of FIG. 17B1. The conductive layer 112R includes a conductive layer 112Ra, a conductive layer 112Rb over the conductive layer 112Ra, and a conductive layer 112Rc over the conductive layer 112Rb.

The conductive films 112af, 112bf, and 112cf can be processed by a wet etching method, for example. In this case, the etching conditions for the conductive films 112af, 112bf, and 112cf are not necessarily the same; for example, they can differ depending on the materials used for the conductive films. For example, the etching conditions for the conductive films 112af and 112cf, which can use an oxide such as indium tin oxide, may be different from the etching conditions for the conductive film 112bff, which can use a metal such as silver or an alloy containing silver. Note that the conductive films 112af, 112bf, and 112cf may be processed by a dry etching method. The conductive films 112af, 112bf, and 112cf are not necessarily processed by the same method; for example, different processing methods may be employed in accordance with the materials used for the conductive films. For example, the conductive films 112af and 112cf may be processed by a wet etching method, and the conductive film 112bf may be processed by a dry etching method.

Here, when the conductive film 112bf is processed by a wet etching method and the adhesion between the conductive film 112bf and the layer provided under the conductive film 112bf is low, an etching solution may enter below the conductive film 112bf and the conductive film 112bf may be easily etched in the horizontal direction. Thus, in some cases, the end portion of the conductive layer 112Rb is positioned on the inner side of the end portion of the conductive layer 112Rc, for example. That is, the conductive layer 112Rc may include a protruding portion that is a region not overlapping the conductive layer 112Rb. Moreover, the angle of the end portion of the conductive layer 112Rb may be larger than 90° in the cross section. That is, the end portion of the conductive layer 112Rb may have an inversely tapered shape. Accordingly, disconnection or local thinning is sometimes caused in a layer that is provided to cover the conductive layer 112R in a subsequent step, for example, in the EL layer 113R.

In view of the above, the conductive film 112af is a film having high adhesion to the conductive film 112bf. As described above, the conductive film 112af has higher adhesion to the insulating layer 112bf than the conductive layer 105 does, for example. In that case, the conductive layer 112Rc does not have a protruding portion, and even when a protruding portion is formed in the conductive layer 112Rc, the protruding portion can be small in size. Furthermore, an inversely tapered shape can be prevented from being formed at the end portion of the conductive layer 112Rb. Here, the size of the protruding portion of the conductive layer 112Rc can be represented by the length in the horizontal direction of a region where the conductive layer 112Rc does not overlap the conductive layer 112Rb in the cross section or the area of the region in the top view.

Accordingly, occurrence of disconnection and local thinning can be prevented in a layer that is formed in a later step to cover the conductive layer 112R, specifically, the EL layer 113R, for example. Thus, the display device 100 can be manufactured by a method with a high yield. Moreover, the display device 100 can have high reliability.

FIG. 17B2 illustrates an example in which the end portions of the conductive layers 112Ra, 112Rb, and 112Rc are tapered. For example, in the case where the conductive layers 112Ra, 112Rb, and 112Rc are formed by a photolithography method, the conductive films 112af, 112bf, and 112cf are processed under the conditions where a resist mask is easily recessed (reduced in size) as compared to the case where the conductive layers 112Ra, 112Rb, and 112Rc are formed so that their side surfaces do not have a tapered shape (i.e., the conductive layers 112Ra, 112Rb, and 112Rc are formed to have a perpendicular side surface). Thus, the end portions of the conductive layers 112Ra, 112Rb, and 112Rc can have a tapered shape. Note that the end portions of the conductive layers 112Ra, 112Rb, and 112Rc are not necessarily tapered.

The conductive layer layers 112Ra, 112Rb, and 112Rc are formed to cover the conductive layer 111R and to be electrically connected to the conductive layer 111R. The conductive layers 112Ra, 112Rb, and 112Rc are formed to include a taper portion 116Ra, a tapered portion 116Rb, and a tapered portion 116Rc, respectively, in a region overlapping the side surface of the conductive layer 111R. Here, when the depression portion of the insulating layer 105 has a tapered side surface, the taper portions 116Ra, 116Rb, and 116Rc may have a region overlapping the side surface of the depression portion of the insulating layer 105. Note that the taper portions 116Ra, 116Rb, and 116Rc are collectively referred to as a tapered portion 116R.

By forming the conductive layer 112R to include the tapered portion 116R, occurrence of disconnection and local thinning, for example, can be prevented in the EL layer 113R, which is formed in a later step. Hence, the display device 100 can be manufactured by a method with a high yield. Moreover, the display device 100 can have high reliability.

The above description of the conductive layer 112R can also apply to the conductive layers 112G, 112B, and 112C by appropriately replacing terms as needed, for example.

Next, hydrophobic treatment is preferably performed on the conductive layer 112, specifically, the conductive layer 112c, for example. The hydrophobic treatment can change the hydrophilic properties of the subject surface to hydrophobic properties or increase the hydrophobic properties of the subject surface. The hydrophobic treatment for the conductive layer 112 can increase the adhesion between the conductive layer 112 and the EL layer 113 formed in a later step and suppress film peeling. Note that the hydrophobic treatment is not necessarily performed.

The hydrophobic treatment can be performed by fluorination of the conductive layer 112, for example. The fluorination can be performed, for example, by treatment or heat treatment using a gas containing fluorine or plasma treatment in a gas atmosphere containing fluorine. As the gas containing fluorine, a fluorine gas such as a fluorocarbon gas can be used, for example. As a fluorocarbon gas, a low carbon fluoride gas such as a carbon tetrafluoride (CF₄) gas, a C₄F₆ gas, a C₂F₆ gas, a C₄F₈ gas, or a C₅F₈ gas can be used, for example. Moreover, as the gas containing fluorine, a SF₆ gas, a NF₃ gas, or a CHF₃ gas can be used, for example. Furthermore, a helium gas, an argon gas, a hydrogen gas, an oxygen gas, or the like can be added to any of these gases as appropriate.

The surface of the conductive layer 112 can also be made hydrophobic by being subjected to plasma treatment in a gas atmosphere containing a Group 18 element such as argon, followed by treatment using a silylation agent. As the silylation agent, hexamethyldisilazane (HMDS), trimethylimidazole (TMSI), or the like can be used. Alternatively, the surface of the conductive layer 112 can be made hydrophobic by being subjected to plasma treatment in a gas atmosphere containing a Group 18 element such as argon, followed by treatment using a silane coupling agent.

Plasma treatment in a gas atmosphere containing a Group 18 element such as argon is performed on the surface of the conductive layer 112, whereby the surface of the conductive layer 112 can be damaged. Thus, a methyl group contained in the silylation agent such as HMDS can easily be bonded to the surface of the conductive layer 112. Moreover, silane coupling due to the silane coupling agent is likely to occur. Accordingly, the surface of the conductive layer 112 can be made hydrophobic by being subjected to plasma treatment in a gas atmosphere containing a Group 18 element such as argon, followed by treatment using the silylation agent or the silane coupling agent.

The treatment using the silylation agent, the silane coupling agent, or the like can be performed by application of the silylation agent, the silane coupling agent, or the like by a spin coating method or a dipping method, for example. The treatment using the silylation agent, the silane coupling agent, or the like can also be performed by forming a film containing the silylation agent, a film containing the silane coupling agent, or the like over the conductive layer 112 and the like by a gas phase method, for example. In a gas phase method, first, a material containing the silylation agent, a material containing the silane coupling agent, or the like is vaporized so that the silylation agent, the silane coupling agent, or the like is included in the atmosphere. Then, the substrate where the conductive layer 112, for example, is formed is put in the atmosphere. Thus, a film containing the silylation agent, the silane coupling agent, or the like can be formed over the conductive layer 112, and the surface of the conductive layer 112 can be made hydrophobic.

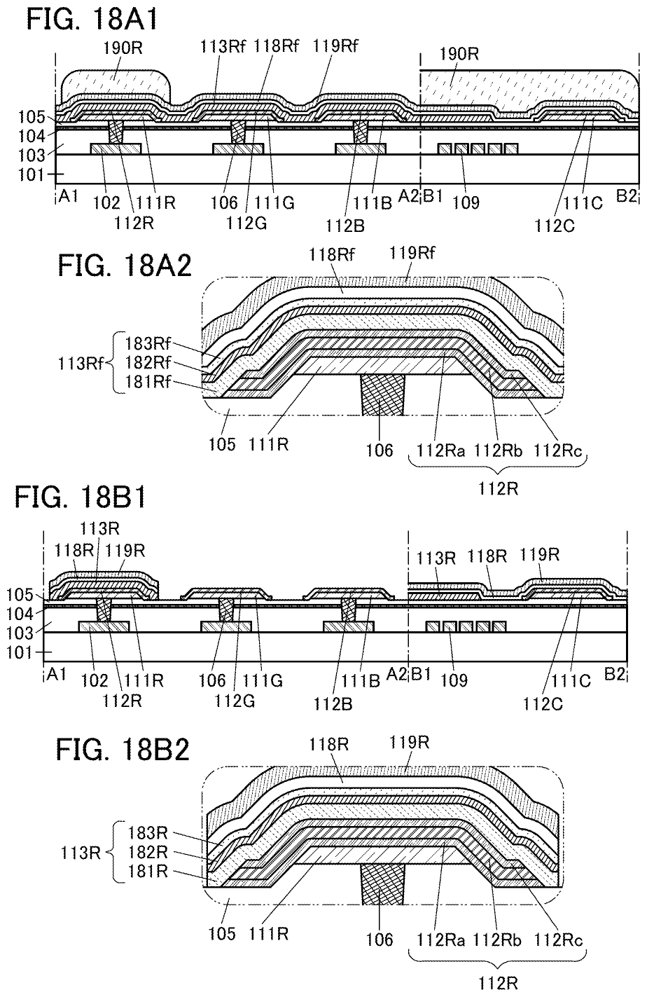

Next, as illustrated in FIG. 18A1, an EL film 113Rf to be the EL layer 113R is formed over the conductive layers 112R, 112G, and 112B and the insulating layer 105.

As illustrated in FIG. 18A1, the EL film 113Rf is not formed over the conductive layer 112C. The EL film 113Rf can be formed only in an intended region by using an area mask, for example. Employing a film formation step using an area mask and a processing step using a resist mask enables a light-emitting element to be manufactured by a relatively easy process.

The EL film 113Rf can be formed by an evaporation method, specifically a vacuum evaporation method, for example. The EL film 113Rf may be formed by a transfer method, a printing method, an inkjet method, a coating method, or the like.

FIG. 18A2 is a cross-sectional view illustrating a structure example of the conductive layer 111R, the conductive layer 112R, and the EL film 113Rf in FIG. 18A1 and their periphery. As illustrated in FIG. 18A2, the EL film 113Rf includes a functional film 181Rf to be a functional layer 181R, a light-emitting film 182Rf to be the light-emitting layer 182R over the functional film 181Rf, and a functional film 183Rf to be a functional layer 183R over the light-emitting film 182Rf. The functional layer 181Rf includes a region that covers the conductive layer 112R and is in contact with the conductive layer 112Rc.

In the case where the conductive layers 111R and 112R function as the anode, the functional film 181Rf includes one or both of a film to be a hole-injection layer and a film to be a hole-transport layer. For example, the functional film 181Rf includes a film to be a hole-injection layer and a film to be a hole-transport layer over the film. The functional film 183Rf includes, for example, a film to be an electron-transport layer.

In the case where the conductive layers 111R and 112R function as the cathode, the functional film 181Rf includes one or both of a film to be an electron-injection layer and a film to be an electron-transport layer. For example, the functional film 181Rf includes a film to be an electron-injection layer and a film to be an electron-transport layer over the film. The functional film 183Rf includes, for example, a film to be a hole-transport layer.

The conductive layer 112Rc includes a region in contact with the undermost layer, for example, among the layers provided in the functional film 181Rf. For example, in the case where the functional film 181Rf has a stacked-layer structure of a film to be a hole-injection layer and a film to be a hole-transport layer over the film, the conductive layer 112Rc includes a region in contact with the film to be the hole-injection layer. As another example, in the case where the functional film 181Rf has a stacked-layer structure of a film to be an electron-injection layer and a film to be an electron-transport layer over the film, the conductive layer 112Rc includes a region in contact with the film to be the electron-injection layer.

Providing the functional film 183Rf over the light-emitting film 182Rf can prevent the light-emitting film 182Rf from being at the uppermost surface of the EL film 113Rf. This makes it possible to reduce damage to the light-emitting film 182Rf in a later step. Thus, a highly reliable display device can be manufactured.

Next, as illustrated in FIG. 18A1, a mask film 118Rf to be the mask layer 118R and a mask film 119Rf to be a mask layer 119R are sequentially formed over the EL film 113Rf, the conductive layer 112C, and the insulating layer 105.

Although this embodiment shows an example where the mask film has a two-layer structure of the mask film 118Rf and the mask film 119Rf, the mask film may have a single-layer structure or a stacked-layer structure of three or more layers.

Providing the mask film over the EL film 113Rf can reduce damage to the EL film 113Rf in the manufacturing process of the display device, resulting in an increase in reliability of the light-emitting element.

For the mask film 118Rf, a film that is highly resistant to the process conditions for the EL film 113Rf, specifically, a film having high etching selectivity with the EL film 113Rf is used. For the mask film 119Rf, a film having high etching selectivity with the mask film 118Rf is used.

The mask films 118Rf and 119Rf are formed at a temperature lower than the upper temperature limit of the EL film 113Rf. The typical substrate temperatures in formation of the mask films 118Rf and 119Rf are each lower than or equal to 200° C., preferably lower than or equal to 150° C., further preferably lower than or equal to 120° C., still further preferably lower than or equal to 100° C., yet still further preferably lower than or equal to 80° C.

The mask films 118Rf and 119Rf are preferably films that can be removed by a wet etching method. The use of a wet etching method can reduce damage to the EL film 113Rf in processing of the mask films 118Rf and 119Rf, as compared to the case of using a dry etching method.

The mask films 118Rf and 119Rf can be formed by a sputtering method, an ALD method (including a thermal ALD method or a PEALD method), a CVD method, or a vacuum evaporation method, for example. Alternatively, the mask films 118Rf and 119Rf may be formed by the above-described wet process.

Note that the mask film 118Rf is preferably formed by a formation method that is less likely to damage the EL film 113Rf than a formation method for the mask film 119Rf. For example, the mask film 118Rf is preferably formed by an ALD method or a vacuum evaporation method rather than a sputtering method.

For each of the mask films 118Rf and 119Rf, one or more of a metal film, an alloy film, a metal oxide film, a semiconductor film, an organic insulating film, and an inorganic insulating film, for example, can be used.

For each of the mask films 118Rf and 119Rf, it is preferable to use a metal such as gold, silver, platinum, magnesium, nickel, tungsten, chromium, molybdenum, iron, cobalt, copper, palladium, titanium, aluminum, yttrium, zirconium, or tantalum or an alloy material containing any of the metals, for example. It is particularly preferable to use a low-melting-point material such as aluminum or silver. It is preferable to use a metal that can block ultraviolet rays for one or both of the mask films 118Rf and 119Rf, in which case the EL film 113Rf can be prevented from being irradiated with ultraviolet rays and deterioration of the EL film 113Rf can be suppressed.

For each of the mask films 118Rf and 119Rf, it is also possible to use a metal oxide such as indium gallium zinc oxide, indium oxide, indium zinc oxide, indium tin oxide, indium titanium oxide, indium tin zinc oxide, indium titanium zinc oxide, indium gallium tin zinc oxide, or indium tin oxide containing silicon.

In addition, in place of gallium described above, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, magnesium, and the like) may be used. In particular, Mis preferably one or more of gallium, aluminum, and yttrium.

As the mask film, a film containing a material having a light-blocking property, particularly with respect to ultraviolet rays, can be used. For example, a film having a property of reflecting ultraviolet rays or a film absorbing ultraviolet rays can be used. Although a variety of materials such as a metal, an insulator, a semiconductor, and a metalloid that have a property of blocking ultraviolet rays can be used as a light-blocking material, the mask film is preferably a film capable of being processed by etching and is particularly preferably a film having good processability because part or the whole of the mask film is removed in a later step.

For example, a semiconductor material such as silicon or germanium can be used as a material with an affinity for the semiconductor manufacturing process. An oxide or a nitride of the semiconductor material can be used. A non-metallic material such as carbon or a compound thereof can be used. A metal such as titanium, tantalum, tungsten, chromium, or aluminum or an alloy containing at least one of these metals can be used. An oxide or a nitride containing any of the above metals can be used. For example, titanium oxide, chromium oxide, titanium nitride, chromium nitride, or tantalum nitride can be used.

When a film containing a material having a property of blocking ultraviolet rays is used as the mask film, the EL layer can be prevented from being irradiated with ultraviolet rays in a light exposure step, for example. Thus, damage to the EL layer can be reduced, and the reliability of the light-emitting element can be increased.

Note that the same effect is obtained when a film containing a material having a property of blocking ultraviolet rays is used for an after-mentioned insulating film 125f.

As each of the mask films 118Rf and 119Rf, a variety of inorganic insulating films that can be used as the protective layer 131 can be used. In particular, an oxide insulating film is preferable because its adhesion to the EL film 113Rf is higher than that of a nitride insulating film. For example, an inorganic insulating material such as aluminum oxide, hafnium oxide, or silicon oxide can be used for the mask films 118Rf and 119Rf. As the mask films 118Rf and 119Rf, aluminum oxide films can be formed by an ALD method, for example. The use of an ALD method is preferable, in which case damage to a base (in particular, the EL layer) can be reduced.

For example, an inorganic insulating film (e.g., an aluminum oxide film) formed by an ALD method can be used as the mask film 118Rf, and an inorganic film (e.g., an indium gallium zinc oxide film, an aluminum film, or a tungsten film) formed by a sputtering method can be used as the mask film 119Rf.

Note that the same inorganic insulating film can be used for both the mask film 118Rf and the insulating layer 125 that is to be formed later. For example, an aluminum oxide film formed by an ALD method can be used for both the mask film 118Rf and the insulating layer 125. For the mask film 118Rf and the insulating layer 125, the same deposition conditions may be used or different deposition conditions may be used. For example, when the mask film 118Rf is formed under conditions similar to those of the insulating layer 125, the mask film 118Rf can be an insulating layer having a high barrier property against at least one of water and oxygen. Meanwhile, since the mask film 118Rf is a layer almost or all of which is to be removed in a later step, it is preferable that the processing of the mask film 118Rf be easy. Therefore, the mask film 118Rf is preferably formed with a substrate temperature lower than that for formation of the insulating layer 125.

One or both of the mask films 118Rf and 119Rf may be formed using an organic material. For example, as the organic material, a material that can be dissolved in a solvent chemically stable with respect to at least the uppermost film of the EL film 113Rf may be used. Specifically, a material that will be dissolved in water or alcohol can be suitably used. In forming a film of such a material, it is preferable to apply the material dissolved in a solvent such as water or alcohol by a wet process and then perform heat treatment for evaporating the solvent. At this time, the heat treatment is preferably performed in a reduced-pressure atmosphere, in which case the solvent can be removed at a low temperature in a short time and thermal damage to the EL film 113Rf can be reduced accordingly.

The mask films 118Rf and 119Rf may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluorine resin like perfluoropolymer.

For example, an organic film (e.g., a PVA film) formed by an evaporation method or any of the above wet processes can be used as the mask film 118Rf, and an inorganic film (e.g., a silicon nitride film) formed by a sputtering method can be used as the mask film 119Rf.

Note that in the display device of one embodiment of the present invention, part of the mask film remains as the mask layer in some cases.

Subsequently, a resist mask 190R is formed over the mask film 119Rf as illustrated in FIG. 18A1. The resist mask 190R can be formed by application of a photosensitive material (photoresist), light exposure, and development.

The resist mask 190R may be formed using either a positive resist material or a negative resist material.

The resist mask 190R is provided at a position overlapping the conductive layer 112R. The resist mask 190R is preferably provided also at a position overlapping the conductive layer 112C. This can prevent the conductive layer 112C from being damaged during the process of manufacturing the display device. Note that the resist mask 190R is not necessarily provided over the conductive layer 112C. The resist mask 190R is preferably provided to cover the area from the end portion of the EL film 113Rf to the end portion of the conductive layer 112C (the end portion closer to the EL film 113Rf), as illustrated in the cross-sectional view along the line B1-B2 in FIG. 18A1.

Next, as illustrated in FIGS. 18A1 and 18B1, part of the mask film 119Rf is removed using the resist mask 190R, whereby the mask layer 119R is formed. The mask layer 119R remains over the conductive layers 112R and 112C. After that, the resist mask 190R is removed. Then, part of the mask film 118Rf is removed using the mask layer 119R as a mask (also referred to as a hard mask), whereby the mask layer 118R is formed.

Each of the mask films 118Rf and 119Rf can be processed by a wet etching method or a dry etching method. The mask films 118Rf and 119Rf are preferably processed by anisotropic etching.

The use of a wet etching method can reduce damage to the EL film 113Rf in processing of the mask films 118Rf and 119Rf, compared to the case of using a dry etching method. In the case of using a wet etching method, it is preferable to use a chemical solution of a developer, an aqueous solution of tetramethylammonium hydroxide (TMAH), dilute hydrofluoric acid, oxalic acid, phosphoric acid, nitric acid, acetic acid, or a mixed solution thereof, for example.

Since the EL film 113Rf is not exposed in the processing of the mask film 119Rf, the range of choice for a processing method for the mask film 119Rf is wider than that for the mask film 118Rf. Specifically, even in the case where a gas containing oxygen is used as the etching gas in the processing of the mask film 119Rf, deterioration of the EL film 113Rf can be suppressed as compared to the case where a gas containing oxygen is used as the etching gas in the processing of the mask film 118Rf.

In the case of using a dry etching method to process the mask film 118Rf, deterioration of the EL film 113Rf can be suppressed by not using a gas containing oxygen as the etching gas. In the case of using a dry etching method, it is preferable to use a gas containing CF₄, C₄F₈, SF₆, CHF₃, Cl₂, H₂O, BCl₃, or a Group 18 element, for example, as the etching gas. As the Group 18 element, He can be used, for example.

For example, in the case where an aluminum oxide film formed by an ALD method is used as the mask film 118Rf, part of the mask film 118Rf can be removed by a dry etching method using CHF₃ and He or a combination of CHF₃, He, and CH₄. In the case where an indium gallium zinc oxide film formed by a sputtering method is used as the mask film 119Rf, part of the mask film 119Rf can be removed by a wet etching method using diluted phosphoric acid. Alternatively, part of the mask film 119Rf may be removed by a dry etching method using CH₄ and Ar. Alternatively, part of the mask film 119Rf can be removed by a wet etching method using diluted phosphoric acid. In the case where a tungsten film formed by a sputtering method is used as the mask film 119Rf, part of the mask film 119Rf can be removed by a dry etching method using a combination of SF₆, CF₄, and O₂ or a combination of CF₄, Cl₂, and O₂.

The resist mask 190R can be removed by a method similar to that for the resist mask 191. For example, the resist mask 190R can be removed by ashing using oxygen plasma. Alternatively, an oxygen gas and any of CF₄, C₄F₈, SF₆, CHF₃, Cl₂, H₂O, BCl₃, and a Group 18 element may be used. As the Group 18 element, He can be used, for example. Alternatively, the resist mask 190R may be removed by wet etching. At this time, the mask film 118Rf is positioned on the outermost surface, and the EL film 113Rf is not exposed; thus, the EL film 113Rf can be prevented from being damaged in the step of removing the resist mask 190R. In addition, the range of choice of the method for removing the resist mask 190R can be widened.

Next, as illustrated in FIGS. 18A1 and 18B1, the EL film 113Rf is processed, so that the EL layer 113R is formed. For example, part of the EL film 113Rf is removed using the mask layers 119R and 118R as a hard mask, whereby the EL layer 113R is formed.

Accordingly, as illustrated in FIG. 18B1, the stacked-layer structure of the EL layer 113R, the mask layer 118R, and the mask layer 119R remains over the conductive layer 112R. The conductive layers 112G and 112B are exposed.

In the example illustrated in FIG. 18B1, the end portion of the EL layer 113R is positioned on the outer side of the end portion of the conductive layer 112R. Such a structure can increase the aperture ratio of the pixel. Although not illustrated in FIG. 18B1, by the above etching treatment, a depression portion may be formed in the insulating layer 105 in a region not overlapped by the EL layer 113R.

Since the EL layer 113R covers the conductive layer 112R, the subsequent steps can be performed without exposure of the conductive layer 112R. If the end portion of the conductive layer 112R is exposed, there is a possibility that corrosion is caused in an etching step, for example. A product generated by corrosion of the conductive layer 112R may be unstable, and for example, might be dissolved in a solution when wet etching is performed and might be scattered in an atmosphere when dry etching is performed. By dissolution of the product in a solution or scattering of the product in the atmosphere, the product might be attached to a surface to be processed and the side surface of the EL layer 113R, for example, which might adversely affect the characteristics of the light-emitting element or form a leak path between a plurality of light-emitting elements. In a region where the end portion of the conductive layer 112R is exposed, adhesion between layers in contact with each other might be lowered, which might be likely to cause peeling of the EL layer 113R or the conductive layer 112R.

Accordingly, the structure where the EL layer 113R covers the conductive layer 112R can improve the yield and characteristics of the light-emitting element, for example.

As described above, the resist mask 190R is preferably provided to cover the area from the end portion of the EL layer 113R to the end portion of the conductive layer 112C (the end portion closer to the EL layer 113R) in the cross section B1-B2. Thus, as illustrated in FIG. 18B1, the mask layers 118R and 119R are provided to cover the area from the end portion of the EL layer 113R to the end portion of the conductive layer 112C (the end portion closer to the EL layer 113R) in the cross section B1-B2. Hence, the insulating layer 105 is not exposed in the cross section B1-B2, for example. This can prevent the insulating layers 105, 104, and 103 from being partly removed by etching, for example, and thus prevent the conductive layer 109 from being exposed. Accordingly, the conductive layer 109 can be prevented from being unintentionally electrically connected to another conductive layer. For example, a short circuit between the conductive layer 109 and the common electrode 115 formed in a later step can be suppressed.

The EL film 113Rf is preferably processed by anisotropic etching. Anisotropic dry etching is particularly preferable. Alternatively, wet etching may be used.

In the case of using a dry etching method, deterioration of the EL film 113Rf can be suppressed by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. When the etching can performed under a low-power condition while an adequately high etching rate is maintained, damage to the EL film 113Rf can be reduced even with the use of a gas containing oxygen as the etching gas. Furthermore, a defect such as attachment of a reaction product generated at the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He and Ar as the etching gas, for example. Alternatively, a gas containing oxygen and at least one of the above is preferably used as the etching gas. Alternatively, an oxygen gas may be used as the etching gas. Specifically, for example, a gas containing H₂ and Ar or a gas containing CF₄ and He can be used as the etching gas. As another example, a gas containing CF₄, He, and oxygen can be used as the etching gas. As another example, a gas containing H₂ and Ar and a gas containing oxygen can be used as the etching gas.

As described above, in one embodiment of the present invention, the mask layer 119R is formed in the following manner: the resist mask 190R is formed over the mask film 119Rf and part of the mask film 119Rf is removed using the resist mask 190R. After that, part of the EL film 113Rf is removed using the mask layer 119R as a hard mask, so that the EL layer 113R is formed. In other words, the EL layer 113R can be formed by processing the EL film 113Rf by a photolithography method. Note that part of the EL film 113Rf may be removed using the resist mask 190R, and then the resist mask 190R may be removed.

FIG. 18B2 is a cross-sectional view illustrating a structure example of the EL layer 113R in FIG. 18B1 and its periphery. As illustrated in FIG. 18B2, the EL layer 113R includes the functional layer 181R, the light-emitting layer 182R over the functional layer 181R, and the functional layer 183R over the light-emitting layer 182R. The functional layer 181R includes a region in contact with the conductive layer 112Rc.

In the case where the conductive layers 111R and 112R function as the anode, the functional layer 181R includes one or both of a hole-injection layer and a hole-transport layer. For example, the functional layer 181R includes a hole-injection layer and a hole-transport layer over the hole-injection layer. The functional layer 183R includes, for example, an electron-transport layer.

In the case where the conductive layers 111R and 112R function as the cathode, the functional layer 181R includes one or both of an electron-injection layer and an electron-transport layer. For example, the functional layer 181R includes an electron-injection layer and an electron-transport layer over the electron-injection layer. The functional layer 183R includes, for example, a hole-transport layer.

The conductive layer 112R includes a region in contact with the undermost layer, for example, among the layers provided in the functional layer 181R. For example, in the case where the functional layer 181R has a stacked-layer structure of a hole-injection layer and a hole-transport layer over the hole-injection layer, the conductive layer 112R includes a region in contact with the hole-injection layer. As another example, in the case where the functional layer 181R has a stacked-layer structure of an electron-injection layer and an electron-transport layer over the electron-injection layer, the conductive layer 112R includes a region in contact with the electron-injection layer.

Here, in the case where the functional layer 181 includes one or both of the hole-injection layer and the hole-transport layer, the work function of the conductive film 112cf is made higher than that of the conductive film 112bf, for example. In the case where the functional layer 181 includes one or both of the electron-injection layer and the electron-transport layer, the work function of the conductive film 112cf is made lower than that of the conductive film 112bf, for example. Thus, the driving voltage of the EL layer 113R can be lowered. The driving voltage of the EL layers 113G and 113B that are formed in later steps can also be lowered.

Next, hydrophobic treatment for the conductive layer 112G, for example, is preferably performed. At the time of processing the EL film 113Rf, the surface of the conductive layer 112G changes to have hydrophilic properties in some cases, for example. The hydrophobic treatment for the conductive layer 112G, for example, can increase the adhesion between the conductive layer 112G and the EL layer 113G formed in a later step and suppress film peeling. Note that the hydrophobic treatment is not necessarily performed.

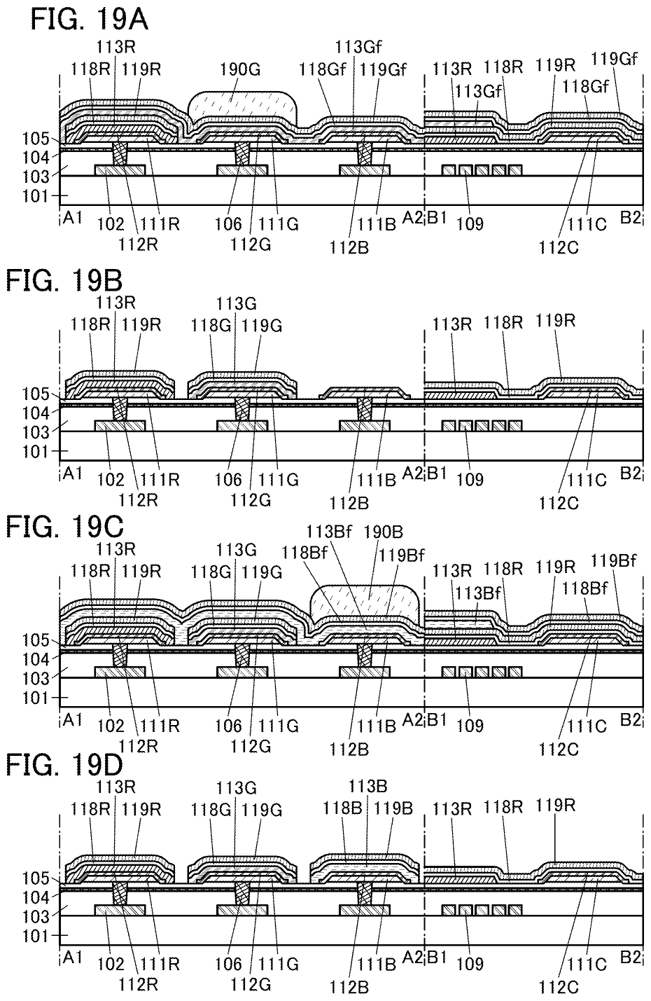

Next, as illustrated in FIG. 19A, an EL film 113Gf to be the EL layer 113G is formed over the conductive layer 112G, the conductive layer 112B, the mask layer 119R, and the insulating layer 105.

The EL film 113Gf can be formed by a method similar to that for forming the EL film 113Rf. The EL film 113Gf can have a structure similar to that of the EL film 113Rf.

Then, as illustrated in FIG. 19A, a mask film 118Gf to be the mask layer 118G and a mask film 119Gf to be a mask layer 119G are sequentially formed over the EL film 113Gf and the mask layer 119R. After that, a resist mask 190G is formed. The materials and the formation methods of the mask film 118Gf and the mask film 119Gf can be similar to those of the mask film 118Rf and the mask film 119Rf. The material and the formation method of the resist mask 190G can be similar to those of the resist mask 190R.

The resist mask 190G is provided at a position overlapping the conductive layer 112G.

Subsequently, as illustrated in FIGS. 19A and 19B, part of the mask film 119Gf is removed using the resist mask 190G, whereby the mask layer 119G is formed. The mask layer 119G remains over the conductive layer 112G. After that, the resist mask 190G is removed. Then, part of the mask film 118Gf is removed using the mask layer 119G as a mask, whereby the mask layer 118G is formed. Next, the EL film 113Gf is processed to form the EL layer 113G. For example, part of the EL film 113Gf is removed using the mask layer 119G and the mask layer 118G as a hard mask to form the EL layer 113G.

Accordingly, as illustrated in FIG. 19B, the stacked-layer structure of the EL layer 113G, the mask layer 118G, and the mask layer 119G remains over the conductive layer 112G. The mask layer 119R and the conductive layer 112B are exposed.

Next, hydrophobic treatment for the conductive layer 112B, for example, is preferably performed. At the time of processing the EL film 113Gf, the surface of the conductive layer 112B changes to have hydrophilic properties in some cases, for example. The hydrophobic treatment for the conductive layer 112B, for example, can increase the adhesion between the conductive layer 112B and the EL layer 113B formed in a later step and suppress film peeling. Note that the hydrophobic treatment is not necessarily performed.

Next, as illustrated in FIG. 19C, an EL film 113Bf to be the EL layer 113B is formed over the conductive layer 112B, the mask layer 119R, the mask layer 119G, and the insulating layer 105.

The EL film 113Bf can be formed by a method similar to that for forming the EL film 113Rf. The EL film 113Bf can have a structure similar to that of the EL film 113Rf.

Then, as illustrated in FIG. 19C, a mask film 118Bf to be the mask layer 118B and a mask film 119Bf to be a mask layer 119B are sequentially formed over the EL film 113Bf and the mask layer 119R. After that, a resist mask 190B is formed. The materials and the formation methods of the mask film 118Bf and the mask film 119Bf can be similar to those of the mask film 118Rf and the mask film 119Rf. The material and the formation method of the resist mask 190B can be similar to those of the resist mask 190R.

The resist mask 190B is provided at a position overlapping the conductive layer 112B.

Subsequently, as illustrated in FIGS. 19C and 19D, part of the mask film 119Bf is removed using the resist mask 190B, whereby the mask layer 119B is formed. The mask layer 119B remains over the conductive layer 112B. After that, the resist mask 190B is removed. Then, part of the mask film 118Bf is removed using the mask layer 119B as a mask, whereby the mask layer 118B is formed. Next, the EL film 113Bf is processed to form the EL layer 113B. For example, part of the EL film 113Bf is removed using the mask layers 119B and 118B as a hard mask to form the EL layer 113B.

Accordingly, as illustrated in FIG. 19D, the stacked-layer structure of the EL layer 113B, the mask layer 118B, and the mask layer 119B remains over the conductive layer 112B. The mask layers 119R and 119G are exposed.

Note that side surfaces of the EL layers 113R, 113G, and 113B are preferably perpendicular or substantially perpendicular to their formation surfaces. For example, the angle between the formation surfaces and these side surfaces is preferably greater than or equal to 60° and less than or equal to 90°.

The distance between two adjacent layers among the EL layers 113R, 113G, and 113B, which are formed by a photolithography method as described above, can be reduced to 8 μm or less, 5 μm or less, 3 μm or less, 2 μm or less, or 1 μm or less. Here, the distance can be specified, for example, by a distance between opposite end portions of two adjacent layers among the EL layers 113R, 113G, and 113B. Reducing the distance between the island-shaped EL layers 113 can provide a display device having high resolution and a high aperture ratio.

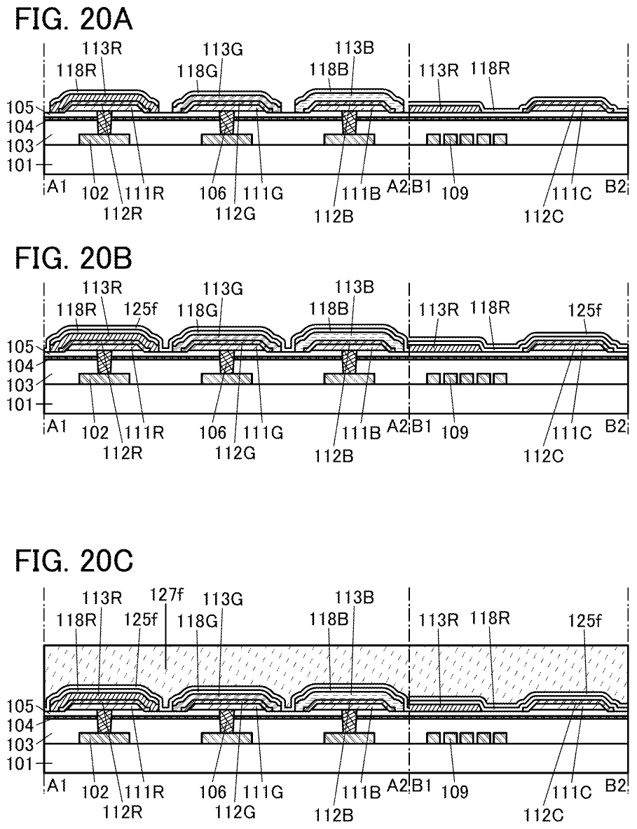

Next, as illustrated in FIGS. 19D and 20A, the mask layers 119R, 119G, and 119B are preferably removed. The mask layers 118R, 118G, 118B, 119R, 119G, and 119B remain in the display device in some cases depending on the subsequent steps. Removing the mask layers 119R, 119G, and 119B at this stage can prevent the mask layers 119R, 119G, and 119B from being left in the display device. For example, in the case where a conductive material is used for the mask layers 119R, 119G, and 119B, removing the mask layers 119R, 119G, and 119B in advance can suppress generation of leakage current, formation of a capacitor, and the like due to the remaining mask layers 119R, 119G, and 119B.

This embodiment shows an example where the mask layers 119R, 119G, and 119B are removed; however, it is possible that the mask layers 119R, 119G, and 119B are not removed. For example, in the case where the mask layers 119R, 119G, and 119B contain the material having a property of blocking ultraviolet rays, the procedure preferably proceeds to the next step without removing the mask layers 119R, 119G, and 119B, in which case the EL layer 113 can be protected from ultraviolet rays.

The step of removing the mask layers can be performed by a method similar to that for the step of processing the mask layers. Specifically, by using a wet etching method, damage applied to the EL layers 113R, 113G, and 113B at the time of removing the mask layers can be reduced as compared to the case of using a dry etching method.

The mask layers may be removed by being dissolved in a solvent such as water or alcohol. Examples of alcohol include ethyl alcohol, methyl alcohol, isopropyl alcohol (IPA), and glycerin.

After the mask layers are removed, drying treatment may be performed in order to remove water included in the EL layers 113R, 113G, and 113B and water adsorbed on the surfaces of the EL layers 113R, 113G, and 113B. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, as illustrated in FIG. 20B, the insulating film 125f to be the insulating layer 125 is formed to cover the EL layers 113R, 113G, and 113B and the mask layers 118R, 118G, and 118B.

As described later, an insulating film to be the insulating layer 127 is formed in contact with the top surface of the insulating film 125f. Therefore, the top surface of the insulating film 125f preferably has a high affinity for the material used for the insulating film (e.g., a photosensitive resin composition containing an acrylic resin). To improve the affinity, surface treatment is preferably performed so that the top surface of the insulating film 125f is made hydrophobic or its hydrophobic properties are improved. For example, it is preferable to perform the treatment using a silylation agent such as hexamethyldisilazane (HMDS). By making the top surface of the insulating film 125f hydrophobic in such a manner, the insulating film can be formed with favorable adhesion to the insulating film 125f. Note that the above-described hydrophobic treatment may be performed as the surface treatment.

Then, as illustrated in FIG. 20C, an insulating film 127f to be the insulating layer 127 is formed over the insulating film 125f.

The insulating films 125f and 127f are preferably formed by a method by which damage to the EL layers 113R, 113G, and 113B is small. The insulating film 125f, which is formed in contact with the side surfaces of the EL layers 113R, 113G, and 113B, is particularly preferably formed by a method that is less likely to damage the EL layers 113R, 113G, and 113B than the method of forming the insulating film 127f.

Each of the insulating films 125f and 127f is formed at a temperature lower than the upper temperature limit of the EL layers 113R, 113G, and 113B. When the substrate temperature at the time of forming the insulating film 125f is high, the insulating film 125f can have a low impurity concentration and have a high barrier property against at least one of water and oxygen even with a small thickness.

The substrate temperature at the time of forming the insulating films 125f and 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the insulating film 125f, it is preferable to form an insulating film having a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm in the above-described range of the substrate temperature.

The insulating film 125f is preferably formed by an ALD method, for example. With the use of an ALD method, damage by the deposition can be reduced and a film with good coverage can be formed. As the insulating film 125f, an aluminum oxide film can be formed by an ALD method, for example.

Alternatively, the insulating film 125f may be formed by a sputtering method, a CVD method, or a PECVD method, each of which has a higher deposition rate than an ALD method. In that case, a highly reliable display device can be manufactured with high productivity.

The insulating film 127f is preferably formed by the aforementioned wet process. The insulating film 127f is preferably formed by spin coating using a photosensitive material, for example, and specifically preferably formed using a photosensitive resin composition containing an acrylic resin.

The insulating film 127f is preferably formed using a resin composition containing a polymer, an acid-generating agent, and a solvent, for example. The polymer is formed using one or more kinds of monomers and has a structure where one or more kinds of structural units (also referred to as building blocks) are repeated regularly or irregularly. As the acid-generating agent, one or both of a compound that generates an acid by light irradiation and a compound that generates an acid by heating can be used. The resin composition may also include one or more of a photosensitizing agent, a sensitizer, a catalyst, an adhesive aid, a surface-active agent, and an antioxidant.

Heat treatment (also referred to as prebaking) is preferably performed after the insulating film 127f is formed. The heat treatment is performed at a temperature lower than the upper temperature limit of the EL layers 113R, 113G, and 113B. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, the solvent contained in the insulating film 127f can be removed.

Then, part of the insulating film 127f is exposed to visible light or ultraviolet rays. Here, when a positive photosensitive resin composition containing an acrylic resin is used for the insulating film 127f, a region where the insulating layer 127 is not formed in a later step is irradiated with visible light or ultraviolet rays. The insulating layer 127 is formed in regions that are sandwiched between any two of the conductive layers 112R, 112G, and 112B and around the conductive layer 112C. Accordingly, the top surfaces of the conductive layers 112R, 112G, 112B, and 112C are irradiated with visible light or ultraviolet rays. Note that when a negative photosensitive material is used for the insulating film 127f, the region where the insulating layer 127 is to be formed is irradiated with visible light or ultraviolet rays.

The width of the insulating layer 127 formed later can be controlled in accordance with the exposed region of the insulating film 127f In this embodiment, the insulating layer 127 is processed to include a region overlapping the top surface of the conductive layer 111.

Light used for exposure preferably includes the i-line (wavelength: 365 nm). Furthermore, light used for exposure may include at least one of the g-line (wavelength: 436 nm) and the h-line (wavelength: 405 nm).

Here, when a material having a high barrier property against oxygen, for example, aluminum oxide is used for one or both of the mask layer 118 (the mask layers 118R, 118G, and 118B) and the insulating film 125f, diffusion of oxygen into the EL layers 113R, 113G, and 113B can be suppressed. When an EL layer is irradiated with light (visible light or ultraviolet rays), the organic compound contained in the EL layer is brought into an excited state and a reaction between the organic compound and oxygen in the atmosphere is promoted in some cases. Specifically, when an EL layer is irradiated with light (visible light or ultraviolet rays) in an atmosphere including oxygen, oxygen might be bonded to the organic compound contained in the EL layer. By providing the mask layer 118 and the insulating film 125f over the island-shaped EL layer 113, bonding of oxygen in the atmosphere to the organic compound contained in the EL layer 113 can be suppressed.

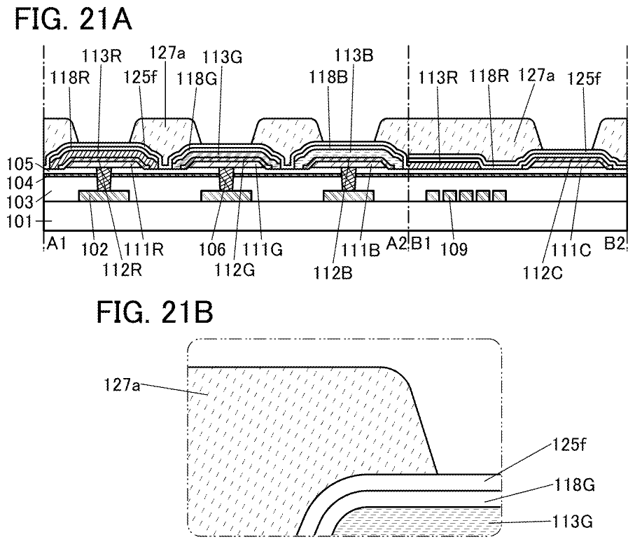

Next, as illustrated in FIGS. 20C and 21A, development is performed to remove the exposed region of the insulating film 127f, whereby an insulating layer 127a is formed. FIG. 21B is an enlarged view of the end portions of the EL layer 113G and the insulating layer 127a illustrated in FIG. 21A and their vicinity. The insulating layer 127a is formed in regions that are sandwiched between any two of the conductive layers 112R, 112G, and 112B and a region surrounding the conductive layer 112C. Here, when an acrylic resin is used for the insulating film 127f, a developer is preferably an alkaline solution and can be TMAH, for example.

Then, a residue (scum) due to the development may be removed. For example, the residue can be removed by ashing using oxygen plasma.

Etching may be performed so that the surface level of the insulating layer 127a is adjusted. The insulating layer 127a may be processed by ashing using oxygen plasma, for example. In the case where a non-photosensitive material is used for the insulating film 127f, the surface level of the insulating film 127f can be adjusted by the ashing, for example.

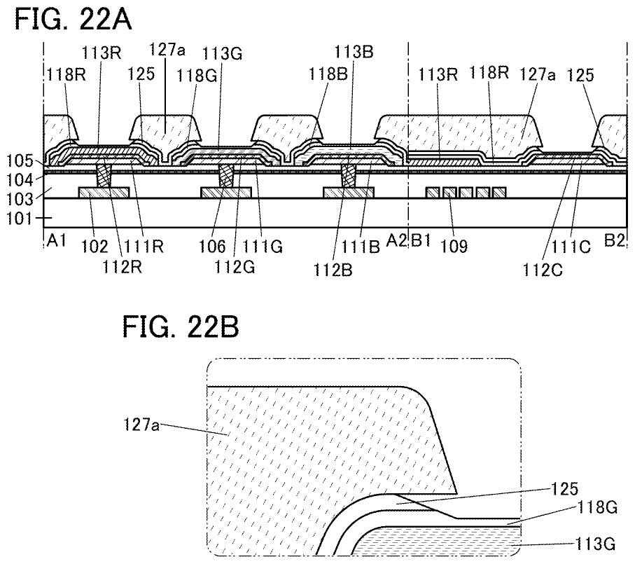

Next, as illustrated in FIGS. 21A and 22A, etching treatment is performed with the insulating layer 127a as a mask to remove part of the insulating film 125f and reduce the thickness of part of the mask layers 118R, 118G, and 118B. Thus, the insulating layer 125 is formed under the insulating layer 127a. Moreover, the surfaces of the thin regions in the mask layers 118R, 118G, and 118B are exposed. FIG. 22B is an enlarged view of the end portions of the EL layer 113G and the insulating layer 127a illustrated in FIG. 22A and their vicinity. Note that the etching treatment using the insulating layer 127a as a mask may be hereinafter referred to as first etching treatment.

The first etching treatment can be performed by dry etching or wet etching. Note that the insulating film 125f is preferably formed using a material similar to that of the mask layers 118R, 118G, and 118B, in which case the first etching treatment can be performed concurrently.

By etching using the insulating layer 127a with a tapered side surface as a mask as illustrated in FIG. 22B, the side surface of the insulating layer 125 and upper end portions of the side surfaces of the mask layers 118R, 118G, and 118B can be made to have a tapered shape relatively easily.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the mask layers 118R, 118G, and 118B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, the capacitively coupled plasma etching apparatus may have a structure in which different high-frequency voltages are applied to one of the parallel-plate electrodes. Alternatively, the capacitively coupled plasma etching apparatus may have a structure in which high-frequency voltages with the same frequency are applied to the parallel-plate electrodes. Alternatively, the capacitively coupled plasma etching apparatus may have a structure in which high-frequency voltages with different frequencies are applied to the parallel-plate electrodes.

In the case of performing dry etching, a by-product or the like generated by the dry etching might be deposited on the top surface and the side surface of the insulating layer 127a, for example. Accordingly, a constituent of the etching gas, a constituent of the insulating film 125f, a constituent of the mask layers 118R, 118G, and 118B, and the like might be included in the insulating layer 127 in the completed display device.

The first etching treatment is preferably performed by wet etching. The use of a wet etching method can reduce damage to the EL layers 113R, 113G, and 113B, as compared to the case of using a dry etching method. The wet etching can be performed using an alkaline solution, for example. For instance, TMAH, which is an alkaline solution, is preferably used for wet etching of an aluminum oxide film. In this case, puddle wet etching can be performed. Note that the insulating film 125f is preferably formed using a material similar to that of the mask layers 118R, 118G, and 118B, in which case the etching treatment can be performed concurrently.

As illustrated in FIGS. 22A and 22B, the mask layers 118R, 118G, and 118B are not removed completely by the first etching treatment, and the etching treatment is stopped when the thickness of the mask layers 118R, 118G, and 118B is reduced. The corresponding mask layers 118R, 118G, and 118B are left over the EL layers 113R, 113G, and 113B in this manner, whereby the EL layers 113R, 113G, and 113B can be prevented from being damaged by processing in a later step.

Although the thickness of the mask layers 118R, 118G, and 118B is reduced in FIGS. 22A and 22B, the present invention is not limited thereto. For example, depending on the thickness of the insulating film 125f and the thickness of the mask layers 118R, 118G, and 118B, the first etching treatment may be stopped before the insulating film 125f is processed into the insulating layer 125. Specifically, the first etching treatment may be stopped only after reducing the thickness of part of the insulating film 125f. In the case where the insulating film 125f is formed using a material similar to that of the mask layers 118R, 118G, and 118B, the boundary between the insulating film 125f and the mask layers 118R, 118G, and 118B may be unclear; hence, whether the insulating layer 125 is formed and whether the thickness of the mask layers 118R, 118G, and 118B is reduced cannot be determined in some cases.

Although FIGS. 22A and 22B show an example in which the shape of the insulating layer 127a is not changed from that in FIGS. 21A and 21B, the present invention is not limited thereto. For example, the end portion of the insulating layer 127a may droop to cover the end portion of the insulating layer 125. As another example, the end portion of the insulating layer 127a may be in contact with the top surfaces of the mask layers 118R, 118G, and 118B.

Next, light exposure is preferably performed on the entire substrate so that the insulating layer 127a is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a to a tapered shape.

Meanwhile, as described later, when light exposure is not performed on the insulating layer 127a, it sometimes becomes easy to change the shape of the insulating layer 127a or change the shape of the insulating layer 127 to a tapered shape in a later step. Therefore, in some cases, it is preferable not to perform light exposure on the insulating layer 127a after the development.

For example, in the case where a light curable resin is used for the insulating layer 127a, light exposure on the insulating layer 127a can start polymerization and cure the insulating layer 127a. Note that without performing light exposure on the insulating layer 127a at this stage, at least one of after-mentioned post-baking and second etching treatment may be performed while the insulating layer 127a remains in a state where its shape is relatively easily changed. Thus, unevenness can be inhibited from being formed on the formation surface of the common layer 114 and the common electrode 115, and occurrence of disconnection and local thinning in the common layer 114 and the common electrode 115 can be suppressed. Note that light exposure may be performed after the development and before the first etching treatment. On the other hand, depending on the material (e.g., a positive-type material) of the insulating layer 127a and the first etching treatment conditions, the insulating layer 127a that has been subjected to light exposure might be dissolved in a chemical solution during the first etching treatment. For this reason, light exposure is preferably performed after the first etching treatment and before post-baking. Hence, the insulating layer 127 having an intended shape can be stably formed with high reproducibility.

Here, irradiation with visible light or ultraviolet rays is preferably performed in an atmosphere containing no oxygen or an atmosphere containing a small amount of oxygen. For example, the irradiation with visible light or ultraviolet rays is preferably performed in an inert gas atmosphere such as a nitrogen atmosphere or a reduced-pressure atmosphere. If the irradiation with visible light or ultraviolet rays is performed in an atmosphere containing a large amount of oxygen, the compound contained in the EL layer might be oxidized and the properties of the EL layer might be changed. In contrast, by performing the irradiation with visible light or ultraviolet rays in an atmosphere containing no oxygen or an atmosphere containing a small amount of oxygen, a change of the properties of the EL layer can be prevented; hence, a more highly reliable display device can be provided.

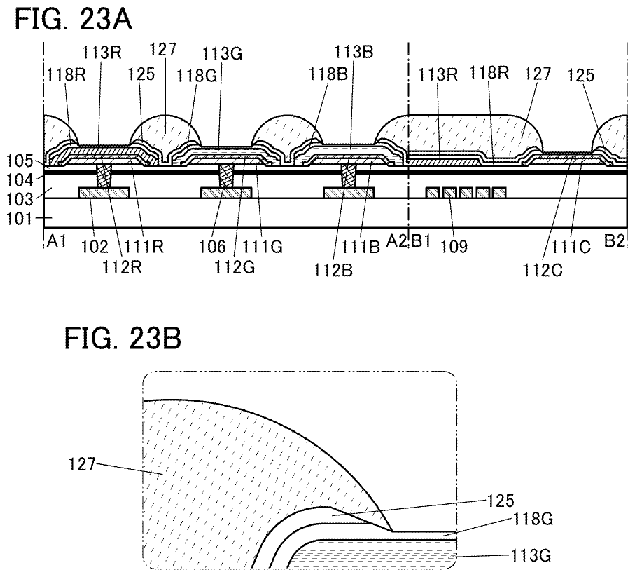

Then, heat treatment (also referred to as post-baking) is performed. Thus, as illustrated in FIGS. 22A and 23A, the heat treatment can change the insulating layer 127a into the insulating layer 127 having a tapered side surface. Note that as described above, in some cases, the insulating layer 127a is already changed in shape and has a tapered side surface at the moment when the first etching treatment ends. The heat treatment is conducted at a temperature lower than the upper temperature limit of the EL layer 113. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. The heating atmosphere is preferably a reduced-pressure atmosphere, in which case drying at a lower temperature is possible. The substrate temperature in the heat treatment of this step is preferably higher than that in the heat treatment (prebaking) after the formation of the insulating film 127f Accordingly, adhesion between the insulating layer 127 and the insulating layer 125 can be improved, and corrosion resistance of the insulating layer 127 can be increased. FIG. 23B is an enlarged view of the end portions of the EL layer 113G and the insulating layer 127 illustrated in FIG. 23A and their vicinity.

As described above, in the display device of one embodiment of the present invention, a material having high heat resistance is used for the EL layer 113. Therefore, the temperature of the prebaking and the temperature of the post-baking can each be higher than or equal to 100° C., higher than or equal to 120° C., or higher than or equal to 140° C. Thus, adhesion between the insulating layer 127 and the insulating layer 125 can be further improved, and the corrosion resistance of the insulating layer 127 can be further increased. Moreover, the range of choice for materials that can be used for the insulating layer 127 can be widened. By adequately removing the solvent and the like included in the insulating layer 127, entry of impurities such as water and oxygen into the EL layer 113 can be suppressed.

When the mask layers 118R, 118G, and 118B are not completely removed by the first etching treatment and the thinned mask layers 118R, 118G, and 118B are left, the EL layers 113R, 113G, and 113B can be prevented from being damaged and deteriorating in the post-baking. This increases the reliability of the light-emitting element.

Note that the side surface of the insulating layer 127 may have a concave shape as illustrated in FIGS. 6A and 6B, for example, depending on the material of the insulating layer 127 and the temperature, time, and atmosphere of the post-baking. For example, the shape of the insulating layer 127 is more likely to change and thus a concave shape may be more likely to be formed as the temperature of the post-baking is higher or the time for the post-baking is longer. When light exposure is not performed on the insulating layer 127a after the development, the shape of the insulating layer 127 may be likely to change in the post-baking.

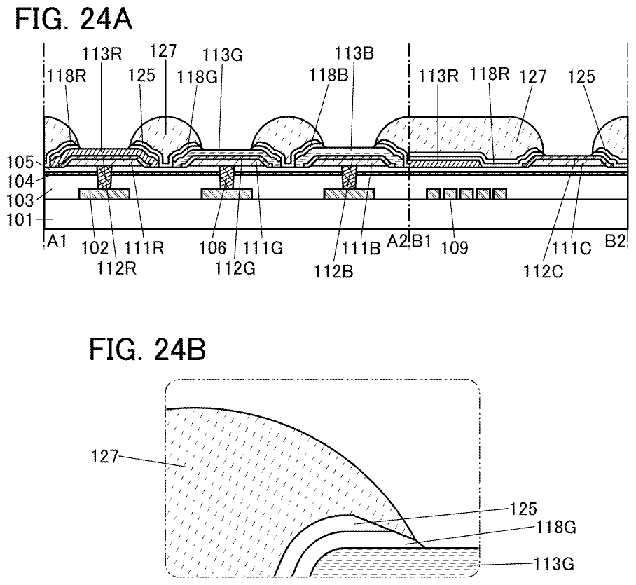

Next, as illustrated in FIGS. 23A and 24A, etching treatment is performed with the insulating layer 127 as a mask to remove part of the mask layers 118R, 118G, and 118B. Note that part of the insulating layer 125 is also removed in some cases. Thus, openings are formed in the mask layers 118R, 118G, and 118B, and the top surfaces of the EL layers 113R, 113G, and 113B and the conductive layer 112C are exposed. FIG. 24B is an enlarged view of the end portions of the EL layer 113G and the insulating layer 127 illustrated in FIG. 24A and their vicinity. Note that the etching treatment using the insulating layer 127 as a mask may be hereinafter referred to as second etching treatment.

The end portion of the insulating layer 125 is covered with the insulating layer 127. FIGS. 24A and 24B illustrate an example in which part of the end portion of the mask layer 118G (specifically a tapered region formed by the first etching treatment) is covered with the insulating layer 127 and a tapered region formed by the second etching treatment is exposed. That is, the structure in FIGS. 24A and 24B corresponds to the structure in FIGS. 4A and 4B.

If the first etching treatment is not performed and the insulating layer 125 and the mask layer 118 are collectively etched after the post-baking, the insulating layer 125 and the mask layer 118 under the end portion of the insulating layer 127 may disappear because of side-etching and a void may be formed. The void causes unevenness on the formation surface of the common layer 114 and the common electrode 115; hence, disconnection or local thinning is more likely to be caused in the common layer 114 and the common electrode 115. On the other hand, in the case where the first etching treatment is performed, even when a void is formed owing to side-etching of the insulating layer 125 and the mask layer 118 by the first etching treatment, the post-baking performed subsequently allows the insulating layer 127 to fill the void. After that, the thinned mask layer 118 is etched by the second etching treatment; thus, the amount of side-etching decreases, a void is less likely to be formed, and even if a void is formed, it can be extremely small. Consequently, the formation surface of the common layer 114 and the common electrode 115 can be made flatter.

Note that for example, the insulating layer 127 may cover the entire end portion of the mask layer 118 as illustrated in FIGS. 5A and 5B. For example, the end portion of the insulating layer 127 may droop to cover the end portion of the mask layer 118. As another example, the end portion of the insulating layer 127 may be in contact with the top surface of at least one of the EL layers 113R, 113G, and 113B. As described above, when light exposure is not performed on the insulating layer 127a after the development, the shape of the insulating layer 127 may be likely to change.

The second etching treatment is performed by wet etching. The use of a wet etching method can reduce damage to the EL layers 113R, 113G, and 113B, as compared to the case of using a dry etching method. The wet etching can be performed using an alkaline solution such as TMAH, for example.

As described above, by providing the insulating layers 127 and 125 and the mask layers 118R, 118G, and 118B, disconnection due to divided portions and an increase in electric resistance due to a local thinning portion can be prevented from occurring in the common layer 114 and the common electrode 115 between the light-emitting elements. Thus, the display device of one embodiment of the present invention can have high display quality.

Heat treatment may be performed after part of the EL layers 113R, 113G, and 113B is exposed. By the heat treatment, water included in the EL layer 113 and water adsorbed on the surface of the EL layer 113, for example, can be removed. The shape of the insulating layer 127 may be changed by the heat treatment. Specifically, the insulating layer 127 may be widened to cover at least one of the end portion of the insulating layer 125, the end portions of the mask layers 118R, 118G, and 118B, and the top surfaces of the EL layers 113R, 113G, and 113B. For example, the insulating layer 127 may have the shape illustrated in FIGS. 5A and 5B. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case dehydration at a lower temperature is possible. Note that the temperature range of the heat treatment is preferably set as appropriate also in consideration of the upper temperature limit of the EL layer 113. In consideration of the upper temperature limit of the EL layer 113, a temperature higher than or equal to 70° C. and lower than or equal to 120° C. is particularly preferable in the above temperature ranges.

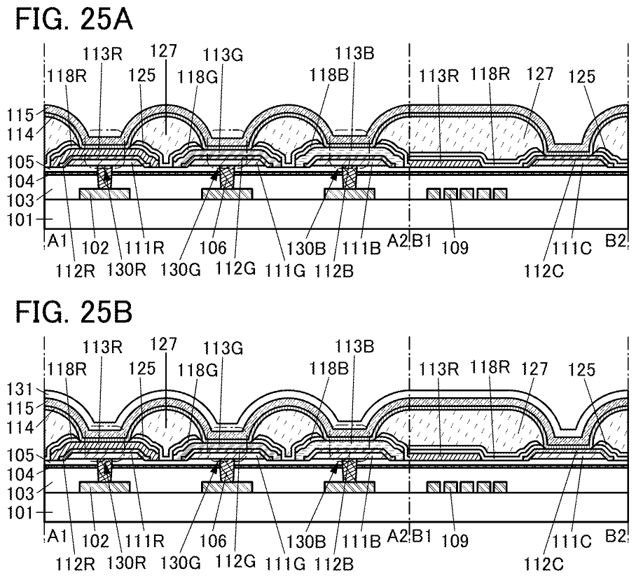

Then, as illustrated in FIG. 25A, the common layer 114 is formed over the EL layers 113R, 113G, and 113B, the conductive layer 112C, and the insulating layer 127. The common layer 114 can be formed by an evaporation method (including a vacuum evaporation method), a transfer method, a printing method, an inkjet method, a coating method, or the like.

Next, as illustrated in FIG. 25A, the common electrode 115 is formed over the common layer 114. The common electrode 115 can be formed by a sputtering method, a vacuum evaporation method, or the like. Alternatively, the common electrode 115 may be formed by stacking a film formed by an evaporation method and a film formed by a sputtering method.

The common electrode 115 can be formed continuously after the formation of the common layer 114, without a step such as etching intervening therebetween. For example, after the common layer 114 is formed in a vacuum, the common electrode 115 can be formed in a vacuum without exposing the substrate to the air. In other words, the common layer 114 and the common electrode 115 can be successively formed in a vacuum. Accordingly, the bottom surface of the common electrode 115 can be a clean surface, as compared to the case where the common layer 114 is not provided in the display device 100. Thus, the light-emitting element 130 can have high reliability and favorable characteristics.

Next, as illustrated in FIG. 25B, the protective layer 131 is formed over the common electrode 115. The protective layer 131 can be formed by a vacuum evaporation method, a sputtering method, a CVD method, an ALD method, or the like.

Then, the substrate 120 is attached to the protective layer 131 using the resin layer 122, whereby the display device having the structures illustrated in FIG. 1B, FIG. 2A, FIG. 4A, and FIG. 12A can be manufactured.

Here, after the insulating layer 127 is formed by the post-baking illustrated in FIGS. 22A and 23A, the insulating layer 127 may be exposed to light. For example, the insulating layer 127 may be exposed to light when the aforementioned light exposure is not performed on the insulating layer 127a. For example, the insulating layer 127 may be exposed to light after the second etching treatment illustrated in FIGS. 23A and 24A and before the formation of the common layer 114 illustrated in FIG. 25A. Alternatively, the insulating layer 127 may be exposed to light after the formation of the common electrode 115 illustrated in FIG. 25A and before the formation of the protective layer 131 illustrated in FIG. 25B. Alternatively, the insulating layer 127 may be exposed to light after the formation of the protective layer 131 illustrated in FIG. 25B. Here, for example, the conditions similar to those for the aforementioned light exposure on the insulating layer 127a can be used as the conditions for light exposure on the insulating layer 127. Note that the total number of light exposure on the insulating layer 127a and light exposure on the insulating layer 127 may be 0, 1, 2, or more.

For example, in the case where a light curable resin is used for the insulating layer 127, light exposure on the insulating layer 127 can cure the insulating layer 127. Consequently, deformation of the insulating layer 127 can be suppressed. Thus, peeling of the layer over the insulating layer 127 can be inhibited, for example. Accordingly, the display device of one embodiment of the present invention can be a highly reliable display device.

As described above, in the method for manufacturing the display device of one embodiment of the present invention, the island-shaped EL layers 113R, 113G, and 113B are formed not by using a fine metal mask but by processing a film formed on the entire surface; thus, the island-shaped EL layers 113 can be formed to have a uniform thickness. Consequently, a high-resolution display device or a display device with a high aperture ratio can be obtained. Furthermore, even when the resolution or the aperture ratio is high and the distance between the subpixels 110 is extremely short, the EL layers 113R, 113G, and 113B can be prevented from being in contact with each other in the adjacent subpixels 110. As a result, generation of leakage current between the subpixels 110 can be inhibited. This can prevent crosstalk due to unintended light emission, so that a display device with extremely high contrast can be obtained.

In addition, the insulating layer 127 having a tapered end portion is provided between the adjacent island-shaped EL layers 113, whereby occurrence of disconnection can be inhibited at the time of forming the common electrode 115, and a local thinning portion can be prevented from being formed in the common electrode 115. Thus, a connection defect due to a disconnection portion and an increase in electrical resistance due to a local thinning portion can be inhibited from occurring in the common layer 114 and the common electrode 115. Hence, the display device of one embodiment of the present invention achieves both high resolution and high display quality.

### [Manufacturing Method Example 2]

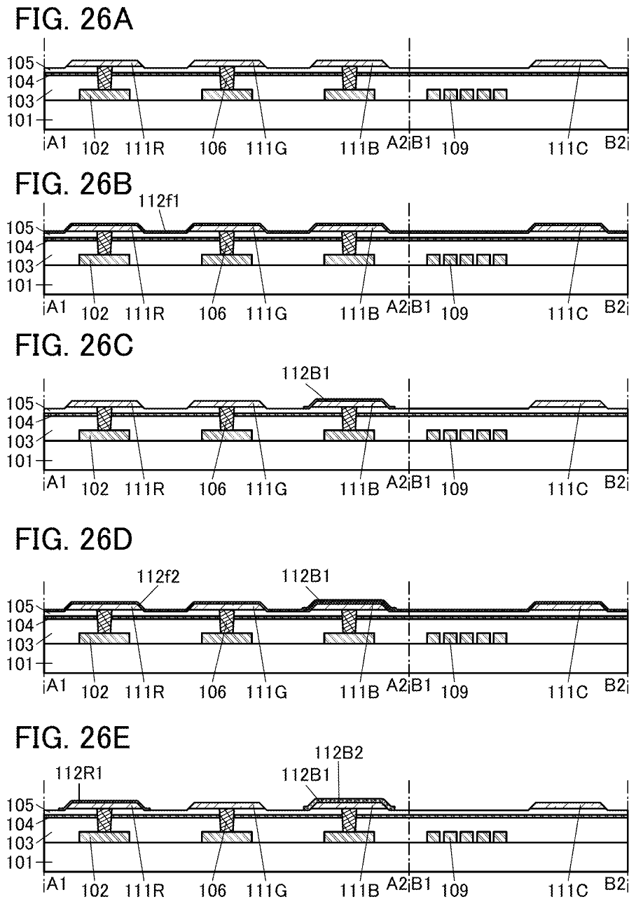

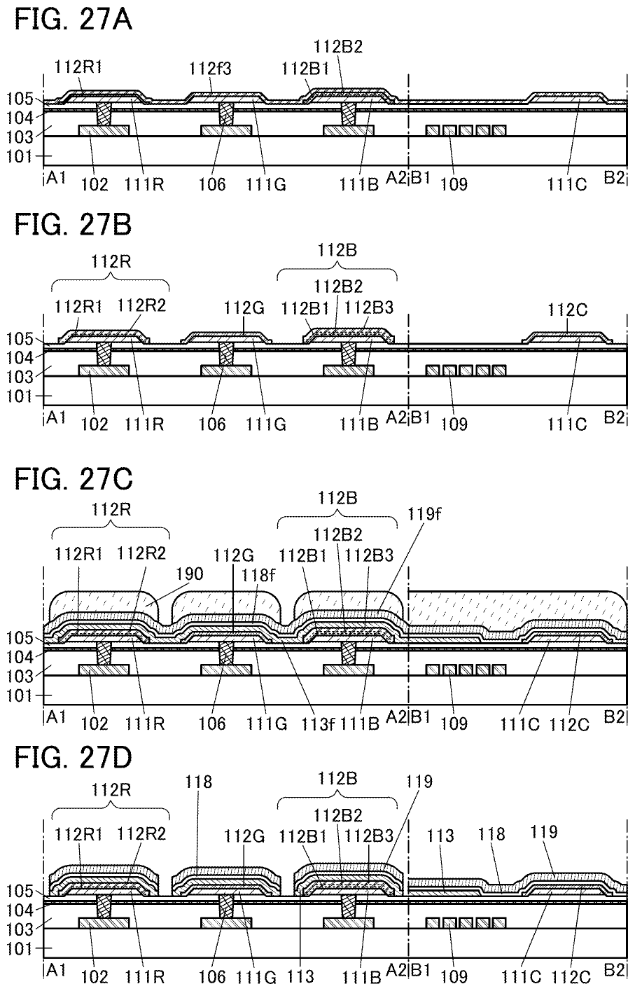

An example of a method for manufacturing the display device 100 having the structures illustrated in FIG. 13A and FIG. 12A will be described below with reference to FIGS. 26A to 26E and FIGS. 27A to 27D. FIGS. 26A to 26E and FIGS. 27A to 27D each show a cross section along the dashed-dotted line A1-A2 and a cross section along the dashed-dotted line B1-B2 in FIG. 1A. Note that steps different from those in the method described with FIGS. 16A1 to 25B will be mainly described, and the description of the same steps as those in the method described with FIGS. 16A1 to 25B will be omitted as appropriate.

First, steps similar to those illustrated in FIGS. 16A1 to 16C are performed. Thus, as illustrated in FIG. 26A, the conductive layers 111R, 111G, 111B, and 111C are formed over the plugs 106 and the insulating layer 105.

Next, as illustrated in FIG. 26B, a conductive film 112f1 is formed over the conductive layers 111R, 111G, 111B, and 111C and the insulating layer 105. The conductive film 112f1 can be formed by a method similar to that for the conductive film 112f illustrated in FIG. 17A1, for example, and formed using a material similar to that for the conductive film 112f.

Then, as illustrated in FIGS. 26B and 26C, the conductive film 112f1 is processed to form a conductive layer 112B1 that covers the top surface and the side surface of the conductive layer 111B. The conductive film 112f1 can be processed by a method similar to that for processing the conductive film 112f.

Next, as illustrated in FIG. 26D, a conductive film 112f2 is formed over the conductive layers 111R, 111G, 112B1, and 111C and the insulating layer 105. The conductive film 112f2 can be formed using a method and a material similar to those for the conductive film 112f.

Subsequently, as illustrated in FIGS. 26D and 26E, the conductive film 112f2 is processed, thereby forming the conductive layer 112R1 that cover the a top surface and the side surface of the conductive layer 111R and a conductive layer 112B2 over the conductive layer 112B1. In FIG. 26E, the boundary between the conductive layer 112B1 and the conductive layer 112B2 is indicated by a dotted line.

Next, as illustrated in FIG. 27A, a conductive film 112f3 is formed over the conductive layers 112R1, 111G, 112B2, and 111C and the insulating layer 105. The conductive film 112f3 can be formed using a method and a material similar to those for the conductive film 112f.

Then, as illustrated in FIGS. 27A and 27B, the conductive film 112f3 is processed, thereby forming a conductive layer 112R2 over the conductive layer 112R1, the conductive layer 112G that covers the top surface and the side surface of the conductive layer 111G, a conductive layer 112B3 over the conductive layer 112B2, and the conductive layer 112C that covers the top surface and the side surface of the conductive layer 111C. The conductive layers 112R1 and 112R2 can form the conductive layer 112R, and the conductive layers 112B1, 112B2, and 112B3 can form the conductive layer 112B. The conductive film 112f3 can be processed by a method similar to that for processing the conductive film 112E In FIG. 27B, the boundary between the conductive layer 112R1 and the conductive layer 112R2, the boundary between the conductive layer 112B1 and the conductive layer 112B2, and the boundary between the conductive layer 112B2 and the conductive layer 112B3 are indicated by dotted lines. The same applies to the following drawings.

In the above manner, the conductive layers 112R, 112G, and 112B can have different thicknesses. Note that among the conductive layers 112R, 112G, and 112B, the conductive layer 112B has the largest thickness and the conductive layer 112G has the smallest thickness; however, one embodiment of the present invention is not limited thereto, and the thicknesses of the conductive layers 112R, 112G, and 112B can be set as appropriate. For example, among the conductive layers 112R, 112G, and 112B, the conductive layer 112R may have the largest thickness, and the conductive layer 112B may have the smallest thickness.

Although the thickness of the conductive layer 112C is equal to that of the conductive layer 112G, one embodiment of the present invention is not limited thereto. For example, the thickness of the conductive layer 112C may be larger than that of the conductive layer 112G. For example, not only at the time of processing the conductive film 112f3 but also at the time of processing the conductive film 112f2, the conductive film may be left to cover the top surface and the side surface of the conductive layer 111C. In that case, the thickness of the conductive layer 112C can be equal to that of the conductive layer 112R, for example. Furthermore, at the time of processing any of the conductive films 112f1, 112f2, and 112f3, the conductive film may be left to cover the top surface and the side surface of the conductive layer 111C. In that case, the thickness of the conductive layer 112C can be equal to that of the conductive layer 112B, for example.

Next, as illustrated in FIG. 27C, an EL film 113f to be the EL layer 113 is formed over the conductive layers 112R, 112G, and 112B and the insulating layer 105. Then, a mask film 118f to be the mask layer 118 and a mask film 119f to be a mask layer 119 are sequentially formed over the EL film 113f, the conductive layer 112C, and the insulating layer 105.

Next, as illustrated in FIG. 27C, a resist mask 190 is formed over the mask film 119f The resist mask 190 is provided at a position overlapping the conductive layer 112R, a position overlapping the conductive layer 112G, and a position overlapping the conductive layer 112B. The resist mask 190 is preferably provided also at a position overlapping the conductive layer 112C. Furthermore, the resist mask 190 is preferably provided to cover the area from the end portion of the EL film 113Rf to the end portion of the conductive layer 112C (the end portion closer to the EL film 113Rf), as illustrated in the cross-sectional view along the line B1-B2 in FIG. 27C.

Subsequently, as illustrated in FIGS. 27C and 27D, part of the mask film 119f is removed using the resist mask 190, whereby the mask layer 119 is formed. The mask layer 119 remains over the conductive layers 112R, 112G, 112B, and 112C. After that, the resist mask 190 is removed. Then, part of the mask film 118f is removed using the mask layer 119 as a mask (also referred to as a hard mask), whereby the mask layer 118 is formed.

Next, as illustrated in FIGS. 27C and 27D, the EL film 113f is processed, so that the EL layer 113 is formed. For example, part of the EL film 113f is removed using the mask layers 119 and 118 as a hard mask, whereby the EL layer 113 is formed.

Thus, as illustrated in FIG. 27D, the stacked-layer structure of the EL layer 113, the mask layer 118, and the mask layer 119 is left over each of the conductive layers 112R, 112G, and 112B. In addition, in the cross section B1-B2, the mask layer 118 and the mask layer 119 can be provided to cover the area from the end portion of the EL layer 113 to the end portion of the conductive layer 112C (the end portion closer to the EL layer 113).

Next, steps similar to those illustrated in FIGS. 20A to 25B are performed. Then, the coloring layers 132R, 132G, and 132B are formed over the protective layer 131. Subsequently, the substrate 120 is attached to the coloring layer 132 using the resin layer 122, whereby the display device having the structures illustrated in FIG. 13A and FIG. 12A can be manufactured.

As described above, in the display device 100 having the structure illustrated in FIG. 13A, the EL film 113f, the mask film 118f, and the mask film 119f can each be completed by one formation step and one processing step, and do not need to be formed and processed separately for each color. Thus, the manufacturing process of the display device 100 can be simplified. This can reduce the manufacturing costs of the display device 100 and make the display device 100 inexpensive.

This embodiment can be combined with any of the other embodiments as appropriate. In this specification, in the case where a plurality of structure examples are shown in one embodiment, the structure examples can be combined as appropriate.

### Embodiment 2

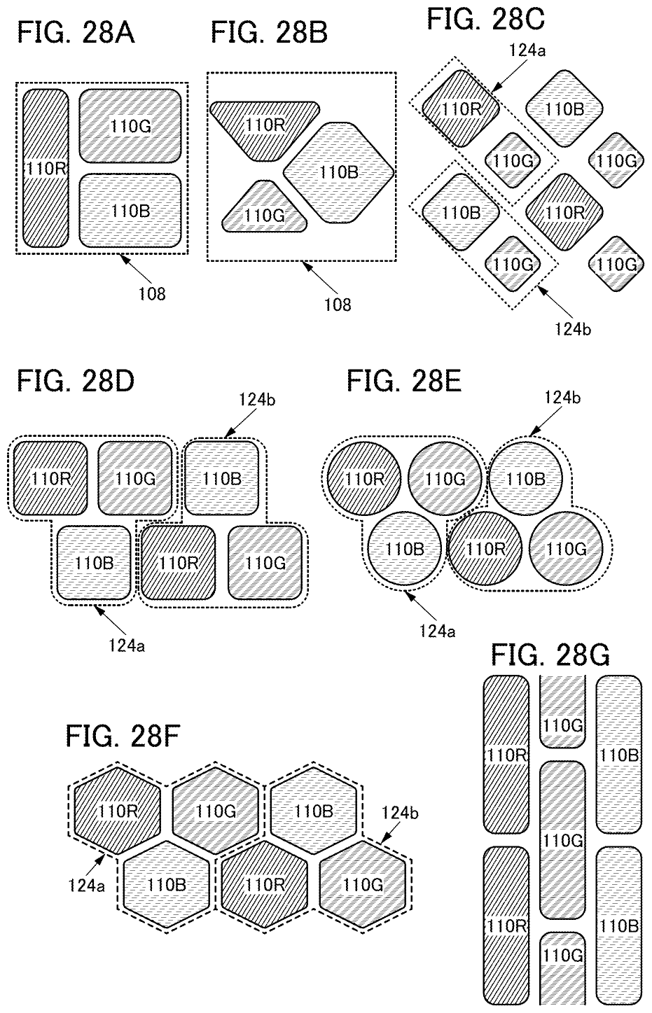

In this embodiment, the display device of one embodiment of the present invention will be described with reference to FIGS. 28A to 28G and FIGS. 29A to 291.

### [Pixel Layout]

In this embodiment, pixel layouts different from that in FIG. 1A will be mainly described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

In this embodiment, the top surface shapes of the subpixels shown in the diagrams correspond to top surface shapes of light-emitting regions.

Examples of a top surface shape of the subpixel include polygons such as a triangle, a tetragon (including a rectangle and a square), and a pentagon; polygons with rounded corners; an ellipse; and a circle.

The circuit constituting the subpixel is not necessarily placed within the dimensions of the subpixel illustrated in the diagrams and may be placed outside the subpixel.

The pixel 108 illustrated in FIG. 28A employs S-stripe arrangement. The pixel 108 illustrated in FIG. 28A includes three subpixels, the subpixel 110R, the subpixel 110G, and the subpixel 110B.

The pixel 108 illustrated in FIG. 28B includes the subpixel 110R whose top surface has a rough trapezoidal shape with rounded corners, the subpixel 110G whose top surface has a rough triangle shape with rounded corners, and the subpixel 110B whose top surface has a rough tetragonal or rough hexagonal shape with rounded corners. The subpixel 110R has a larger light-emitting area than the subpixel 110G. In this manner, the shapes and sizes of the subpixels can be determined independently. For example, the size of a subpixel including a light-emitting element with higher reliability can be smaller.

Pixels 124a and 124b illustrated in FIG. 28C employ PenTile arrangement. FIG. 28C shows an example in which the pixels 124a including the subpixels 110R and 110G and the pixels 124b including the subpixels 110G and 110B are alternately arranged.

The pixels 124a and 124b illustrated in FIGS. 28D to 28F employ delta arrangement. The pixel 124a includes two subpixels (the subpixels 110R and 110G) in the upper row (first row) and one subpixel (the subpixel 110B) in the lower row (second row). The pixel 124b includes one subpixel (the subpixel 110B) in the upper row (first row) and two subpixels (the subpixels 110R and 110G) in the lower row (second row).

FIG. 28D illustrates an example where each subpixel has a rough tetragonal top surface with rounded corners. FIG. 28E illustrates an example where each subpixel has a circular top surface. FIG. 28F illustrates an example where each subpixel has a rough hexagonal top surface with rounded corners.

In FIG. 28F, each subpixel is placed inside one of close-packed hexagonal regions. Focusing on one of the subpixels, the subpixel is placed so as to be surrounded by six subpixels. The subpixels are arranged such that subpixels that emit light of the same color are not adjacent to each other. For example, focusing on the subpixel 110R, the subpixel 110R is surrounded by three subpixels 110G and three subpixels 110B that are alternately arranged.

FIG. 28G shows an example where subpixels of different colors are arranged in a zigzag manner. Specifically, the positions of the top sides of two subpixels arranged in the column direction (e.g., the subpixel 110R and the subpixel 110G or the subpixel 110G and the subpixel 110B) are not aligned in the top view.

For the pixels illustrated in FIGS. 28A to 28G, for example, it is preferred that the subpixel 110R be a subpixel that emits red light, the subpixel 110G be a subpixel that emits green light, and the subpixel 110B be a subpixel that emits blue light. Note that the structures of the subpixels are not limited thereto, and the colors and the order of the subpixels can be determined as appropriate. For example, the subpixel 110G may be a subpixel that emits red light, and the subpixel 110R may be a subpixel that emits green light.

In a photolithography method, as a pattern to be formed by processing becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel can have a polygonal shape with rounded corners, an elliptical shape, a circular shape, or the like.

Furthermore, in the method for manufacturing the display device of one embodiment of the present invention, the EL layer is processed into an island shape with the use of a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape by processing. As a result, the top surface of the EL layer may have a polygonal shape with rounded corners, an elliptical shape, a circular shape, or the like. For example, when a resist mask with a square top surface is intended to be formed, a resist mask with a circular top surface may be formed, and the top surface of the EL layer may be circular.

To obtain a desired top surface shape of the EL layer, a technique of correcting a mask pattern in advance so that a transferred pattern agrees with a design pattern (an optical proximity correction (OPC) technique) may be used. Specifically, with the OPC technique, a pattern for correction is added to a corner portion of a figure on a mask pattern, for example.

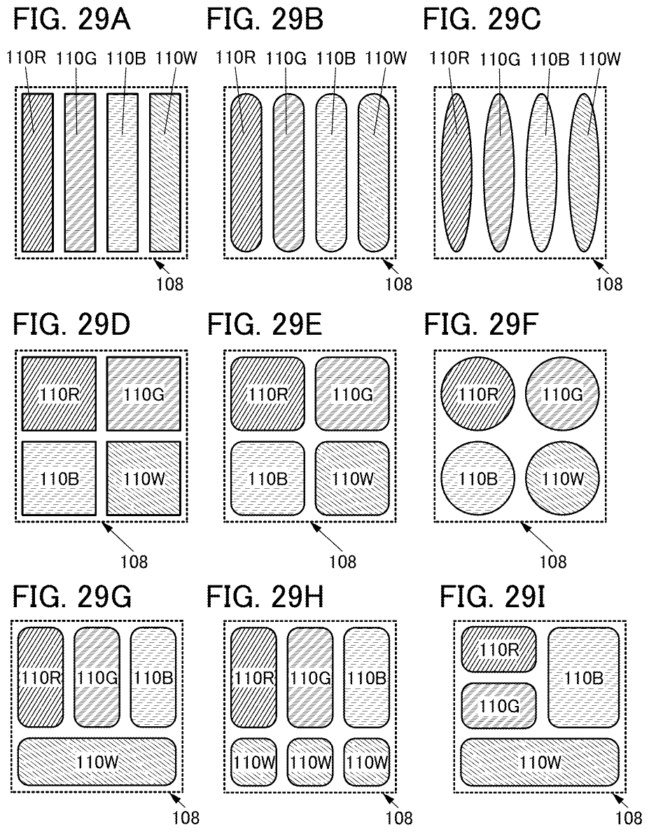

As illustrated in FIGS. 29A to 291, the pixel can include four types of subpixels.

The pixels 108 illustrated in FIGS. 29A to 29C employ stripe arrangement.

FIG. 29A illustrates an example where each subpixel has a rectangular top surface. FIG. 29B illustrates an example where each subpixel has a top surface shape formed by combining two half circles and a rectangle. FIG. 29C illustrates an example where each subpixel has an elliptical top surface.

The pixels 108 illustrated in FIGS. 29D to 29F employ matrix arrangement.

FIG. 29D illustrates an example where each subpixel has a square top surface. FIG. 29E illustrates an example where each subpixel has a substantially square top surface with rounded corners. FIG. 29F illustrates an example where each subpixel has a circular top surface.

FIGS. 29G and 29H each illustrate an example where one pixel 108 is composed of two rows and three columns.

The pixel 108 illustrated in FIG. 29G includes three subpixels (the subpixels 110R, 110G, and 110B) in the upper row (first row) and one subpixel (a subpixel 110W) in the lower row (second row). In other words, the pixel 108 includes the subpixel 110R in the left column (first column), the subpixel 110G in the middle column (second column), the subpixel 110B in the right column (third column), and the subpixel 110W across these three columns.

The pixel 108 illustrated in FIG. 29H includes three subpixels (the subpixels 110R, 110G, and 110B) in the upper row (first row) and three subpixels 110W in the lower row (second row). In other words, the pixel 108 includes the subpixel 110R and the subpixel 110W in the left column (first column), the subpixel 110G and another subpixel 110W in the middle column (second column), and the subpixel 110B and another subpixel 110W in the right column (third column). Matching the positions of the subpixels in the upper row and the lower row as illustrated in FIG. 29H enables dust that would be produced in the manufacturing process, for example, to be removed efficiently. Thus, a display device having high display quality can be provided.

In the pixel 108 illustrated in FIGS. 29G and 29H, the subpixels 110R, 110G, and 110B are arranged in a stripe pattern, whereby the display quality can be improved.

FIG. 29I illustrates an example where one pixel 108 is composed of three rows and two columns.

The pixel 108 illustrated in FIG. 29I includes the subpixel 110R in the upper row (first row), the subpixel 110G in the middle row (second row), the subpixel 110B across the first row and the second row, and one subpixel (the subpixel 110W) in the lower row (third row). In other words, the pixel 108 includes the subpixel 110R and the subpixel 110G in the left column (first column), the subpixel 110B in the right column (second column), and the subpixel 110W across these two columns.

In the pixel 108 illustrated in FIG. 29I, the subpixels 110R, 110G, and 110B are arranged in what is called an S-stripe pattern, whereby the display quality can be improved.

The pixel 108 illustrated in each of FIGS. 29A to 291 is composed of four subpixels, which are the subpixels 110R, 110G, 110B, and 110W. For example, the subpixel 110R can be a subpixel that emits red light, the subpixel 110G can be a subpixel that emits green light, the subpixel 110B can be a subpixel that emits blue light, and the subpixel 110W can be a subpixel that emits white light. Note that at least one of the subpixels 110R, 110G, 110B, and 110W may be a subpixel that emits cyan light, magenta light, yellow light, or near-infrared light.

As described above, the pixel composed of the subpixels each including the light-emitting element can employ any of a variety of layouts in the display device of one embodiment of the present invention.

This embodiment can be combined with any of the other embodiments as appropriate. In this specification, in the case where a plurality of structure examples are shown in one embodiment, the structure examples can be combined as appropriate.

### Embodiment 3

In this embodiment, the display device of one embodiment of the present invention will be described.

The display device in this embodiment can be a high-resolution display device. Thus, the display device in this embodiment can be used for display portions of information terminals (wearable devices) such as watch-type and bracelet-type information terminals and display portions of wearable devices capable of being worn on a head, such as a VR device like a head mounted display (HMD) and a glasses-type AR device.

The display device in this embodiment can be a high-definition display device or a large-sized display device. Accordingly, the display device in this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, desktop and laptop personal computers, a monitor of a computer and the like, digital signage, and a large game machine such as a pachinko machine.

### [Display Module]

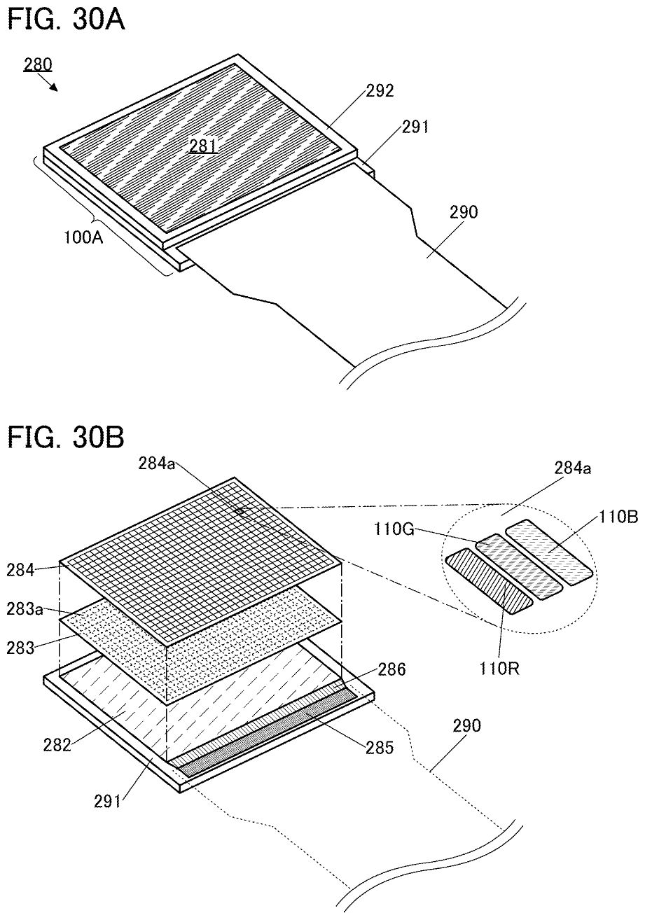

FIG. 30A is a perspective view of a display module 280. The display module 280 includes a display device 100A and an FPC 290. Note that the display device included in the display module 280 is not limited to the display device 100A and may be any of display devices 100B to 100G described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 30B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a region not overlapping with the pixel portion 284 over the substrate 291. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 30B. The pixels 284a can employ any of the structures described in the above embodiments. FIG. 30B illustrates an example where the pixel 284a has a structure similar to that of the pixel 108 illustrated in FIG. 1A.

The pixel circuit portion 283 includes a plurality of pixel circuits 283a arranged periodically.

The pixel circuit 283a has a function of controlling the driving of the light-emitting element included in the pixel 284a. For example, the pixel circuit 283a can include at least one selection transistor, one current control transistor (driving transistor), and a capacitor for one light-emitting element. In this case, a gate signal is input to a gate of the selection transistor, and a data signal (also referred to as a video signal) is input to a source or a drain of the selection transistor. Thus, an active-matrix display device is achieved.

The circuit portion 282 includes a circuit for driving the pixel circuits 283a in the pixel circuit portion 283. For example, the circuit portion 282 preferably includes one or both of a gate line driver circuit and a data line driver circuit. The circuit portion 282 may also include at least one of an arithmetic circuit, a memory circuit, a power supply circuit, and the like.

The FPC 290 functions as a wiring for supplying a data signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have significantly high resolution. For example, the pixels 284a are preferably arranged in the display portion 281 with a resolution greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi.

Such a display module 280 has extremely high resolution, and thus can be suitably used for a VR device such as a HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic devices including a relatively small display portion. For example, the display module 280 can be favorably used in a display portion of a wearable electronic device, such as a wrist watch.

### [Display Device 100A]

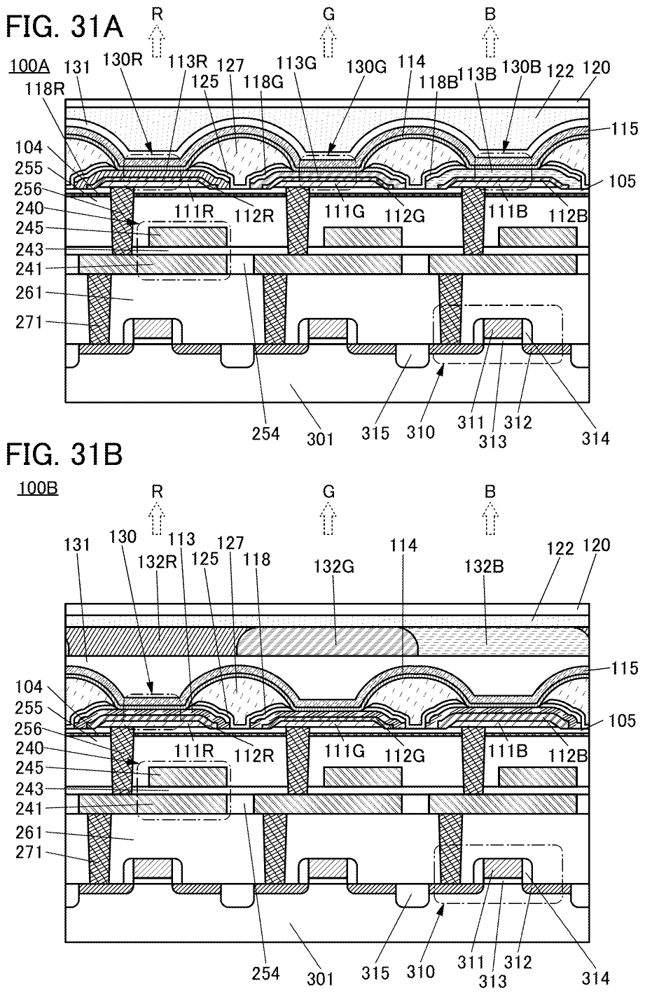

The display device 100A illustrated in FIG. 31A includes a substrate 301, the light-emitting elements 130R, 130G, and 130B, a capacitor 240, and a transistor 310.

The substrate 301 corresponds to the substrate 291 in FIGS. 30A and 30B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a pair of low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The pair of low-resistance regions 312 are regions where the substrate 301 is doped with an impurity, and function as a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping the conductive layer 241 with the insulating layer 243 therebetween.

An insulating layer 255 is provided to cover the capacitor 240. The insulating layer 104 is provided over the insulating layer 255. The insulating layer 105 is provided over the insulating layer 104. The light-emitting elements 130R, 130G, and 130B are provided over the insulating layer 105. FIG. 31A illustrates an example in which the light-emitting elements 130R, 130G, and 130B each have the stacked-layer structure illustrated in FIG. 1B. An insulator is provided in regions between adjacent light-emitting elements. For example, in FIG. 31A, the insulating layer 125 and the insulating layer 127 over the insulating layer 125 are provided in those regions.

The conductive layer 112R is provided to cover the top surface and the side surface of the conductive layer 111R included in the light-emitting element 130R. The conductive layer 112G is provided to cover the top surface and the side surface of the conductive layer 111G included in the light-emitting element 130G. The conductive layer 112B is provided to cover the top surface and the side surface of the conductive layer 111B included in the light-emitting element 130B. The mask layer 118R is positioned over the EL layer 113R included in the light-emitting element 130R. The mask layer 118G is positioned over the EL layer 113G included in the light-emitting element 130G. The mask layer 118B is positioned over the EL layer 113B included in the light-emitting element 130B.

Each of the conductive layers 111R, 111G, and 111B is electrically connected to one of the source and the drain of the corresponding transistor 310 through a plug 256 embedded in the insulating layers 243, 255, 104, and 105, the conductive layer 241 embedded in the insulating layer 254, and the plug 271 embedded in the insulating layer 261. The top surface of the insulating layer 105 and the top surface of the plug 256 are level with or substantially level with each other. Any of a variety of conductive materials can be used for the plugs.

The protective layer 131 is provided over the light-emitting elements 130R, 130G, and 130B. The substrate 120 is attached to the protective layer 131 with the resin layer 122. Embodiment 1 can be referred to for the details of the light-emitting element 130 and the components thereover up to the substrate 120. The substrate 120 corresponds to the substrate 292 in FIG. 30A.

### [Display Device 100B]

The display device 100B illustrated in FIG. 31B includes the coloring layers 132R, 132G, and 132B, and each light-emitting element 130 includes a region overlapped by one of the coloring layers 132R, 132G, and 132B. FIG. 13A can be referred to for the details of the light-emitting element 130 and the components thereover up to the substrate 120 in the display device 100B. In the display device 100B, the light-emitting element 130 can emit white light, for example. For example, the coloring layer 132R, the coloring layer 132G, and the coloring layer 132B can transmit red light, green light, and blue light, respectively.

### [Display Device 100C]

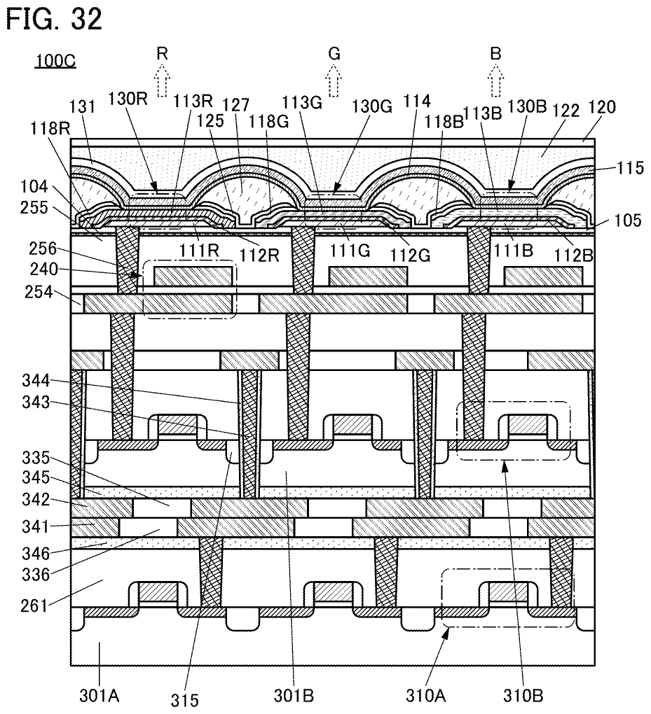

In the display device 100C illustrated in FIG. 32, a transistor 310A and a transistor 310B in each of which a channel is formed in a semiconductor substrate are stacked. Note that in the following description of display devices, the description of portions similar to those of the above-described display devices may be omitted.

In the display device 100C, a substrate 301B provided with the transistor 310B, the capacitor 240, and the light-emitting elements 130 is bonded to a substrate 301A provided with the transistor 310A.

Here, an insulating layer 345 is preferably provided on the bottom surface of the substrate 301B. An insulating layer 346 is preferably provided over the insulating layer 261 over the substrate 301A. The insulating layers 345 and 346 function as protective layers and can inhibit diffusion of impurities into the substrate 301B and the substrate 301A. As the insulating layers 345 and 346, an inorganic insulating film that can be used as the protective layer 131 can be used.

The substrate 301B is provided with a plug 343 that penetrates the substrate 301B and the insulating layer 345. An insulating layer 344 is preferably provided to cover the side surface of the plug 343. The insulating layer 344 functions as a protective layer and can inhibit diffusion of impurities into the substrate 301B. As the insulating layer 344, an inorganic insulating film that can be used as the protective layer 131 can be used.

A conductive layer 342 is provided under the insulating layer 345 on the substrate 301B. The conductive layer 342 is preferably provided to be embedded in the insulating layer 335. The bottom surfaces of the conductive layer 342 and the insulating layer 335 are preferably planarized. Here, the conductive layer 342 is electrically connected to the plug 343.

A conductive layer 341 is provided over the insulating layer 346 between the substrate 301A and the substrate 301B. The conductive layer 341 is preferably provided to be embedded in the insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layers 341 and 342 to be bonded to each other favorably.

The conductive layers 341 and 342 are preferably formed using the same conductive material. For example, it is possible to use a metal film containing an element selected from Al, Cr, Cu, Ta, Ti, Mo, and W, or a metal nitride film containing any of the above elements as a component (e.g., a titanium nitride film, a molybdenum nitride film, or a tungsten nitride film). Copper is particularly preferably used for the conductive layers 341 and 342. In that case, it is possible to employ copper-to-copper (Cu-to-Cu) direct bonding (a technique for achieving electrical continuity by connecting copper (Cu) pads).

### [Display Device 100D]

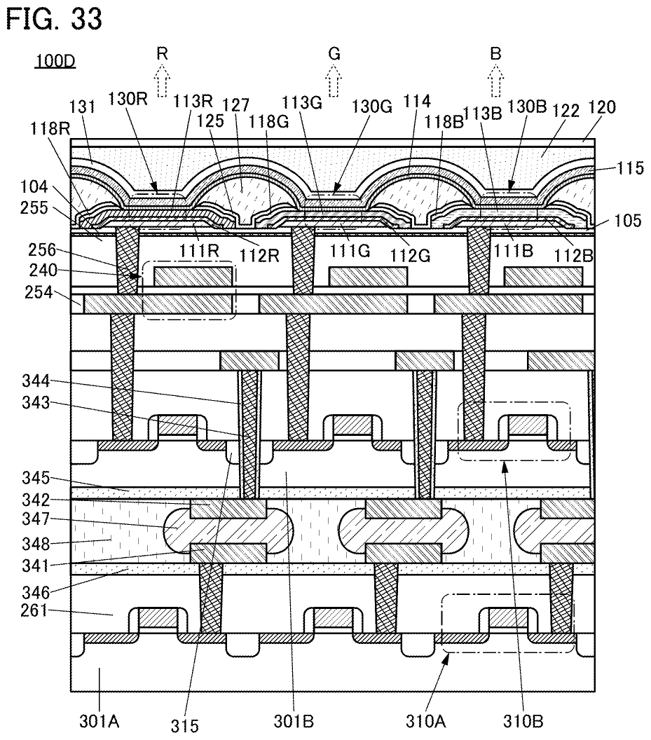

In the display device 100D illustrated in FIG. 33, the conductive layer 341 and the conductive layer 342 are bonded to each other with a bump 347.

As illustrated in FIG. 33, providing the bump 347 between the conductive layer 341 and the conductive layer 342 enables the conductive layers 341 and 342 to be electrically connected to each other. The bump 347 can be formed using a conductive material containing gold (Au), nickel (Ni), indium (In), tin (Sn), or the like, for example. As another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### [Display Device 100E]

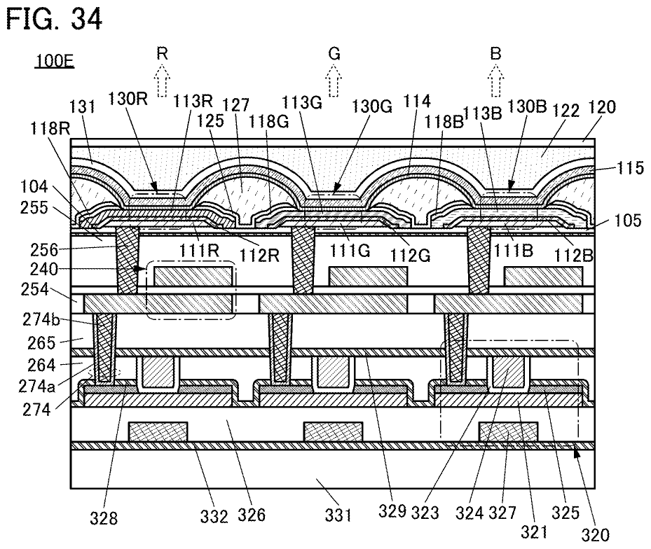

The display device 100E illustrated in FIG. 34 differs from the display device 100A mainly in a structure of a transistor.

A transistor 320 is a transistor that contains a metal oxide (also referred to as an oxide semiconductor) in a semiconductor layer where a channel is formed (i.e., an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 illustrated in FIGS. 30A and 30B. As the substrate 331, an insulating substrate or a semiconductor substrate can be used.

An insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film can be used. Examples of such a film include an aluminum oxide film, a hafnium oxide film, and a silicon nitride film.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used for at least a region of the insulating layer 326 that is in contact with the semiconductor layer 321. The top surface of the insulating layer 326 is preferably planarized.

The semiconductor layer 321 is provided over the insulating layer 326. A metal oxide film having semiconductor characteristics is preferably used as the semiconductor layer 321. The pair of conductive layers 325 are provided over and in contact with the semiconductor layer 321, and function as a source electrode and a drain electrode.

An insulating layer 328 is provided to cover the top and side surfaces of the pair of conductive layers 325, the side surface of the semiconductor layer 321, and the like. An insulating layer 264 is provided over the insulating layer 328. The insulating layer 328 functions as a barrier layer that prevents diffusion of impurities such as water and hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layers 328 and 264. The insulating layer 323 that is in contact with the side surfaces of the insulating layers 264 and 328 and the conductive layer 325 and the top surface of the semiconductor layer 321, and the conductive layer 324 over the insulating layer 323 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are level with or substantially level with each other, and an insulating layer 329 and an insulating layer 265 are provided to cover these layers.

The insulating layers 264 and 265 each function as an interlayer insulating layer. The insulating layer 329 functions as a barrier layer that prevents diffusion of impurities such as water and hydrogen from the insulating layer 265 and the like to the transistor 320. As the insulating layer 329, an insulating film similar to the insulating layers 328 and 332 can be used.

A plug 274 electrically connected to one of the pair of conductive layers 325 is provided to be embedded in the insulating layers 265, 329, 264, and 328. Here, the plug 274 preferably includes a conductive layer 274a that covers the side surface of an opening formed in the insulating layers 265, 329, 264, and 328 and part of the top surface of the conductive layer 325, and a conductive layer 274b in contact with the top surface of the conductive layer 274a. For the conductive layer 274a, a conductive material in which hydrogen and oxygen are less likely to diffuse is preferably used.

### [Display Device 100F]

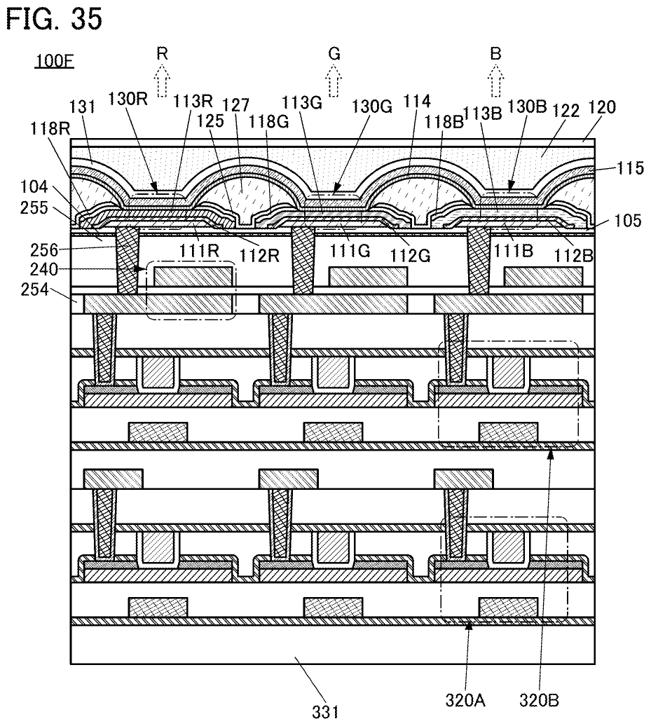

In the display device 100F illustrated in FIG. 35, a transistor 320A and a transistor 320B each including an oxide semiconductor in a semiconductor where a channel is formed are stacked.

The description of the display device 100E can be referred to for the transistor 320A, the transistor 320B, and other peripheral structures.

Although the structure in which two transistors each including an oxide semiconductor are stacked is described, one embodiment of the present invention is not limited thereto. For example, three or more transistors may be stacked.

### [Display Device 100G]

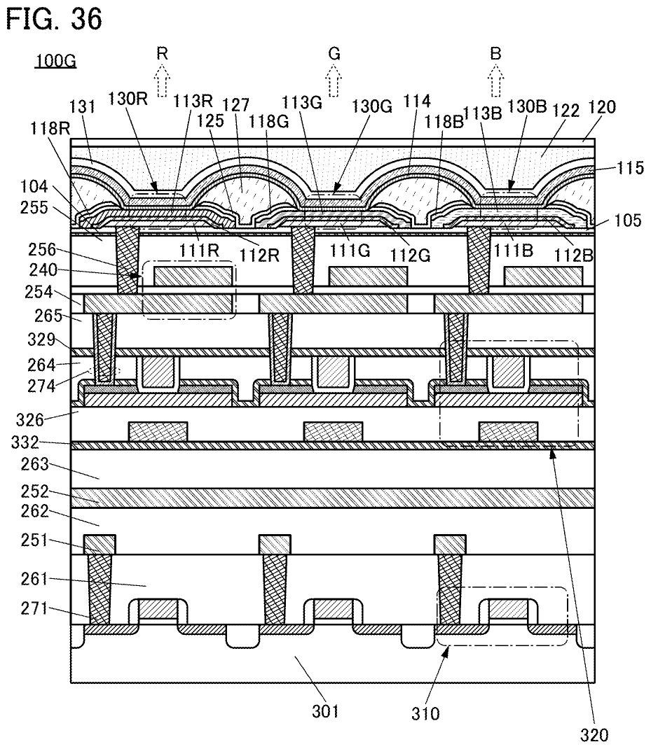

In the display device 100G illustrated in FIG. 36, the transistor 310 whose channel is formed in the substrate 301 and the transistor 320 including a metal oxide in the semiconductor layer where the channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided so as to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit for driving the pixel circuit (e.g., a gate line driver circuit or a data line driver circuit). The transistor 310 and the transistor 320 can also be used as transistors included in a variety of circuits such as an arithmetic circuit and a memory circuit.

With such a structure, not only the pixel circuit but also the driver circuit, for example, can be formed directly under the light-emitting element; thus, the display device can be downsized as compared to the case where the driver circuit is provided around a display portion.

### [Display Device 100H]

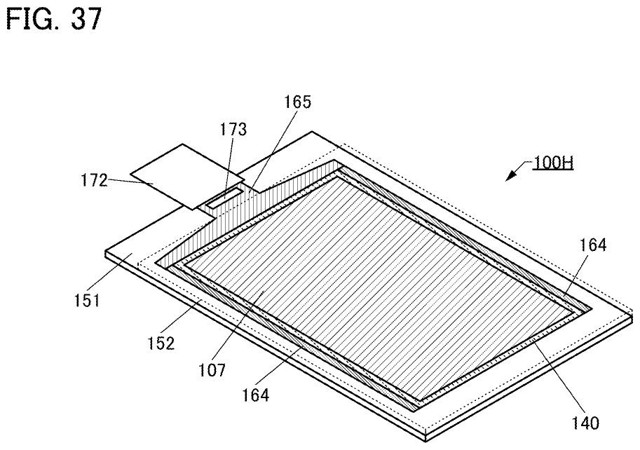

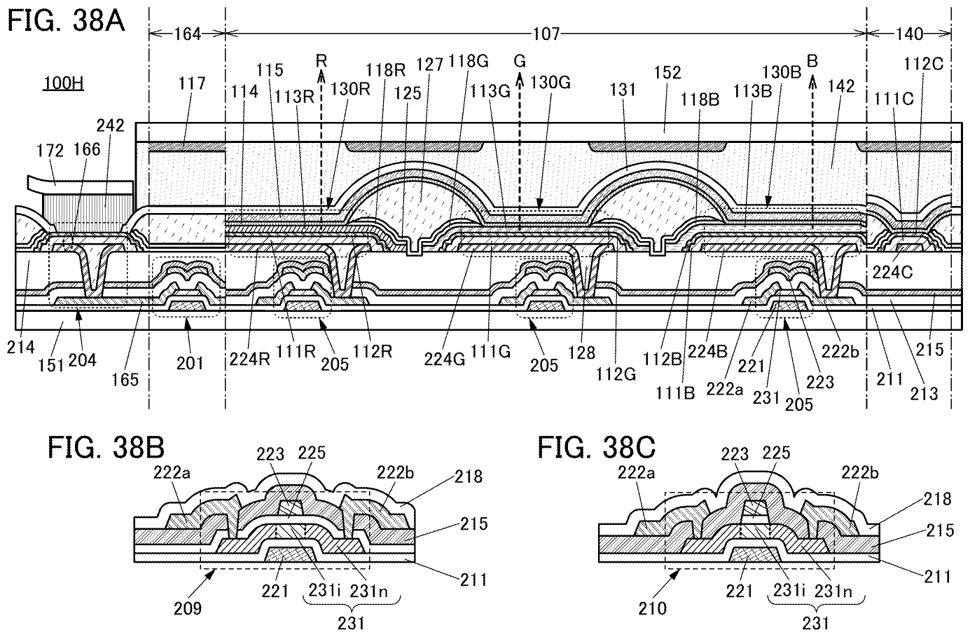

FIG. 37 is a perspective view of the display device 100H, and FIG. 38A is a cross-sectional view of the display device 100H.

In the display device 100H, a substrate 152 and a substrate 151 are attached to each other. In FIG. 37, the substrate 152 is denoted by a dashed line.

The display device 100H includes the pixel portion 107, the connection portion 140, a circuit 164, a wiring 165, and the like. FIG. 37 illustrates an example in which an IC 173 and an FPC 172 are mounted on the display device 100H. Thus, the structure illustrated in FIG. 37 can be regarded as a display module including the display device 100H, the integrated circuit (IC), and the FPC. Here, a display device in which a substrate is equipped with a connector such as an FPC or mounted with an IC is referred to as a display module.

The connection portion 140 is provided outside the pixel portion 107. The connection portion 140 can be provided along one side or a plurality of sides of the pixel portion 107. The number of connection portions 140 may be one or more. FIG. 37 illustrates an example in which the connection portion 140 is provided to surround the four sides of the pixel portion 107. In the connection portion 140, a common electrode of a light-emitting element is electrically connected to a conductive layer so that a potential can be supplied to the common electrode.

As the circuit 164, a gate line driver circuit can be used, for example.

A signal and power can be supplied to the pixel portion 107 and the circuit 164 through the wiring 165. The signal and power are input to the wiring 165 from the outside through the FPC 172 or from the IC 173.

FIG. 37 illustrates an example in which the IC 173 is provided over the substrate 151 by a chip on glass (COG) method, a chip on film (COF) method, or the like. An IC including a gate line driver circuit, a data line driver circuit, or the like can be used as the IC 173, for example. Note that the display device 100H and the display module are not necessarily provided with an IC. Alternatively, the IC may be mounted on the FPC by a COF method, for example.

FIG. 38A illustrates an example of cross sections of part of a region including the FPC 172, part of the circuit 164, part of the pixel portion 107, part of the connection portion 140, and part of a region including an end portion of the display device 100H.

The display device 100H illustrated in FIG. 38A includes a transistor 201, a transistor 205, the light-emitting element 130R that emits red light, the light-emitting element 130G that emits green light, the light-emitting element 130B that emits blue light, and the like between the substrate 151 and the substrate 152.

Other than a difference in the structure of the pixel electrode, the light-emitting elements 130R, 130G, 130B each have the stacked-layer structure illustrated in FIG. 1B. Embodiment 1 can be referred to for the details of the light-emitting elements 130.

The light-emitting element 130R includes a conductive layer 224R, the conductive layer 111R over the conductive layer 224R, and the conductive layer 112R over the conductive layer 111R. The light-emitting element 130G includes a conductive layer 224G, the conductive layer 111G over the conductive layer 224G, and the conductive layer 112G over the conductive layer 111G. The light-emitting element 130B includes a conductive layer 224B, the conductive layer 111B over the conductive layer 224B, and the conductive layer 112B over the conductive layer 111B. Here, the conductive layers 224R, 111R, and 112R can be collectively referred to as the pixel electrode of the light-emitting element 130R; the conductive layers 111R and 112R excluding the conductive layer 224R can also be referred to as the pixel electrode of the light-emitting element 130R. Similarly, the conductive layers 224G, 111G, and 112G can be collectively referred to as the pixel electrode of the light-emitting element 130G; the conductive layers 111G and 112G excluding the conductive layer 224G can also be referred to as the pixel electrode of the light-emitting element 130G. The conductive layers 224B, 111B, and 112B can be collectively referred to as the pixel electrode of the light-emitting element 130B; the conductive layers 111B and 112B excluding the conductive layer 224B can also be referred to as the pixel electrode of the light-emitting element 130B.

The conductive layer 224R is electrically connected to a conductive layer 222b included in the transistor 205 through an opening provided in insulating layers 214, 215, and 213. The end portion of the conductive layer 111R is positioned on the outer side of the end portion of the conductive layer 224R. The conductive layer 112R is provided to cover the top surface and the side surface of the conductive layer 111R.

The conductive layers 224G, 111G, and 112G in the light-emitting element 130G and the conductive layers 224B, 111B, and 112B in the light-emitting element 130B are similar to the conductive layers 224R, 111R, and 112R in the light-emitting element 130R; therefore, the detailed description is omitted.

The conductive layers 224R, 224G, and 224B are provided along openings in the insulating layers 214, 215, and 213. Thus, each of the conductive layers 224R, 224G, and 224B has a depression portion. An layer 128 is embedded in the depression portions.

The layer 128 has a function of filling the depression portions of the conductive layers 224R, 224G, and 224B to obtain planarity. The conductive layer 111R electrically connected to the conductive layer 224R is provided over the conductive layer 224R and the layer 128. The conductive layer 111G electrically connected to the conductive layer 224G is provided over the conductive layer 224G and the layer 128. The conductive layer 111B electrically connected to the conductive layer 224B is provided over the conductive layer 224B and the layer 128. In the above manner, the regions overlapping the depression portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting elements 130R, 130G, and 130B. The protective layer 131 and the substrate 152 are bonded to each other with an adhesive layer 142. A solid sealing structure, a hollow sealing structure, or the like can be employed to seal the light-emitting element 130. In FIG. 38A, a solid sealing structure is employed, in which a space between the substrate 152 and the substrate 151 is filled with the adhesive layer 142. Alternatively, the space may be filled with an inert gas (e.g., nitrogen or argon), i.e., a hollow sealing structure may be employed. In that case, the adhesive layer 142 may be provided not to overlap the light-emitting element. Alternatively, the space may be filled with a resin other than the frame-like adhesive layer 142.

A light-blocking layer 117 is preferably provided on the surface of the substrate 152 on the substrate 151 side. The light-blocking layer 117 can be provided between the adjacent light-emitting elements 130. This can prevent light emitted from the light-emitting element 130 from being reflected by the substrate 152 and diffusing inside the display device 100H, for example. Thus, the display device 100H can have high display quality. Note that the light-blocking layer 117 can also be provided in the connection portion 140, the circuit 164, and the like. A variety of optical members can be arranged on the outer surface of the substrate 152.

FIG. 38A illustrates an example in which the connection portion 140 includes a conductive layer 224C obtained by processing the same conductive film as the conductive layers 224R, 224G, and 224B; the conductive layer 111C obtained by processing the same conductive film as the conductive layers 111R, 111G, and 111B; and the conductive layer 112C obtained by processing the same conductive film as the conductive layers 112R, 112G, and 112B.

The display device 100H has a top-emission structure. Light from the light-emitting element is emitted toward the substrate 152. For the substrate 152, a material having a high visible-light-transmitting property is preferably used. The pixel electrode contains a material that reflects visible light, and the counter electrode (the common electrode 115) contains a material that transmits visible light.

The transistor 201 and the transistor 205 are formed over the substrate 151. These transistors can be fabricated using the same materials in the same steps.

An insulating layer 211, an insulating layer 213, an insulating layer 215, and an insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material through which impurities such as water and hydrogen do not easily diffuse is preferably used for at least one of the insulating layers covering the transistors. This is because such an insulating layer can function as a barrier layer. Such a structure can effectively inhibit diffusion of impurities into the transistors from the outside and increase the reliability of the display device.

An inorganic insulating film is preferably used as each of the insulating layers 211, 213, and 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably functions as an etching protective layer. This can inhibit formation of a recessed portion in the insulating layer 214 at the time of processing the conductive layer 224, the conductive layer 111, the conductive layer 112, or the like, for example. Alternatively, a recessed portion may be provided in the insulating layer 214 at the time of processing the conductive layer 224, the conductive layer 111, the conductive layer 112, or the like.

Each of the transistors 201 and 205 includes a conductive layer 221 functioning as a gate, the insulating layer 211 functioning as a gate insulating layer, a conductive layer 222a and a conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

The structure in which the semiconductor layer where a channel is formed is provided between two gates is used for the transistors 201 and 205. The two gates may be connected to each other and supplied with the same signal to operate the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) can be used. It is preferable to use a semiconductor having crystallinity, in which case deterioration of transistor characteristics can be suppressed.

The semiconductor layer of the transistor preferably includes a metal oxide. That is, a transistor including a metal oxide in its channel formation region (an OS transistor) is preferably used in the display device of this embodiment.

Examples of an oxide semiconductor having crystallinity include a c-axis-aligned crystalline oxide semiconductor (CAAC-OS) and a nanocrystalline oxide semiconductor (nc-OS).

Alternatively, a transistor using silicon in its channel formation region (a Si transistor) may be used. Examples of silicon include single crystal silicon, polycrystalline silicon, and amorphous silicon. In particular, a transistor containing low-temperature polysilicon (LTPS) in its semiconductor layer (also referred to as an LTPS transistor) can be used. The LTPS transistor has high field-effect mobility and excellent frequency characteristics.

With the use of Si transistors such as LTPS transistors, a circuit required to be driven at a high frequency (e.g., a data driver circuit) can be formed on the same substrate as the display portion. This allows simplification of an external circuit mounted on the display device and a reduction in costs of parts and mounting costs.

An OS transistor has much higher field-effect mobility than a transistor containing amorphous silicon. In addition, the OS transistor has an extremely low leakage current between a source and a drain in an off state (hereinafter also referred to as off-state current), and charge accumulated in a capacitor that is connected in series to the transistor can be held for a long period. Furthermore, the power consumption of the display device can be reduced with the OS transistor.

To increase the luminance of the light-emitting element included in the pixel circuit, the amount of current fed through the light-emitting element needs to be increased. To increase the current amount, the source—drain voltage of a driving transistor included in the pixel circuit needs to be increased. An OS transistor has a higher withstand voltage between a source and a drain than a Si transistor; hence, high voltage can be applied between the source and the drain of the OS transistor. Therefore, when an OS transistor is used as the driving transistor in the pixel circuit, the amount of current flowing through the light-emitting element can be increased, so that the luminance of the light-emitting element can be increased.

When transistors are driven in a saturation region, a change in source—drain current relative to a change in gate—source voltage can be smaller in an OS transistor than in a Si transistor. Accordingly, when an OS transistor is used as the driving transistor included in the pixel circuit, a current flowing between the source and the drain can be minutely determined by controlling the gate—source voltage. Thus, the amount of current flowing through the light-emitting element can be controlled. Consequently, the number of gray levels expressed by the pixel circuit can be increased.

Regarding saturation characteristics of current flowing when transistors are driven in the saturation region, even when the source—drain voltage of an OS transistor increases gradually, a more stable current (saturation current) can be fed through the OS transistor than through a Si transistor. Thus, by using an OS transistor as the driving transistor, a stable current can be fed through light-emitting elements even when the current—voltage characteristics of the organic EL elements vary, for example. In other words, when the OS transistor is driven in the saturation region, the source—drain current hardly changes with an increase in the source—drain voltage. Hence, the luminance of the light-emitting element can be stable.

As described above, by using OS transistors as the driving transistors included in the pixel circuits, it is possible to prevent black-level degradation, increase the luminance, increase the number of gray levels, and suppress variations in characteristics of light-emitting elements, for example.

The semiconductor layer preferably contains indium, M (M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more of aluminum, gallium, yttrium, and tin.

It is particularly preferable that an oxide containing indium (In), gallium (Ga), and zinc (Zn) (also referred to as IGZO) be used for the semiconductor layer. It is preferable to use an oxide containing indium, tin, and zinc. It is preferable to use an oxide containing indium, gallium, tin, and zinc. It is preferable to use an oxide containing indium (In), aluminum (Al), and zinc (Zn) (also referred to as IAZO). It is preferable to use an oxide containing indium (In), aluminum (Al), gallium (Ga), and zinc (Zn) (also referred to as IAGZO).

When the semiconductor layer is an In-M-Zn oxide, the atomic ratio of In is preferably greater than or equal to the atomic ratio of M in the In-M-Zn oxide. Examples of the atomic ratio of the metal elements in such an In-M-Zn oxide are In:M:Zn=1:1:1, 1:1:1.2, 2:1:3, 3:1:2, 4:2:3, 4:2:4.1, 5:1:3, 5:1:6, 5:1:7, 5:1:8, 6:1:6, and 5:2:5 and a composition in the vicinity of any of the above atomic ratios. Note that the vicinity of the atomic ratio includes ±30% of an intended atomic ratio.

For example, in the case of describing an atomic ratio of In:Ga:Zn=4:2:3 or a composition in the vicinity thereof, the case is included in which with the atomic proportion of In being 4, the atomic proportion of Ga is greater than or equal to 1 and less than or equal to 3 and the atomic proportion of Zn is greater than or equal to 2 and less than or equal to 4. In the case of describing an atomic ratio of In:Ga:Zn=5:1:6 or a composition in the vicinity thereof, the case is included in which with the atomic proportion of In being 5, the atomic proportion of Ga is greater than 0.1 and less than or equal to 2 and the atomic proportion of Zn is greater than or equal to 5 and less than or equal to 7. In the case of describing an atomic ratio of In:Ga:Zn=1:1:1 or a composition in the vicinity thereof, the case is included in which with the atomic proportion of In being 1, the atomic proportion of Ga is greater than 0.1 and less than or equal to 2 and the atomic proportion of Zn is greater than 0.1 and less than or equal to 2.

The transistors included in the circuit 164 and the transistors included in the pixel portion 107 may have the same structure or different structures. One structure or two or more kinds of structures may be employed for a plurality of transistors included in the circuit 164. Similarly, one structure or two or more kinds of structures may be employed for a plurality of transistors included in the pixel portion 107.

All transistors included in the pixel portion 107 may be OS transistors, or all transistors included in the pixel portion 107 may be Si transistors. Alternatively, some of the transistors included in the pixel portion 107 may be OS transistors and the others may be Si transistors.

For example, when both an LTPS transistor and an OS transistor are used in the pixel portion 107, the display device can have low power consumption and high driving capability. Note that a structure in which an LTPS transistor and an OS transistor are used in combination is referred to as LTPO in some cases. For example, it is preferable that an OS transistor be used as a transistor functioning as a switch for controlling electrical continuity between wirings and an LTPS transistor be used as a transistor for controlling current.

For example, one transistor included in the pixel portion 107 functions as a transistor for controlling a current flowing through the light-emitting element and can be referred to as a driving transistor. One of a source and a drain of the driving transistor is electrically connected to the pixel electrode of the light-emitting element. An LTPS transistor is preferably used as the driving transistor. In that case, the amount of current flowing through the light-emitting element can be increased.

Another transistor included in the pixel portion 107 functions as a switch for controlling selection or non-selection of a pixel and can be referred to as a selection transistor. A gate of the selection transistor is electrically connected to a gate line, and one of a source and a drain thereof is electrically connected to a data line. An OS transistor is preferably used as the selection transistor. In that case, the gray level of the pixel can be maintained even with an extremely low frame frequency (e.g., 1 fps or less); thus, power consumption can be reduced by stopping the driver in displaying a still image.

As described above, the display device of one embodiment of the present invention can have all of a high aperture ratio, high resolution, high display quality, and low power consumption.

Note that the display device of one embodiment of the present invention has a structure including the OS transistor and the light-emitting element having an MML structure. This structure can significantly reduce a leakage current that would flow through a transistor and a leakage current that would flow between adjacent light-emitting elements. Displaying images on the display device having this structure can bring one or more of image crispness, image sharpness, high color saturation, and a high contrast ratio to the viewer. When a leakage current that would flow through the transistor and a lateral leakage current that would flow between light-emitting elements are extremely low, display with little leakage of light at the time of black display (black-level degradation), for example, can be achieved.

In particular, in the case where a light-emitting element having an MML structure employs the SBS structure, a layer provided between light-emitting elements is disconnected; accordingly, display with no or extremely small side leakage can be achieved.

FIGS. 38B and 38C illustrate other structure examples of transistors.

Transistors 209 and 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a electrically connected to one of the pair of low-resistance regions 231n, the conductive layer 222b electrically connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistor may be provided.

FIG. 38B illustrates an example of the transistor 209 in which the insulating layer 225 covers the top and side surfaces of the semiconductor layer 231. The conductive layer 222a and the conductive layer 222b are electrically connected to the corresponding low-resistance regions 231n through openings provided in the insulating layer 225 and the insulating layer 215. One of the conductive layers 222a and 222b functions as a source, and the other functions as a drain.

In the transistor 210 illustrated in FIG. 38C, the insulating layer 225 overlaps the channel formation region 231i of the semiconductor layer 231 and does not overlap the low-resistance regions 231n. The structure illustrated in FIG. 38C is obtained by processing the insulating layer 225 with the conductive layer 223 as a mask, for example. In FIG. 38C, the insulating layer 215 is provided to cover the insulating layer 225 and the conductive layer 223, and the conductive layer 222a and the conductive layer 222b are electrically connected to the corresponding low-resistance regions 231n through openings in the insulating layer 215.

A connection portion 204 is provided in a region of the substrate 151 where the substrate 152 does not overlap. In the connection portion 204, the wiring 165 is electrically connected to the FPC 172 through a conductive layer 166 and a connection layer 242. As an example, the conductive layer 166 has a stacked-layer structure of a conductive film obtained by processing the same conductive film as the conductive layers 224R, 224G, and 224B; a conductive film obtained by processing the same conductive film as the conductive layers 111R, 111G, and 111B; and a conductive film obtained by processing the same conductive film as the conductive layers 112R, 112G, and 112B. On the top surface of the connection portion 204, the conductive layer 166 is exposed. Thus, the connection portion 204 and the FPC 172 can be electrically connected to each other through the connection layer 242.

A material that can be used for the substrate 120 can be used for each of the substrates 151 and 152.

A material that can be used for the resin layer 122 can be used for the adhesive layer 142.

As the connection layer 242, an anisotropic conductive film (ACF), an anisotropic conductive paste (ACP), or the like can be used.

### [Display Device 100I]

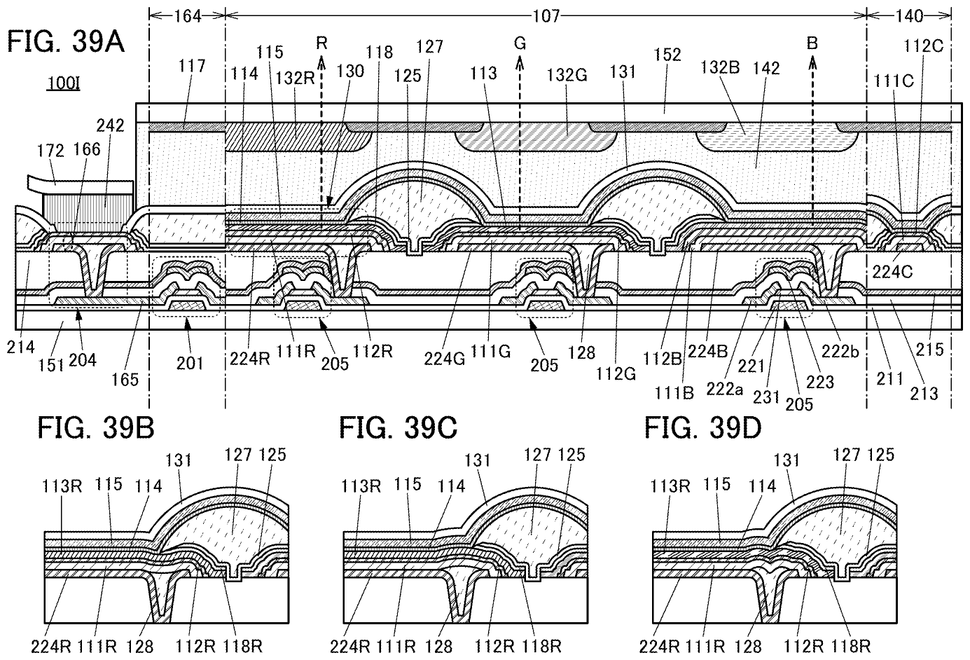

The display device 100I illustrated in FIG. 39A is a variation example of the display device 100H illustrated in FIG. 38A and differs from the display device 100H mainly in including the coloring layers 132R, 132G, and 132B.

In the display device 100I, the light-emitting element 130 includes a region overlapped by one of the coloring layers 132R, 132G, and 132B. The coloring layers 132R, 132G, and 132B can be provided on a surface of the substrate 152 on the substrate 151 side. The end portions of the coloring layers 132R, 132G, and 132B can overlap the light-blocking layer 117. Regarding the display device 100I, FIG. 13A can be referred to for the details of the structure of the light-emitting element 130, for example.

In the display device 100I, the light-emitting element 130 can emit white light, for example. The coloring layer 132R, the coloring layer 132G, and the coloring layer 132B can transmit red light, green light, and blue light, respectively, for example. Note that in the display device 100I, the coloring layers 132R, 132G, and 132B may be provided between the protective layer 131 and the adhesive layer 142. In that case, the protective layer 131 is preferably planarized as illustrated in FIG. 13A.

Although FIG. 38A, FIG. 39A, and the like illustrate an example in which the top surface of the layer 128 includes a flat portion, the shape of the layer 128 is not particularly limited. FIGS. 39B to 39D illustrate variation examples of the layer 128 provided to fill a depression portion of the conductive layer 224R.

As illustrated in FIG. 39B, the top surface of the layer 128 can have a shape such that its middle and the vicinity thereof are recessed (i.e., a shape including a concave surface) in the cross section. As illustrated in FIG. 39C, the top surface of the layer 128 can have a shape such that its middle and the vicinity thereof expand (i.e., a shape including a convex surface) in the cross section. As illustrated in FIG. 39D, the top surface of the layer 128 may have a concave shape in the middle and its vicinity and the area between the end portion and the concave surface of the layer 128 may have a convex shape in the cross section.

The above description of the layer 128 illustrated in FIGS. 38B to 38D can also apply to the layer 128 provided to fill a depression portion of the conductive layer 224G and the layer 128 provided to fill a depression portion of the conductive layer 224B.

This embodiment can be combined with any of the other embodiments as appropriate. In this specification, in the case where a plurality of structure examples are shown in one embodiment, the structure examples can be combined as appropriate.

### Embodiment 4

In this embodiment, a light-emitting element that can be used in the display device of one embodiment of the present invention will be described.

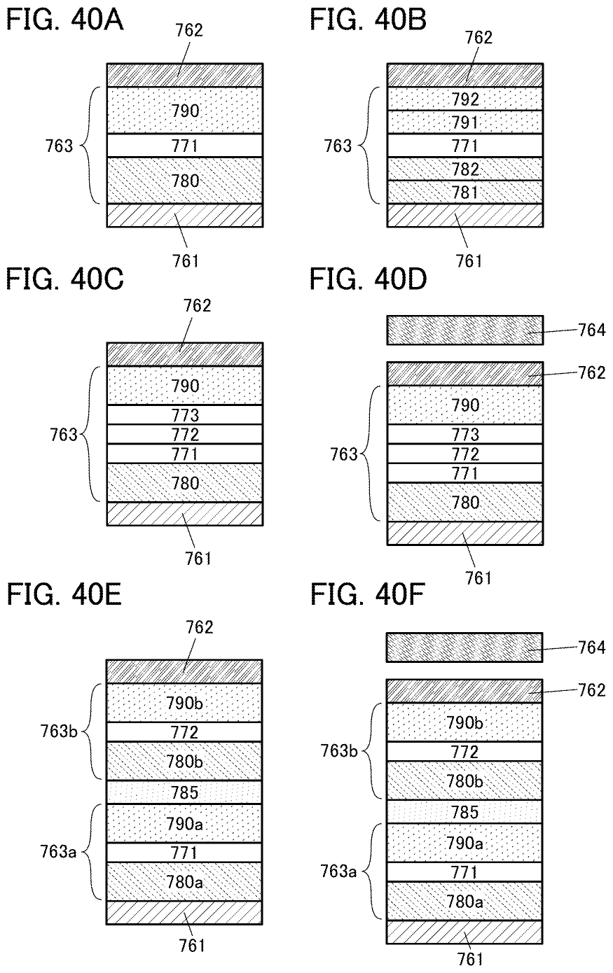

As illustrated in FIG. 40A, the light-emitting element includes an EL layer 763 between a pair of electrodes (a lower electrode 761 and an upper electrode 762). The EL layer 763 can include a plurality of layers such as a layer 780, a light-emitting layer 771, and a layer 790.

The light-emitting layer 771 contains at least a light-emitting substance.

In the case where the lower electrode 761 is an anode and the upper electrode 762 is a cathode, the layer 780 includes one or more of a layer containing a substance with a high hole-injection property (hole-injection layer), a layer containing a substance with a high hole-transport property (hole-transport layer), and a layer containing a substance with a high electron-blocking property (electron-blocking layer). The layer 790 includes one or more of a layer containing a substance with a high electron-injection property (electron-injection layer), a layer containing a substance with a high electron-transport property (electron-transport layer), and a layer containing a substance with a high hole-blocking property (hole-blocking layer). In the case where the lower electrode 761 is the cathode and the upper electrode 762 is the anode, the above structures of the layer 780 and the layer 790 are switched.

The structure including the layer 780, the light-emitting layer 771, and the layer 790, which is provided between a pair of electrodes, can function as a single light-emitting unit, and the structure in FIG. 40A is referred to as a single structure in this specification.

FIG. 40B shows a variation example of the EL layer 763 included in the light-emitting element illustrated in FIG. 40A. Specifically, the light-emitting element illustrated in FIG. 40B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is the anode and the upper electrode 762 is the cathode, for example, the layer 781 can be a hole-injection layer, the layer 782 can be a hole-transport layer, the layer 791 can be an electron-transport layer, and the layer 792 can be an electron-injection layer. In the case where the lower electrode 761 is the cathode and the upper electrode 762 is the anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that structures in which a plurality of light-emitting layers (light-emitting layers 771, 772, and 773) are provided between the layer 780 and the layer 790 as illustrated in FIGS. 40C and 40D are variations of the single structure. Although FIGS. 40C and 40D illustrate examples including three light-emitting layers, the number of light-emitting layers in the light-emitting element having a single structure may be two or four or more. Moreover, the light-emitting element having a single structure may include a buffer layer between two light-emitting layers.

A structure in which a plurality of light-emitting units (light-emitting units 763a and 763b) are connected in series through a charge-generation layer 785 (also referred to as an intermediate layer) as illustrated in FIGS. 40E and 40F is referred to as a tandem structure in this specification. A tandem structure may be referred to as a stack structure. A tandem structure enables a light-emitting element capable of emitting light at high luminance. Furthermore, a tandem structure allows the amount of current needed for obtaining the same luminance to be reduced as compared to the case of using a single structure; thus, the display device can have lower power consumption and higher reliability.

Note that FIGS. 40D and 40F show examples where the display device includes a layer 764 overlapping the light-emitting element. FIG. 40D shows an example where the layer 764 overlaps the light-emitting element illustrated in FIG. 40C. FIG. 40F shows an example where the layer 764 overlaps the light-emitting element illustrated in FIG. 40E. In FIGS. 40D and 40F, a conductive film that transmits visible light is used for the upper electrode 762 so that light is extracted from the upper electrode 762 side.

One or both of a color conversion layer and a color filter (coloring layer) can be used as the layer 764.

In FIGS. 40C and 40D, light-emitting substances that emit light of the same color, or moreover, the same light-emitting substance may be used for the light-emitting layers 771, 772, and 773. For example, a light-emitting substance that emits blue light may be used for the light-emitting layers 771, 772, and 773. In a subpixel that exhibits blue light, blue light emitted from the light-emitting element can be extracted. In a subpixel that exhibits red light and a subpixel that exhibits green light, by providing a color conversion layer as the layer 764 illustrated in FIG. 40D, blue light emitted from the light-emitting element can be converted into light with a longer wavelength, and red light or green light can be extracted. As the layer 764, both a color conversion layer and a coloring layer are preferably used. In some cases, part of light emitted from the light-emitting element is transmitted through the color conversion layer without being converted. When light transmitted through the color conversion layer is extracted through the coloring layer, light other than light of the intended color can be absorbed by the coloring layer, and color purity of light exhibited by a subpixel can be improved.

In FIGS. 40C and 40D, the light-emitting layers 771, 772, and 773 may be formed using light-emitting substances that emit light of different colors. White light is obtained when the light-emitting layers 771, 772, and 773 emit light of complementary colors. For example, the light-emitting element having a single structure preferably includes a light-emitting layer containing a light-emitting substance that emits blue light and a light-emitting layer containing a light-emitting substance that emits visible light having a longer wavelength than blue light.

As the layer 764 illustrated in FIG. 40D, a color filter may be provided. When white light passes through the color filter, light of a desired color can be obtained.

For example, in the case where the light-emitting element having a single structure includes three light-emitting layers, the light-emitting element preferably includes a light-emitting layer containing a light-emitting substance that emits red (R) light, a light-emitting layer containing a light-emitting substance that emits green (G) light, and a light-emitting layer containing a light-emitting substance that emits blue (B) light. The stacking order of the light-emitting layers can be R, G, and B from the anode side or R, B, and G from the anode side, for example. In such a case, a buffer layer may be provided between R and G or between R and B.

For example, in the case where the light-emitting element having a single structure includes two light-emitting layers, the light-emitting element preferably includes a light-emitting layer containing a light-emitting substance that emits blue (B) light and a light-emitting layer containing a light-emitting substance that emits yellow (Y) light. This structure may be referred to as a BY single structure.

A light-emitting element that emits white light preferably includes two or more light-emitting layers. For example, to obtain white light emission by using two light-emitting layers, the two light-emitting layers are selected such that emission colors of the light-emitting layers are complementary colors. For example, when the emission colors of the first light-emitting layer and the second light-emitting layer are made complementary, the light-emitting element can be configured to emit white light as a whole. To obtain white light emission by using three or more light-emitting layers, the light-emitting element is configured to emit white light as a whole by combining emission colors of the three or more light-emitting layers.

In FIGS. 40C and 40D, each of the layers 780 and 790 may independently have a stacked-layer structure of two or more layers as in FIG. 40B.

In FIGS. 40E and 40F, light-emitting substances that emit light of the same color, or moreover, the same light-emitting substance may be used for the light-emitting layers 771 and 772. For example, in light-emitting elements included in subpixels that exhibit light of different colors, a light-emitting substance that emits blue light may be used for the light-emitting layers 771 and 772. In a subpixel that exhibits blue light, blue light emitted from the light-emitting element can be extracted. In a subpixel that exhibits red light and a subpixel that exhibits green light, by providing a color conversion layer as the layer 764 illustrated in FIG. 40F, blue light emitted from the light-emitting element can be converted into light with a longer wavelength, and red light or green light can be extracted. As the layer 764, both a color conversion layer and a coloring layer are preferably used.

In the case where the light-emitting element having the structure illustrated in FIG. 40E or FIG. 40F is used in subpixels that exhibit light of different colors, different light-emitting substances may be used in the subpixels. Specifically, in the light-emitting element included in the subpixel that exhibits red light, a light-emitting substance that emits red light may be used for the light-emitting layers 771 and 772. Similarly, in the light-emitting element included in the subpixel that exhibits green light, a light-emitting substance that emits green light may be used for the light-emitting layers 771 and 772. In the light-emitting element included in the subpixel that exhibits blue light, a light-emitting substance that emits blue light may be used for the light-emitting layers 771 and 772. The display device with such a structure employs light-emitting elements having a tandem structure and is regarded as having the SBS structure. Thus, the display device can have both the advantage of the tandem structure and the advantage of the SBS structure. Accordingly, a highly reliable light-emitting element capable of emitting light at high luminance is achieved.

In FIGS. 40E and 40F, light-emitting substances that emit light of different colors may be used for the light-emitting layers 771 and 772. White light is obtained when the light-emitting layers 771 and 772 emit light of complementary colors. As the layer 764 illustrated in FIG. 40F, a color filter may be provided. When white light passes through the color filter, light of a desired color can be obtained.

Although FIGS. 40E and 40F illustrate examples in which the light-emitting unit 763a includes one light-emitting layer 771 and the light-emitting unit 763b includes one light-emitting layer 772, one embodiment of the present invention is not limited thereto. Each of the light-emitting units 763a and 763b may include two or more light-emitting layers.

Although FIGS. 40E and 40F illustrate examples in which the light-emitting element includes two light-emitting units, one embodiment of the present invention is not limited thereto. The light-emitting element may include three or more light-emitting units. Note that a structure including two light-emitting units may be referred to as a two-unit tandem structure, and a structure including three light-emitting units may be referred to as a three-unit tandem structure.

In FIGS. 40E and 40F, the light-emitting unit 763a includes a layer 780a, the light-emitting layer 771, and a layer 790a and the light-emitting unit 763b includes a layer 780b, the light-emitting layer 772, and a layer 790b.

In the case where the lower electrode 761 is the anode and the upper electrode 762 is the cathode, each of the layers 780a and 780b includes one or more of a hole-injection layer, a hole-transport layer, and an electron-blocking layer. Each of the layers 790a and 790b includes one or more of an electron-injection layer, an electron-transport layer, and a hole-blocking layer. In the case where the lower electrode 761 is the cathode and the upper electrode 762 is the anode, the above structures of the layer 780a and the layer 790a are switched, and the above structures of the layer 780b and the layer 790b are switched.

In the case where the lower electrode 761 is the anode and the upper electrode 762 is the cathode, for example, the layer 780a includes a hole-injection layer and a hole-transport layer over the hole-injection layer and may also include an electron-blocking layer over the hole-transport layer. The layer 790a includes an electron-transport layer and may also include a hole-blocking layer between the light-emitting layer 771 and the electron-transport layer. The layer 780b includes a hole-transport layer and may also include an electron-blocking layer over the hole-transport layer. The layer 790b includes an electron-transport layer and an electron-injection layer over the electron-transport layer and may also include a hole-blocking layer between the light-emitting layer 772 and the electron-transport layer. In the case where the lower electrode 761 is the cathode and the upper electrode 762 is the anode, for example, the layer 780a includes an electron-injection layer and an electron-transport layer over the electron-injection layer and may also include a hole-blocking layer over the electron-transport layer. The layer 790a includes a hole-transport layer and may also include an electron-blocking layer between the light-emitting layer 771 and the hole-transport layer. The layer 780b includes an electron-transport layer and may also include a hole-blocking layer over the electron-transport layer. The layer 790b includes a hole-transport layer and a hole-injection layer over the hole-transport layer and may also include an electron-blocking layer between the light-emitting layer 772 and the hole-transport layer.

In the case of fabricating a light-emitting element having a tandem structure, two light-emitting units are stacked with the charge-generation layer 785 positioned therebetween. The charge-generation layer 785 includes at least a charge-generation region. The charge-generation layer 785 has a function of injecting electrons into one of the two light-emitting units and injecting holes to the other when voltage is applied between the pair of electrodes.

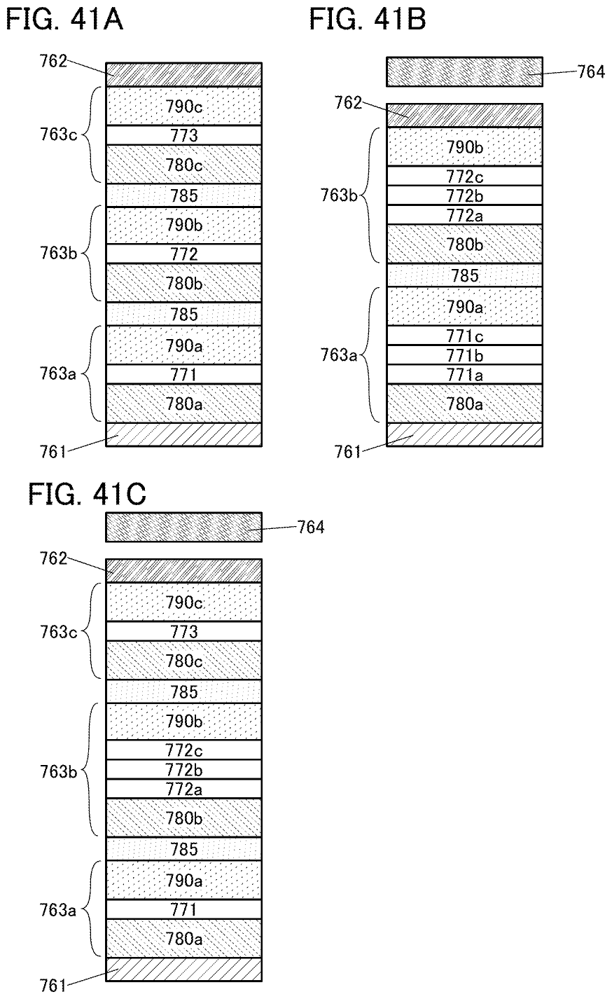

Examples of the structure of a light-emitting element having a tandem structure are structures illustrated in FIGS. 41A to 41C.

FIG. 41A shows a structure including three light-emitting units. In FIG. 41A, a plurality of light-emitting units (light-emitting units 763a, 763b, and 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layers 780a and 780b, and the layer 790c can have a structure applicable to the layers 790a and 790b.

In FIG. 41A, the light-emitting layers 771, 772, and 773 each preferably contain a light-emitting substance that emits light of the same color. Specifically, the light-emitting layers 771, 772, and 773 can each contain a light-emitting substance that emits red (R) light (i.e., an R\R\R three-unit tandem structure), can each contain a light-emitting substance that emits green (G) light (i.e., a G\G\G three-unit tandem structure), or can each contain a light-emitting substance that emits blue (B) light (i.e., a B\B\B three-unit tandem structure). Note that “a\b” means that a light-emitting unit containing a light-emitting substance that emits light of the color “b” is provided over a light-emitting unit containing a light-emitting substance that emits light of the color “a” with a charge-generation layer therebetween.

In FIG. 41A, light-emitting substances that emit light of different colors may be used for some or all of the light-emitting layers 771, 772, and 773. Examples of a combination of emission colors for the light-emitting layers 771, 772, and 773 include blue (B) for two of them and yellow (Y) for the other; and red (R) for one of them, green (G) for another, and blue (B) for the other.

Note that the structure of the light-emitting unit is not limited to that in FIG. 41A. For example, as illustrated in FIG. 41B, light-emitting units each including a plurality of light-emitting layers may be stacked in a tandem light-emitting element. FIG. 41B shows a structure in which two light-emitting units (the light-emitting units 763a and 763b) are connected in series through the charge-generation layer 785. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 41B, the light-emitting unit 763a is configured to emit white (W) light by selecting light-emitting substances for the light-emitting layers 771a, 771b, and 771c so that their emission colors are complementary colors. In addition, the light-emitting unit 763b is configured to emit white (W) light by selecting light-emitting substances for the light-emitting layers 772a, 772b, and 772c so that their emission colors are complementary colors. In other words, the structure illustrated in FIG. 41B is a W\W two-unit tandem structure. Note that there is no particular limitation on the stacking order of the light-emitting substances having complementary emission colors. The practitioner can select the optimal stacking order as appropriate. Although not illustrated, a W\W\W three-unit tandem structure or a tandem structure of four or more units may be employed.

Other examples of the structure of a light-emitting element having a tandem structure include a B\Y or Y\B two-unit tandem structure including a light-emitting unit that emits yellow (Y) light and a light-emitting unit that emits blue (B) light; an R·G\B or B\RG two-unit tandem structure including a light-emitting unit that emits red (R) light and green (G) light and a light-emitting unit that emits blue (B) light; a B\Y\B three-unit tandem structure including a light-emitting unit that emits blue (B) light, a light-emitting unit that emits yellow (Y) light, and a light-emitting unit that emits blue (B) light in this order; a B\YG\B three-unit tandem structure including a light-emitting unit that emits blue (B) light, a light-emitting unit that emits yellow green (YG) light, and a light-emitting unit that emits blue (B) light in this order; and a B\G\B three-unit tandem structure including a light-emitting unit that emits blue (B) light, a light-emitting unit that emits green (G) light, and a light-emitting unit that emits blue (B) light in this order. Note that “a·b” means that one light-emitting unit contains a light-emitting substance that emits light of the color “a” and a light-emitting substance that emits light of the color “b”.

As illustrated in FIG. 41C, a light-emitting unit including one light-emitting layer and a light-emitting unit including a plurality of light-emitting layers may be used in combination.

Specifically, in the structure illustrated in FIG. 41C, a plurality of light-emitting units (the light-emitting units 763a, 763b, and 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

For example, the structure illustrated in FIG. 41C can be a B\R·G·YG\B three-unit tandem structure in which the light-emitting unit 763a emits blue (B) light, the light-emitting unit 763b emits red (R) light, green (G) light, and yellow green (YG) light, and the light-emitting unit 763c emits blue (B) light.

Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Next, a material that can be used for the light-emitting element will be described.

A conductive film that transmits visible light is used as the electrode through which light is extracted, which is either the lower electrode 761 or the upper electrode 762. A conductive film that reflects visible light is preferably used as the electrode through which light is not extracted. In the case where a display device includes a light-emitting element that emits infrared light, a conductive film that transmits visible light and infrared light is used as the electrode through which light is extracted, and a conductive film that reflects visible light and infrared light is preferably used as the electrode through which light is not extracted.

A conductive film that transmits visible light may be used also as the electrode through which light is not extracted. In that case, this electrode is preferably provided between a reflective layer and the EL layer 763. In other words, light emitted by the EL layer 763 may be reflected by the reflective layer to be extracted from the display device.

As the material of the pair of electrodes of the light-emitting element, a metal, an alloy, an electrically conductive compound, a mixture thereof, and the like can be used as appropriate. Specific examples of the material include a metal such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium; and an alloy containing any of these metals in appropriate combination. Other examples of the material include indium tin oxide, indium tin oxide containing silicon, indium zinc oxide, and indium zinc oxide containing tungsten. Other examples of the material include an aluminum-containing alloy such as an alloy of aluminum, nickel, and lanthanum (Al—Ni—La); and a silver-containing alloy such as an alloy of silver and magnesium and an alloy of silver, palladium, and copper (APC). Other examples of the material include Group 1 and 2 elements of the periodic table that are not shown above (e.g., lithium, cesium, calcium, and strontium), a rare earth metal element such as europium and ytterbium, an alloy containing any of these elements in appropriate combination, and graphene.

The light-emitting element preferably employs a microcavity structure. Therefore, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

Note that the transflective electrode can have a stacked-layer structure of a conductive layer that can be used as a reflective electrode and a conductive layer that can be used as an electrode having a property of transmitting visible light (also referred to as a transparent electrode).

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The light-emitting element includes at least a light-emitting layer. In addition to the light-emitting layer, the light-emitting element may further include a layer containing any of a substance with a high hole-injection property, a substance with a high hole-transport property, a hole-blocking material, a substance with a high electron-transport property, an electron-blocking material, a substance with a high electron-injection property, a substance with a bipolar property (a substance with high electron-transport and hole-transport properties), or the like. For example, the light-emitting element can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting element, and an inorganic compound may also be included. Each layer included in the light-emitting element can be formed by an evaporation method (including a vacuum evaporation method), a transfer method, a printing method, an inkjet method, a coating method, or the like.

The light-emitting layer can contain one or more kinds of light-emitting substances. As the light-emitting substance, a substance whose emission color is blue, violet, bluish violet, green, yellow green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (guest material). As one or more kinds of organic compounds, one or both of a substance with a high hole-transport property (hole-transport material) and a substance with a high electron-transport property (electron-transport material) can be used. As the hole-transport material, an aftermentioned material with a high hole-transport property usable for a hole-transport layer can be used. As the electron-transport material, an aftermentioned material with a high electron-transport property usable for the electron-transport layer can be used. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by exciplex-triplet energy transfer (ExTET), which is energy transfer from the exciplex to the light-emitting substance (phosphorescent material). When a combination of materials is selected so as to form an exciplex that emits light whose wavelength overlaps the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

The hole-injection layer injects holes from the anode to the hole-transport layer and contains a material with a high hole-injection property. Examples of the material with a high hole-injection property include an aromatic amine compound and a composite material containing a hole-transport material and an acceptor material (electron-accepting material).

As the hole-transport material, the aftermentioned material with a high hole-transport property usable for the hole-transport layer can be used.

As the acceptor material, an oxide of a metal that belongs to any of Groups 4 to 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is especially preferable since it is stable in the air, has a low hygroscopic property, and is easy to handle. An organic acceptor material containing fluorine can also be used. An organic acceptor material such as a quinodimethane derivative, a chloranil derivative, and a hexaazatriphenylene derivative can also be used.

As the material with a high hole-injection property, a material containing a hole-transport material and the oxide of a metal that belongs to any of Groups 4 to 8 of the periodic table (typically molybdenum oxide) may be used, for example.

The hole-transport layer transports holes injected from the anode by the hole-injection layer, to the light-emitting layer. The hole-transport layer contains a hole-transport material. The hole-transport material preferably has a hole mobility higher than or equal to 1×10⁻⁶ cm²/Vs. Note that other substances can also be used as long as the substances have a hole-transport property higher than an electron-transport property. As the hole-transport material, a material having a high hole-transport property, such as a π-electron rich heteroaromatic compound (e.g., a carbazole derivative, a thiophene derivative, or a furan derivative) or an aromatic amine (a compound having an aromatic amine skeleton), is preferred.

The electron-blocking layer is provided in contact with the light-emitting layer. The electron-blocking layer contains a material that has a hole-transport property and can block electrons. The electron-blocking layer can be formed using a material having an electron-blocking property among the hole-transport materials.

Since the electron-blocking layer has a hole-transport property, the electron-blocking layer can also be referred to as a hole-transport layer. A hole-transport layer having an electron-blocking property can be referred to as an electron-blocking layer.

The electron-transport layer transports electrons injected from the cathode by the electron-injection layer, to the light-emitting layer. The electron-transport layer contains an electron-transport material. The electron-transport material preferably has an electron mobility higher than or equal to 1×10⁻⁶ cm²/Vs. Note that other substances can also be used as long as the substances have an electron-transport property higher than a hole-transport property. As the electron-transport material, any of the following materials having a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The hole-blocking layer is provided in contact with the light-emitting layer. The hole-blocking layer contains a material that has an electron-transport property and can block holes. The hole-blocking layer can be formed using a material having a hole-blocking property among the electron-transport materials.

Since the hole-blocking layer has an electron-transport property, the hole-blocking layer can also be referred to as an electron-transport layer. An electron-transport layer having a hole-blocking property can be referred to as a hole-blocking layer.

The electron-injection layer injects electrons from the cathode to the electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The difference between the LUMO level of the material with a high electron-injection property and the work function of the material used for the cathode is preferably small (specifically, less than or equal to 0.5 eV).

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFx, where x is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate, for example. The electron-injection layer may have a stacked-layer structure of two or more layers. In the stacked-layer structure, for example, lithium fluoride can be used for the first layer and ytterbium can be used for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-α:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

The charge-generation layer includes at least a charge-generation region, as described above. The charge-generation region preferably contains an acceptor material, and for example, preferably contains a hole-transport material and an acceptor material, each of which can be used for the hole-injection layer.

The charge-generation layer preferably includes a layer containing a material with a high electron-injection property. The layer can be referred to as an electron-injection buffer layer. The electron-injection buffer layer is preferably provided between the charge-generation region and the electron-transport layer. Providing the electron-injection buffer layer can relieve an injection barrier between the charge-generation region and the electron-transport layer; thus, electrons generated in the charge-generation region can be easily injected to the electron-transport layer.

The electron-injection buffer layer preferably contains an alkali metal or an alkaline earth metal, and for example, can contain an alkali metal compound or an alkaline earth metal compound. Specifically, the electron-injection buffer layer preferably contains an inorganic compound containing an alkali metal and oxygen or an inorganic compound containing an alkaline earth metal and oxygen, and further preferably contains an inorganic compound containing lithium and oxygen (e.g., lithium oxide (Li₂O)). Furthermore, a material that can be used for the electron-injection layer is suitably used for the electron-injection buffer layer.

The charge-generation layer preferably includes a layer containing a material with a high electron-transport property. The layer can be referred to as an electron-relay layer. The electron-relay layer is preferably provided between the charge-generation region and the electron-injection buffer layer. In the case where the charge-generation layer does not include the electron-injection buffer layer, the electron-relay layer is preferably provided between the charge-generation region and the electron-transport layer. The electron-relay layer has a function of preventing an interaction between the charge-generation region and the electron-injection buffer layer (or the electron-transport layer) and transferring electrons smoothly.

For the electron-relay layer, it is preferable to use a phthalocyanine-based material such as copper(II) phthalocyanine (abbreviation: CuPc) or a metal complex having a metal-oxygen bond and an aromatic ligand.

Note that the charge-generation region, the electron-injection buffer layer, and the electron-relay layer cannot be clearly distinguished from each other in some cases depending on their cross-sectional shapes, characteristics, or the like.

The charge-generation layer may contain a donor material instead of an acceptor material. For example, as the charge-generation layer, a layer containing an electron-transport material and a donor material that can be used for the electron-injection layer may be provided.

When light-emitting units are stacked, the charge-generation layer provided between two light-emitting units can suppress an increase in driving voltage.

This embodiment can be combined with any of the other embodiments as appropriate. In this specification, in the case where a plurality of structure examples are shown in one embodiment, the structure examples can be combined as appropriate.

### Embodiment 5

In this embodiment, electronic devices of embodiments of the present invention will be described.

Electronic devices of this embodiment are each provided with the display device of one embodiment of the present invention in a display portion. The display device of one embodiment of the present invention is highly reliable and can be easily increased in resolution and definition. Thus, the display panel of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display device of one embodiment of the present invention can have high definition, and thus can be favorably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, resolution of 4K, 8K, or higher is preferable. The pixel density (resolution) of the display device of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. With such a display device having one or both of high resolution and high definition, the electronic device can have higher realistic sensation, sense of depth, and the like in personal use such as portable use or home use. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic device in this embodiment can have a variety of functions. For example, the electronic device in this embodiment can have a function of displaying a variety of data (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

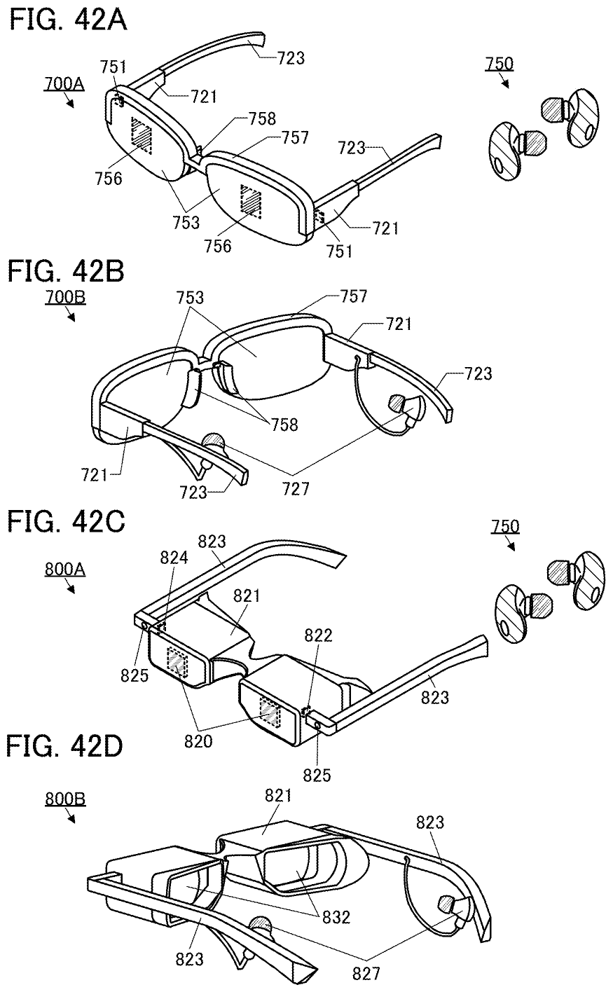

Examples of head-mounted wearable devices are described with reference to FIGS. 42A to 42D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 42A and an electronic device 700B illustrated in FIG. 42B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, a highly reliable electronic device is obtained.

The electronic devices 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic devices 700A and 700B are electronic devices capable of AR display.

In the electronic devices 700A and 700B, a camera capable of capturing images of the front side may be provided as the image capturing portion. Furthermore, when the electronic devices 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic devices 700A and 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element (also referred to as a photoelectric conversion device) can be used as a light-receiving element. One or both of an inorganic semiconductor and an organic semiconductor can be used for an active layer of the photoelectric conversion element.

An electronic device 800A illustrated in FIG. 42C and an electronic device 800B illustrated in FIG. 42D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, a highly reliable electronic device is obtained.

The display portions 820 are provided at positions where the user can see through the lenses 832 inside the housing 821. When the pair of display portions 820 display different images, three-dimensional display using parallax can be performed.

The electronic devices 800A and 800B can be regarded as electronic devices for VR. The user who wears the electronic device 800A or the electronic device 800B can see images displayed on the display portions 820 through the lenses 832.

The electronic devices 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic devices 800A and 800B preferably include a mechanism for adjusting focus by changing the distance between the lenses 832 and the display portions 820.

The electronic device 800A or the electronic device 800B can be mounted on the user's head with the wearing portions 823. FIG. 42C, for instance, shows an example where the wearing portion 823 has a shape like a temple (also referred to as a joint or the like) of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portions 825 are provided is shown here, a range sensor (also referred to as a sensing portion) capable of measuring a distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic device 800A.

The electronic devices 800A and 800B may each include an input terminal. To the input terminal, a cable for supplying a video signal from a video output device or the like, power for charging a battery provided in the electronic device, and the like can be connected.

The electronic device of one embodiment of the present invention may have a function of performing wireless communication with earphones 750. The earphones 750 include a communication portion (not illustrated) and has a wireless communication function. The earphones 750 can receive information (e.g., audio data) from the electronic device with the wireless communication function. For example, the electronic device 700A in FIG. 42A has a function of transmitting information to the earphones 750 with the wireless communication function. As another example, the electronic device 800A in FIG. 42C has a function of transmitting information to the earphones 750 with the wireless communication function.

The electronic device may include an earphone portion. The electronic device 700B in FIG. 42B includes earphone portions 727. For example, the earphone portion 727 can be connected to the control portion by wire. Part of a wiring that connects the earphone portion 727 and the control portion may be positioned inside the housing 721 or the mounting portion 723.

Similarly, the electronic device 800B in FIG. 42D includes earphone portions 827. For example, the earphone portion 827 can be connected to the control portion 824 by wire. Part of a wiring that connects the earphone portion 827 and the control portion 824 may be positioned inside the housing 821 or the mounting portion 823. Alternatively, the earphone portions 827 and the mounting portions 823 may include magnets. This is preferred because the earphone portions 827 can be fixed to the mounting portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic devices 700A and 700B) and the goggles-type device (e.g., the electronic devices 800A and 800B) are preferable as the electronic device of one embodiment of the present invention.

The electronic device of one embodiment of the present invention can transmit information to earphones by wire or wirelessly.

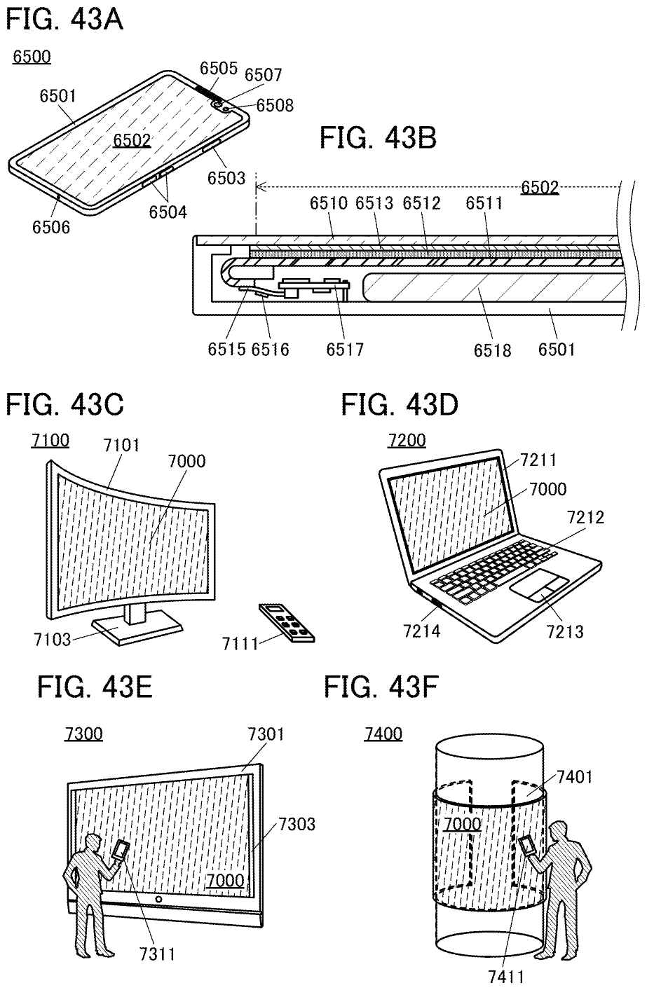

An electronic device 6500 illustrated in FIG. 43A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, a highly reliable electronic device is obtained.

FIG. 43B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the region that is folded back. An IC 6516 is mounted on the FPC 6515. The FPC 6515 is connected to a terminal provided on the printed circuit board 6517.

The display device of one embodiment of the present invention can be used in the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be achieved.

FIG. 43C illustrates an example of a television device. In a television device 7100, a display portion 7000 is incorporated in a housing 7101. Here, the housing 7101 is supported by a stand 7103.

The display device of one embodiment of the present invention can be used in the display portion 7000. Thus, a highly reliable electronic device is obtained.

Operation of the television device 7100 illustrated in FIG. 43C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel of the remote controller 7111, channels and volume can be controlled and images displayed on the display portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (e.g., between a transmitter and a receiver or between receivers) information communication can be performed.

FIG. 43D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000. Thus, a highly reliable electronic device is obtained.

FIGS. 43E and 43F illustrate examples of digital signage.

Digital signage 7300 illustrated in FIG. 43E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 43F shows digital signage 7400 attached to a cylindrical pillar 7401. The digital signage 7400 includes the display portion 7000 provided along a curved surface of the pillar 7401.

In FIGS. 43E and 43F, the display device of one embodiment of the present invention can be used in the display portion 7000. Thus, a highly reliable electronic device is obtained.

A larger area of the display portion 7000 can increase the amount of information that can be provided at a time. The larger display portion 7000 attracts more attention, so that the effectiveness of the advertisement can be increased, for example.

The use of the touch panel in the display portion 7000 is preferable because in addition to display of still or moving images on the display portion 7000, intuitive operation by a user is possible. Moreover, for an application for providing information such as route information or traffic information, usability can be enhanced by intuitive operation.

As illustrated in FIGS. 43E and 43F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, a displayed image on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

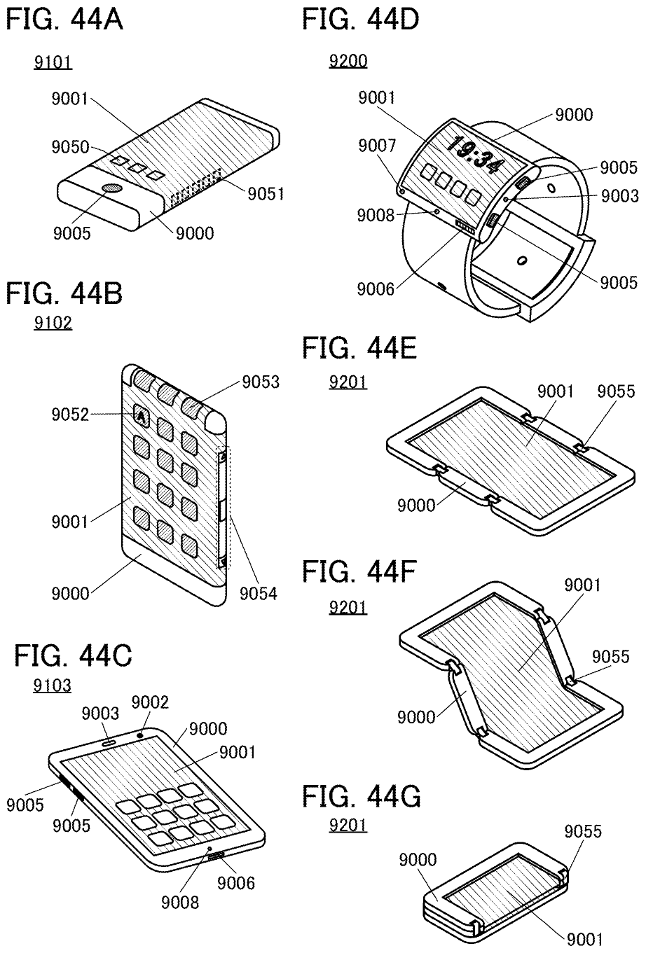

Electronic devices illustrated in FIGS. 44A to 44G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 9008, and the like.

The electronic devices illustrated in FIGS. 44A to 44G have a variety of functions. For example, the electronic devices can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium. Note that the functions of the electronic devices are not limited thereto, and the electronic devices can have a variety of functions. The electronic devices may include a plurality of display portions. The electronic devices may be provided with a camera or the like and have a function of taking a still image or a moving image, a function of storing the taken image in a storage medium (an external storage medium or a storage medium incorporated in the camera), a function of displaying the taken image on the display portion, and the like.

The electronic devices in FIGS. 44A to 44G are described in detail below.

FIG. 44A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 44A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050, for example, may be displayed at the position where the information 9051 is displayed.

FIG. 44B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. Thus, the user can see the display without taking out the portable information terminal 9102 from the pocket and decide whether to answer the call, for example.

FIG. 44C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 44D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 44E to 44G are perspective views of a foldable portable information terminal 9201. FIG. 44E is a perspective view showing the portable information terminal 9201 that is opened. FIG. 44G is a perspective view showing the portable information terminal 9201 that is folded. FIG. 44F is a perspective view showing the portable information terminal 9201 that is shifted from one of the states in FIGS. 44E and 44G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with any of the other embodiments as appropriate. In this specification, in the case where a plurality of structure examples are shown in one embodiment, the structure examples can be combined as appropriate.

This application is based on Japanese Patent Application Serial No. 2021-169567 filed with Japan Patent Office on Oct. 15, 2021, the entire contents of which are hereby incorporated by reference.

What is claimed is:

1. A display device comprising:
a first conductive layer;
a second conductive layer;
a third conductive layer;
a fourth conductive layer;
a functional layer; and
a light-emitting layer,
wherein the second conductive layer, the third conductive layer, and the fourth conductive layer are positioned to cover the first conductive layer and to be electrically connected to the first conductive layer,
wherein the third conductive layer is positioned over the second conductive layer,
wherein the fourth conductive layer is positioned over the third conductive layer,
wherein the functional layer includes a region covering the second conductive layer, the third conductive layer, and the fourth conductive layer and being in contact with the fourth conductive layer,
wherein the light-emitting layer is positioned over the functional layer,
wherein a side surface of the first conductive layer has a tapered shape with a taper angle less than 90° in a cross-sectional view,
wherein the second conductive layer, the third conductive layer, and the fourth conductive layer each include a tapered portion in a region overlapping the side surface of the first conductive layer, and
wherein visible light reflectance of the third conductive layer is higher than visible light reflectance of the first conductive layer, the second conductive layer, and the fourth conductive layer.

2. The display device according to claim 1,
wherein the functional layer includes one or both of a hole-injection layer and a hole-transport layer, and
wherein a work function of the fourth conductive layer is higher than a work function of the third conductive layer.

3. The display device according to claim 1,
wherein the functional layer includes one or both of an electron-injection layer and an electron-transport layer, and
wherein a work function of the fourth conductive layer is lower than a work function of the third conductive layer.

4. The display device according to claim 1, further comprising a base insulating layer under the first conductive layer,
wherein the base insulating layer includes a projection portion in a region overlapped by the first conductive layer, and
wherein a side surface of the projection portion of the base insulating layer has a tapered shape with a taper angle less than 90° in the cross-sectional view.

5. The display device according to claim 1,
wherein the visible light reflectance of the third conductive layer is higher than visible light reflectance of aluminum.

6. The display device according to claim 1,
wherein the third conductive layer comprises silver.

7. The display device according to claim 1,
wherein the first conductive layer comprises titanium, and
wherein the second conductive layer and the fourth conductive layer each comprise an oxide containing one or more selected from indium, tin, zinc, gallium, titanium, aluminum, and silicon.

8. A display module comprising:
the display device according to claim 1; and
at least one of a connector and an integrated circuit.

9. An electronic device comprising:
the display module according to claim 8; and
at least one of a battery, a camera, a speaker, and a microphone.

10. A method for manufacturing a display device, comprising:
forming a first conductive film;
processing the first conductive film, thereby forming a first conductive layer whose side surface has a tapered shape with a taper angle less than 90° in a cross-sectional view;
forming, over the first conductive layer, a second conductive film, a third conductive film over the second conductive film, and a fourth conductive film over the third conductive film;
processing the second conductive film, the third conductive film, and the fourth conductive film, thereby forming a second conductive layer, a third conductive layer, and a fourth conductive layer to cover the first conductive layer, to be electrically connected to the first conductive layer, and to include a tapered portion in a region overlapping the side surface of the first conductive layer; and
forming a functional layer including a region covering the second conductive layer, the third conductive layer, and the fourth conductive layer and being in contact with the fourth conductive layer, and a light-emitting layer over the functional layer,
wherein as the third conductive film, a film having higher visible light reflectance than the first conductive film, the second conductive film, and the fourth conductive film is formed.

11. The method for manufacturing a display device, according to claim 10,
wherein as the fourth conductive film, a film having a higher work function than the third conductive film is formed, and
wherein as the functional layer, one or both of a hole-injection layer and a hole-transport layer are formed.

12. The method for manufacturing a display device, according to claim 10,
wherein as the fourth conductive film, a film having a lower work function than the third conductive film is formed, and
wherein as the functional layer, one or both of an electron-injection layer and an electron-transport layer are formed.

13. The method for manufacturing a display device, according to claim 10,
wherein the first conductive film is formed over a base insulating layer, and
wherein in the step of processing the first conductive film to form the first conductive layer, a depression portion whose side surface has a tapered shape with a taper angle less than 90° is formed in the base insulating layer in a region not overlapped by the first conductive layer.

14. The method for manufacturing a display device, according to claim 10,
wherein the third conductive film comprises silver.

15. The method for manufacturing a display device, according to claim 10,
wherein the visible light reflectance of the third conductive film is higher than visible light reflectance of aluminum.

16. The method for manufacturing a display device, according to claim 10,
wherein the first conductive film comprises titanium, and
wherein the second conductive film and the fourth conductive film each comprise an oxide containing one or more selected from indium, tin, zinc, gallium, titanium, aluminum, and silicon.

17. The method for manufacturing a display device, according to claim 10, further comprising:
forming, over the fourth conductive layer, a functional film, a light-emitting film over the functional film, and a mask film over the light-emitting film;
processing the functional film, the light-emitting film, and the mask film, thereby forming the functional layer, the light-emitting layer, and a mask layer over the light-emitting layer; and
removing at least part of the mask layer.

18. The method for manufacturing a display device, according to claim 17,
wherein the functional film, the light-emitting film, and the mask film are processed by a photolithography method.
